(19) United States
(12) Patent Application Publication
(10) Pub. No.: US 2024/0079475 A1
(43) Pub. Date: Mar. 7, 2024

(54) METHODS OF COMPACT CELL DESIGN FOR LOGIC APPLICATIONS

(71) Applicant: Tokyo Electron Limited, Tokyo (JP)

(72) Inventors: Mark I. Gardner, Albany, NY (US); H. Jim Fulford, Albany, NY (US)

(73) Assignee: Tokyo Electron Limited, Tokyo (JP)

(21) Appl. No.: 17/901,783

(22) Filed: Sep. 1, 2022

(51) Int. Cl. H01L 29/66; H01L 29/423

(52) U.S. Cl. CPC H01L 29/66439; H01L 29/42392

(57) ABSTRACT

Semiconductor devices and corresponding methods of manufacture are disclosed. The method includes forming a first stack over a substrate, including first dielectric layers and second dielectric layers alternately stacked on top of one another. The method includes replacing a first portion of the first stack with a second stack including first semiconductor layers and second semiconductor layers alternately stacked on top of one another. The method includes removing a second portion of the first stack to expose sidewalls of each of the second semiconductor layers, respectively. The method includes forming, through the removed second portion of the first stack, a pair of first epitaxial structures in contact with a lower one of the second semiconductor layers, respectively. The method includes forming, through the removed second portion of the first stack, a pair of second epitaxial structures in contact with an upper one of the second semiconductor layers, respectively.

### FIELD OF THE DISCLOSURE

This disclosure relates to microelectronic devices including semiconductor devices, transistors, and integrated circuits, including methods of microfabrication.

### BACKGROUND

In the manufacture of semiconductor devices (especially on the microscopic scale), various fabrication processes are executed, for example, film-forming depositions, etch mask creation, patterning, material etching and removal, and doping treatments, among others. These processes can be performed repeatedly to form desired semiconductor device elements on a substrate. Historically, with microfabrication, transistors have been created in one plane, with wiring or metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

### SUMMARY

Three-dimensional integration (e.g., the vertical stacking of multiple devices) aims to overcome scaling limitations experienced in planar devices by increasing transistor density in volume rather than area. Three-dimensional integration as applied to random logic designs is substantially more difficult than alternative approaches. Three-dimensional integration for logic chips (e.g., CPU (central processing unit), GPU (graphics processing unit), FPGA (field programmable gate array, SoC (System on a Chip), etc.) are being pursued.

The techniques described herein include methods and devices for 3D fabrication of semiconductor devices. Specifically, techniques may include 3D stacking with source and drain extensions using at least one 3D channel nanosheet core formation. The 3D structure for the semiconductor device can include an integrated metal self-aligned extension for source and drain epitaxial (EPI) hookup (e.g., for 3D horizontal device integration). The techniques can achieve or be used to fabricate both 3D complementary field-effect transistor (CFET) complementary metal-oxide semiconductor (CMOS) and side-by-side CMOS devices. The build or structure constructed using the techniques can include at least one of 3D compact cell designs, self-aligned source/drawing metal regions (e.g., etched at minimum spacer dimension for high-density 3D semiconductor devices), or self-aligned spacer flow to define overhang dielectric region (e.g., spacer offset) to achieve high-performance 3D semiconductor devices. By utilizing the techniques of the technical solution, fewer operations/processes can be performed for fabricating the 3D semiconductor devices.

Of course, the order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

At least one aspect of the present disclosure is directed to a method for microfabrication. The method includes forming a first stack over a substrate, the first stack including a plurality of first dielectric layers and a plurality of second dielectric layers alternately stacked on top of one another. The method includes replacing a first portion of the first stack with a second stack, the second stack including a plurality of first semiconductor layers and a plurality of second semiconductor layers alternately stacked on top of one another. The method includes removing a second portion of the first stack to expose sidewalls of each of the plurality of second semiconductor layers, respectively. The method includes forming, through the removed second portion of the first stack, a pair of first epitaxial structures in contact with a lower one of the second semiconductor layers, respectively. The method includes forming, through the removed second portion of the first stack, a pair of second epitaxial structures in contact with an upper one of the second semiconductor layers, respectively.

In some implementations, the pair of first epitaxial structures and the pair of second epitaxial structures are concurrently formed. The pair of first epitaxial structures and the pair of second epitaxial structures have a same conductive type. The method includes forming, through the removed second portion of the first stack, a pair of metal structures in electrical contact with the pair of first epitaxial structures, respectively, and with the pair of second epitaxial structures, respectively.

In various arrangements, the pair of first epitaxial structures and the pair of second epitaxial structures are separately formed. The pair of first epitaxial structures and the pair of second epitaxial structures have respectively different conductive types. The method includes forming, through the removed second portion of the first stack, a pair of metal structures in electrical contact with the pair of first epitaxial structures, respectively. In some arrangements, the method includes replacing the first semiconductor layers with a gate structure that is around each of the second semiconductor layers.

In some implementations, the step of replacing a first portion of the first stack with a second stack further comprises: epitaxially growing a third semiconductor layer from the substrate; epitaxially growing a lower one of the first semiconductor layers; epitaxially growing the lower second semiconductor layer; epitaxially growing a middle one of the first semiconductor layers; epitaxially growing the upper second semiconductor layer; and epitaxially growing an upper one of the first semiconductor layers. In some implementations, the method includes replacing the third semiconductor layer with a third dielectric layer to electrically isolate the second stack from the substrate.

In various implementations, prior to removing the second portion of the first stack, the method includes forming a pair of dielectric spacers on opposite sides of a topmost one of the second semiconductor layers. In some implementations, the method includes removing a third portion of the first stack using the dielectric spacers as a mask. The method includes etching, through the removed third portion, respective portions of the second dielectric layers while leaving the first dielectric layers substantially intact to form the second portion of the first stack.

Yet another aspect of the present disclosure is directed to a method of fabricating semiconductor devices. The method includes forming a stack including a plurality of first semiconductor layers and a plurality of second semiconductor layers alternately stacked on top of one another. Sidewalls of each of the first semiconductor layers are respectively covered by corresponding first dielectric layers. Sidewalls of each of the second semiconductor layers are respectively covered by corresponding second dielectric layers. The method includes exposing the sidewalls of each of the second semiconductor layers. The method includes forming a pair of first epitaxial structures in contact with the sidewalls of a lower one of the second semiconductor layers, respectively. The method includes forming a pair of second epitaxial structures in contact with the sidewalls of an upper one of the second semiconductor layers, respectively.

In various implementations, the method includes replacing the first semiconductor layers with a gate structure that is around each of the second semiconductor layers. The pair of first epitaxial structures and the pair of second epitaxial structures are concurrently formed. The pair of first epitaxial structures and the pair of second epitaxial structures have a same conductive type. In some cases, the gate structure, the upper and lower second semiconductor layers, the pair of first epitaxial structures, and the pair of second epitaxial structures collectively operate as a single transistor.

In various arrangements, the pair of first epitaxial structures and the pair of second epitaxial structures are separately formed. The pair of first epitaxial structures and the pair of second epitaxial structures have respectively different conductive types. In some implementations, the gate structure, the lower second semiconductor layer, and the pair of first epitaxial structures collectively operate as a first transistor of an inverter, and the gate structure, the upper second semiconductor layer, and the pair of second epitaxial structures collectively operate as a second transistor of the inverter.

In various implementations, the step of forming a stack comprises: epitaxially growing a third semiconductor layer from a semiconductor substrate; epitaxially growing a lower one of the first semiconductor layers; epitaxially growing the lower second semiconductor layer; epitaxially growing a middle one of the first semiconductor layers; epitaxially growing the upper second semiconductor layer; and epitaxially growing an upper one of the first semiconductor layers. The third semiconductor layer is replaced with a third dielectric layer to electrically isolate the stack from the semiconductor substrate.

Yet another aspect of the present disclosure is directed to a semiconductor device. The semiconductor device includes a first semiconductor layer and a second semiconductor layer vertically spaced from one another. The semiconductor device includes a pair of first epitaxial structures and a pair of second epitaxial structures vertically spaced from one another. The pair of first epitaxial structures are in contact with the first semiconductor layer and the pair of second epitaxial structures are in contact with the second semiconductor layer. The semiconductor device includes a gate structure disposed around each of the first and second semiconductor layers.

In various arrangements, the pair of first epitaxial structures and the pair of second epitaxial structures have a same conductive type such that the gate structure, the first and second semiconductor layers, the pair of first epitaxial structures, and the pair of second epitaxial structures collectively operate as a single transistor. In various arrangements, the pair of first epitaxial structures and the pair of second epitaxial structures have respectively different conductive types such that the gate structure, the first semiconductor layer, and the pair of first epitaxial structures collectively operate as a first transistor of an inverter, and the gate structure, the second semiconductor layer, and the pair of second epitaxial structures collectively operate as a second transistor of the inverter.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIGS. 1-24 show various views of a first process flow to manufacture semiconductor devices with source/drain (S/D) extensions, according to an embodiment;

FIGS. 25-46 show various views of a second process flow to manufacture semiconductor devices with S/D extensions, according to an embodiment;

FIGS. 47-70 show various views of a third process flow to manufacture semiconductor devices with S/D extensions, according to an embodiment;

FIGS. 71-76 show various views of a process flow to manufacture semiconductor devices with S/D metal regions, according to an embodiment; and

FIG. 77 shows a flow diagram of example methods for microfabrication using the process flows described in connection with FIGS. 1-76, according to an embodiment.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Techniques herein include methods and devices for 3D fabrication of semiconductor devices. Specifically, techniques include 3D stacking with S/D extensions using 3D channel nanosheet core formation. Further, the techniques include self-aligned metal extensions/routing for S/D EPI hookup for horizontal device integration. 3D CFET CMOS and side-by-side CMOS devices can be achieved or fabricated with such techniques. Techniques herein can be used for any geometry device (e.g., circular, rectangular, ellipse, etc.). As used herein, the value N can refer to the number of alternating layers of metal or dielectric that are utilized to form various transistor devices. For example, some embodiments herein show an N=2 3D stack, but techniques apply to any number of N layers for any number of stacked devices (e.g., horizontal or vertical stacking), which may be connected with 3D wiring or metallization. Accordingly, high-density circuit formation is enabled because devices are grown, or otherwise formed, vertically. Embodiments can also include self-aligned metal regions that are etched at minimal spacer dimension for high-density 3D builds. The techniques can achieve self-aligned spacer flow defining the overhang dielectric region (e.g., spacer offset).

One advantage with techniques herein is enabling higher density circuits to be produced at reduced cost. The methods described herein provide an efficient 3D process flow that reduces the number of steps for improved efficiency in 3D semiconductor device fabrication processes. Devices include integrated metal self-aligned to S/D EPI hookup for horizontal device integration. Self-aligned spacer flow is achieved to define overhang dielectric region (e.g., spacer offset) by utilization of the techniques discussed herein.

One embodiment described herein includes device (e.g., NMOS, PMOS, or others) fabrication techniques for 3D stacking with S/D extensions. Figures herein illustrate a 3D stack N=2 devices. Another embodiment includes device fabrication techniques for 3D stacking with S/D extensions. Figures show an example of N=2 devices with inverter flow, where the gate electrode is tied together for NMOS and PMOS. Yet another embodiment includes device fabrication techniques for 3D stacking with S/D extensions. Figures show an example of N=2 devices using a precision top spacer for defining dielectric overhang for additional symmetry, such as for S/D spacer regions. Other embodiments include device fabrication techniques to subdivide S/D metal regions. Figures show an example method using a self-aligned spacer between adjacent 3D nanosheet device stacks to achieve a high-density 3D semiconductor device.

Reference will now be made to the figures, which for the convenience of visualizing the fabrication techniques described herein, illustrate a variety of materials undergoing a process flow in various views. Unless expressly indicated otherwise, each Figure represents one (or a set) of fabrication steps in a process flow for manufacturing the devices described herein. In the various views of the Figures, connections between conductive layers or materials may or may not be shown. However, it should be understood that connections between various layers, masks, or materials may be implemented in any configuration to create electric or electronic circuits. When such connections are shown, it should be understood that such connections are merely illustrative and are intended to show a capability for providing such connections, and should not be considered limiting to the scope of the claims.

Likewise, although the Figures and aspects of the disclosure may show or describe devices herein as having a particular shape, it should be understood that such shapes are merely illustrative and should not be considered limiting to the scope of the techniques described herein. For example, the techniques described herein may be implemented in any shape or geometry for any material or layer to achieve desired results. In addition, examples in which two transistors or devices are shown stacked on top of one another are shown for illustrative purposes only, and for the purposes of simplicity. Indeed, the techniques described herein may provide for one to any number of stacked devices. Further, although the devices fabricated using these techniques are shown as transistors, it should be understood that any type of electric electronic device may be manufactured using such techniques, including but not limited to transistors, variable resistors, resistors, and capacitors.

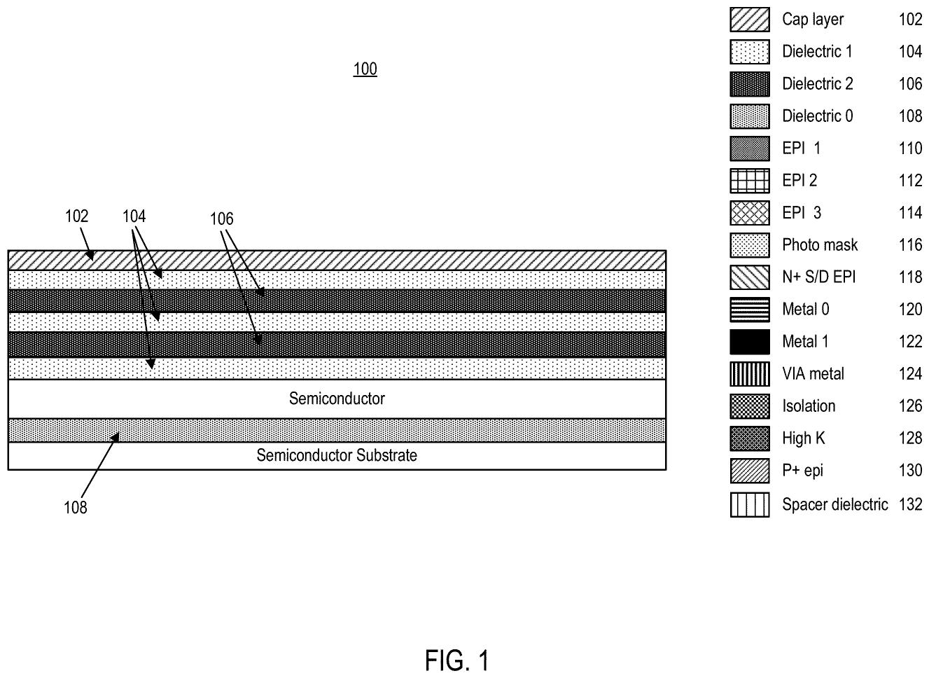

FIGS. 1-24 show various views of a first process flow to manufacture semiconductor devices with S/D extensions. Each of the FIGS. 1-24 generally refer to one or more process steps in a process flow, each of which are described in detail in connection with a respective Figure. For the purposes of simplicity and ease of visualization, some reference numbers may be omitted from some Figures.

FIG. 1 illustrates a cross-sectional view 100 of a semiconductor device in which various layers (e.g., sometimes referred to as blanket layers), including various materials (e.g., dielectric materials), are formed over at least one semiconductor substrate (or other types of substrate, such as a silicon substrate). The semiconductor substrate can be interposed by dielectric material 108 (e.g., shown in the legend as “Dielectric 0”). The dielectric materials discussed herein can be composed of any material with a relatively large dielectric constant and may include oxide materials. Certain dielectric materials can be a spacer for isolating or insulating materials. The dielectric material/layer may sometimes be referred to as an isolation material, insulation material, spacer material, among other similar terms.

The stack of layers includes alternating layers of the dielectric material 104 (e.g., shown in the legend as “Dielectric 1”) and dielectric material 106 (e.g., shown in the legend as “Dielectric 2”). The layers of the dielectric materials can be composed of or include similar materials/compositions or may be constructed from different dielectric materials. Different materials can be used, but subsequent etching is simplified with layers in the stack alternating between two materials. The layer stack can be formed on a substrate, which may be formed from silicon or other material. The formation of the various layers of the semiconductor device can include planarization of the layers, such as by cutting, ablation, chemical mechanical grinding or polishing (CMG/P), or other planarization techniques.

Subsequent to depositing the dielectric materials (e.g., alternating dielectric material 104 and dielectric material 106), a capping layer 102 or top layer (e.g., shown in the legend as “Cap layer 102”) can be deposited above the top surface of the stack of layers, such as above the dielectric material 104. The capping layer 102 can be relatively thicker or include a predefined thickness, and can be a hardmask material, such as TiN. The dielectric materials 104, 106 can be selected to have different etch resistivities. That is, a given dielectric material can be etched without etching other dielectric materials. The layers in the layer stack may be formed using any suitable material deposition technique, including atomic layer deposition (ALD), chemical vapor deposition (CVD), physical vapor deposition (PVD), plasma-enhanced CVD (PECVD), or epitaxial growth or deposition techniques.

In various arrangements, the layers can include similar thicknesses or different thicknesses according to the construction or configuration of the semiconductor device. Although five layers of the dielectric materials are shown, the stack of layers can include additional layers, such as additional dielectric materials. In some cases, there may be fewer layers in the stack of layers. In this example, the dielectric materials 104 can be used as spacers from channel to source or drain, such as described herein. It this step, the stack of layers can be referred to as a first stack including layers of dielectric materials 104 (e.g., first dielectric layers) and dielectric materials 106 (e.g., second dielectric layers) alternatively stacked on top of one another.

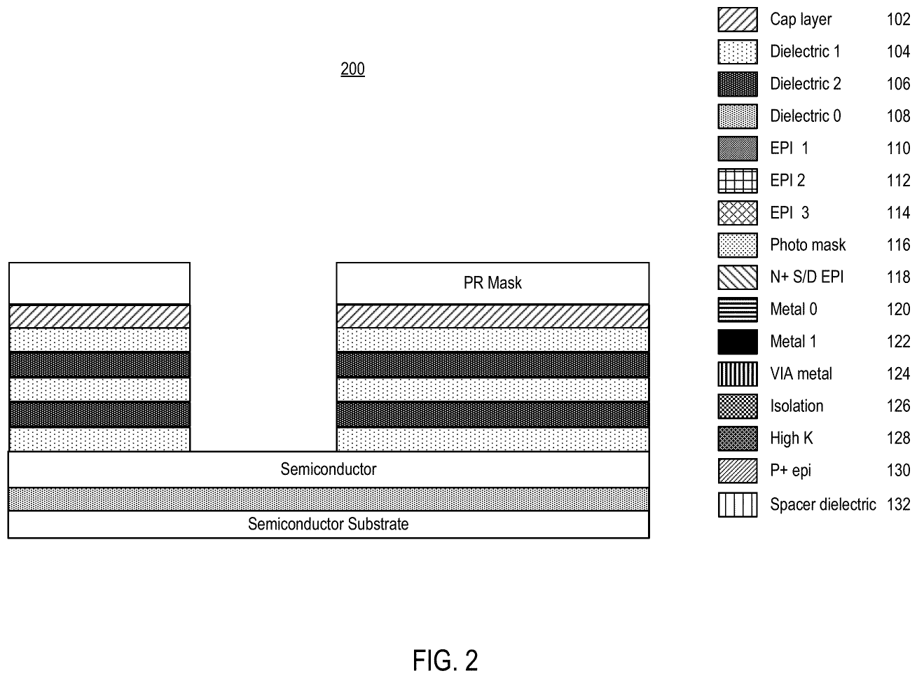

FIG. 2 illustrates a cross-sectional view 200 of the next stage in the process flow. At this stage in the process flow, an etch mask is formed and used to directionally etch openings through the layer stack until uncovering the substrate (e.g., semiconductor substrate, silicon substrate, or another underlying layer). Any suitable etching or material removal technique can be used, including but not limited to dry etching, wet etching, or plasma etching techniques, among others. The etch mask may be removed after the etching process is complete. The etching process may have an etch stop at the substrate. As shown, the etching process exposes the surface of the substrate, forming a vertical channel through the semiconductor device.

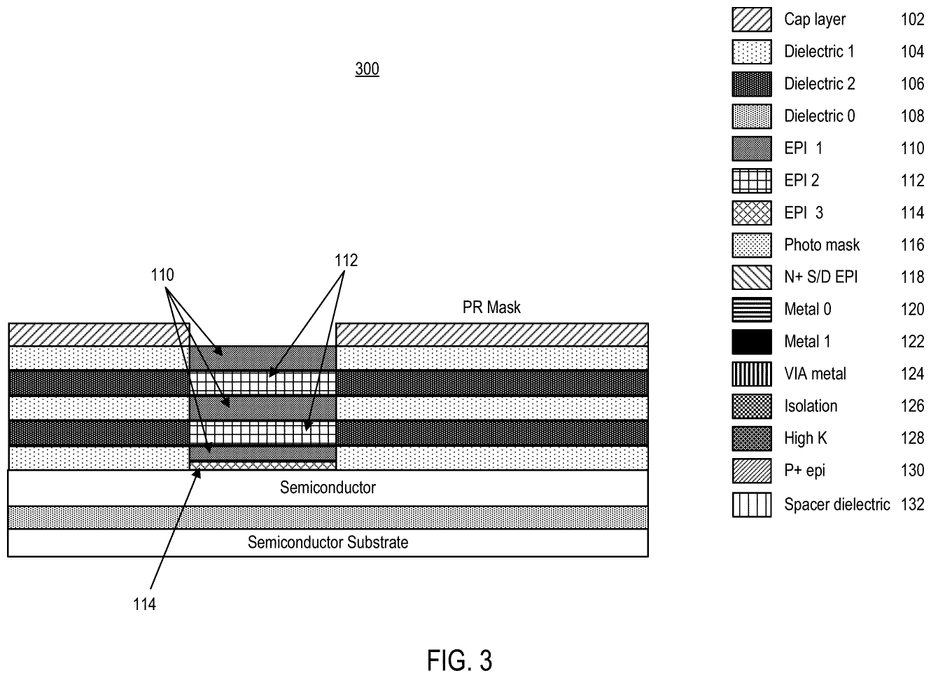

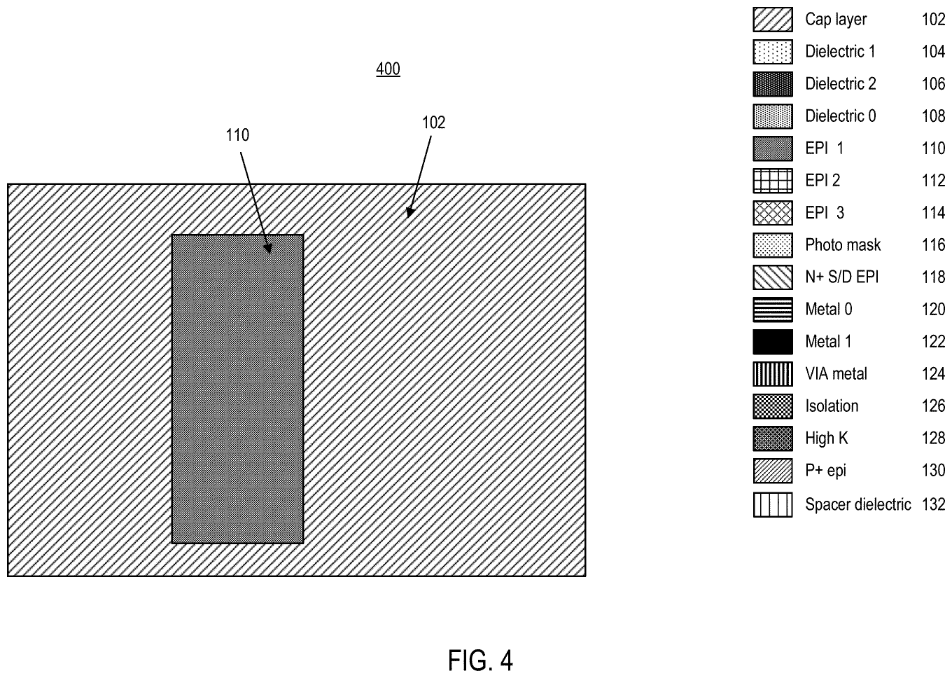

FIG. 3 illustrates a cross-sectional view 300 of the next stage in the process flow. FIG. 4 illustrates a top view 400 corresponding to the cross-sectional view 300 of FIG. 3. Vertical channel materials (e.g., the semiconductor materials 110, 112, 114, etc.) can then be grown epitaxially or formed with the uncovered substrate as a seed material, for example. The vertical channel materials can form a second stack as a replacement of the removed portion (e.g., a first portion) of the first stack. Each of the layers in the second stack can be epitaxially grown. To do so, in this stage in the process flow, a layer of a semiconductor material 114 (e.g., shown in the legend as “EPI 3,” sometimes referred to as a third semiconductor material/layer) can first be grown in the openings formed in the previous process step. The semiconductor material 114 may be any type of material that can be epitaxially grown on the substrate layer, such as SiGe. The semiconductor material 114 may be formed using any suitable material formation technique, including epitaxial growth. As discussed herein, the semiconductor material 114 can isolate the stack of layers (e.g., the second stack) from the substrate.

After forming the semiconductor material 114, the semiconductor material 110 (e.g., shown in the legend as “EPI 1,” sometimes referred to as a first semiconductor layer) is grown in the opening utilizing the semiconductor material 114 as a seed layer. The semiconductor material 110 can be formed to a predetermined height, for example, to just below the lower layer of the dielectric materials 106 in the first stack. In this step, the semiconductor material 110 can be a lower one of first (e.g., set of) semiconductor layers (e.g., lower first semiconductor layer).

The semiconductor material 112 (e.g., shown in the legend as “EPI 2”) is grown in the opening utilizing the semiconductor material 110 as a seed layer. The semiconductor material 112 can be formed to a predetermined height, for example, to just below the middle dielectric material 104 (e.g., middle one of the dielectric materials 104). The semiconductor material 112 can be a lower one of second (e.g., set of) semiconductor layers (e.g., lower second semiconductor layer). The semiconductor material 112 can include a similar height as the dielectric material 104.

After depositing the lower second semiconductor layer, another semiconductor material 110 is grown above the semiconductor material 112. At this process, the semiconductor material 110 can be referred to as a middle one of the first semiconductor layers (e.g., a middle first semiconductor layer). Subsequently, another semiconductor material 112 is grown above the middle first semiconductor layer. This semiconductor material 112 can be referred to as an upper one of the second semiconductor layers (e.g., an upper second semiconductor layer). After, another layer of the semiconductor material 110 is grown above the upper second semiconductor layer. This semiconductor material 110 can be referred to as an upper one of the first semiconductor layers (e.g., an upper first semiconductor layer). Hence, the second stack replacing the removed portion of the first stack can include the semiconductor materials 110, 112 that are alternately stacked on top of one another above the semiconductor material 114.

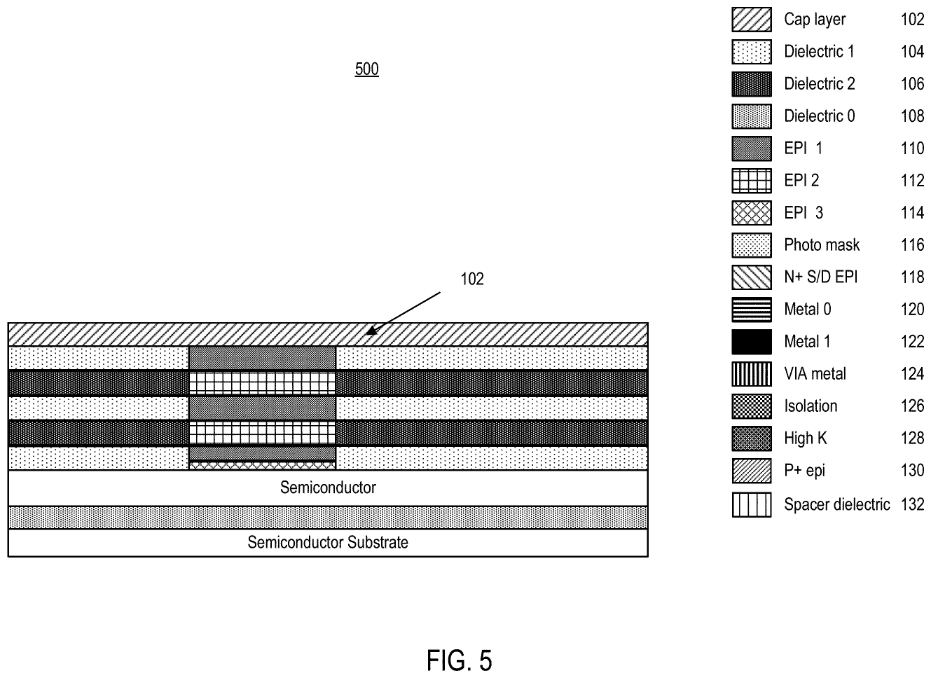

FIG. 5 illustrates a cross-sectional view 500 of the next stage in the process flow. After forming or growing the second stack including the semiconductor materials 110, 112, 114, the capping layer 102 can be deposited above the second stack using at least one suitable deposition technique. Any overburden can be removed by a chemical-mechanical planarization (CMP) process. Accordingly, the capping layer 102 can be disposed above the top surface of the dielectric material 104 (e.g., an upper first dielectric layer) and the semiconductor material 110 (e.g., the upper first semiconductor layer).

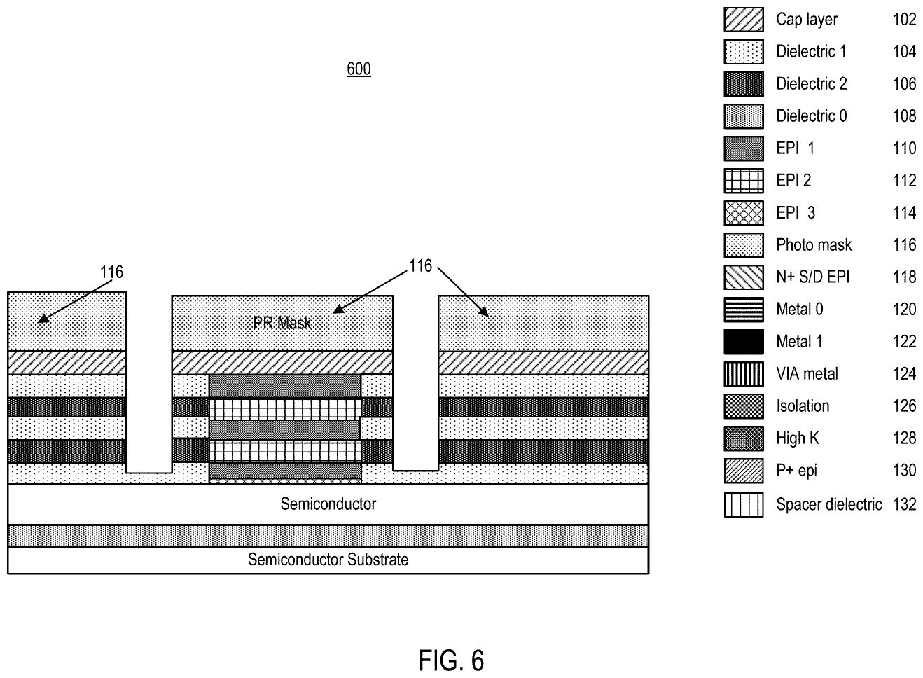

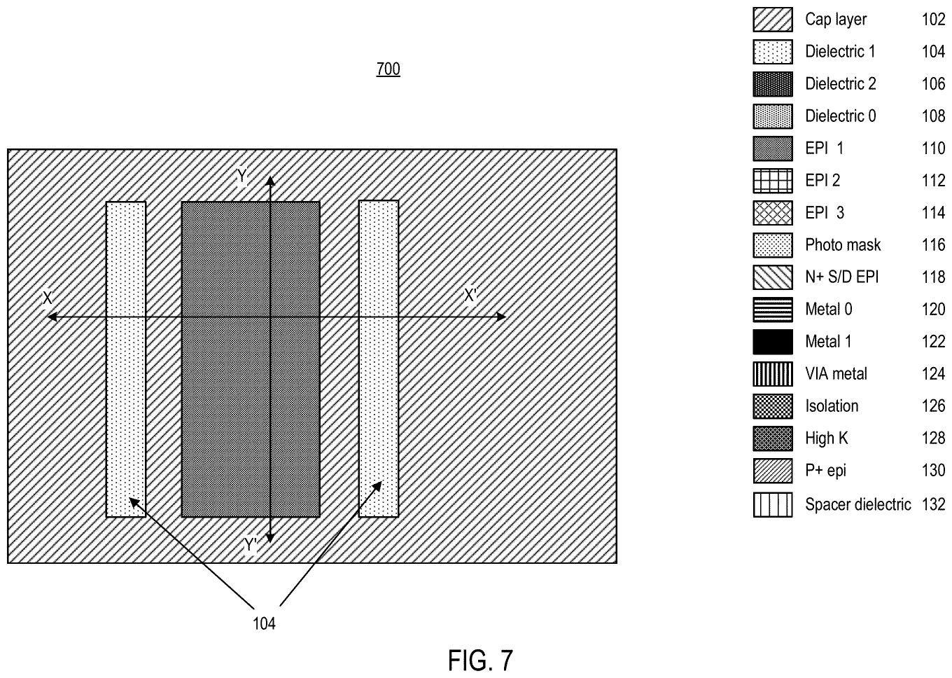

FIG. 6 illustrates a cross-sectional view 600 of the next stage in the process flow. A mask can be deposited above portions (e.g., second portions) of the first stack. FIG. 7 illustrates a top view 700 corresponding to the cross-sectional view 600 of FIG. 6. The mask can be patterned to have at least one opening. As shown, for example, the mask can be patterned to have openings on opposite sides of the second stack. The second portion of the first stack can be etched or removed to form vertical channels along the openings of the mask. Subsequent to the etching process, a predetermined horizontal length of the dielectric materials 104, 106 (e.g., dielectric overhang) can be obtained or remained at opposite sides of the semiconductor materials 110, 112. The dielectric overhang can be associated with the source and drain sides of the semiconductor device. The channel openings at the second portion of the first stack can vertically extend from the surface of the capping layer 102 to at least a portion of a lower layer of the dielectric materials 104 (e.g., a lower first dielectric layer), adjacent to the substrate. The (e.g., inner) sidewalls of the dielectric materials 104, 106 can be exposed via the opening.

In some implementations, one or more dielectric spacers can be formed or used, such as instead of the mask, to form the channel openings at the second portion of the first stack. The width of the dielectric spacer (or the pattern of the mask) can be configured to obtain desired width(s) for the channel openings. In various arrangements, the lower dielectric layer (e.g., lower one of the dielectric materials 104) can be left or remain substantially intact to form the second portion of the first stack. The top surface of the dielectric material 104 can be exposed via the channel openings.

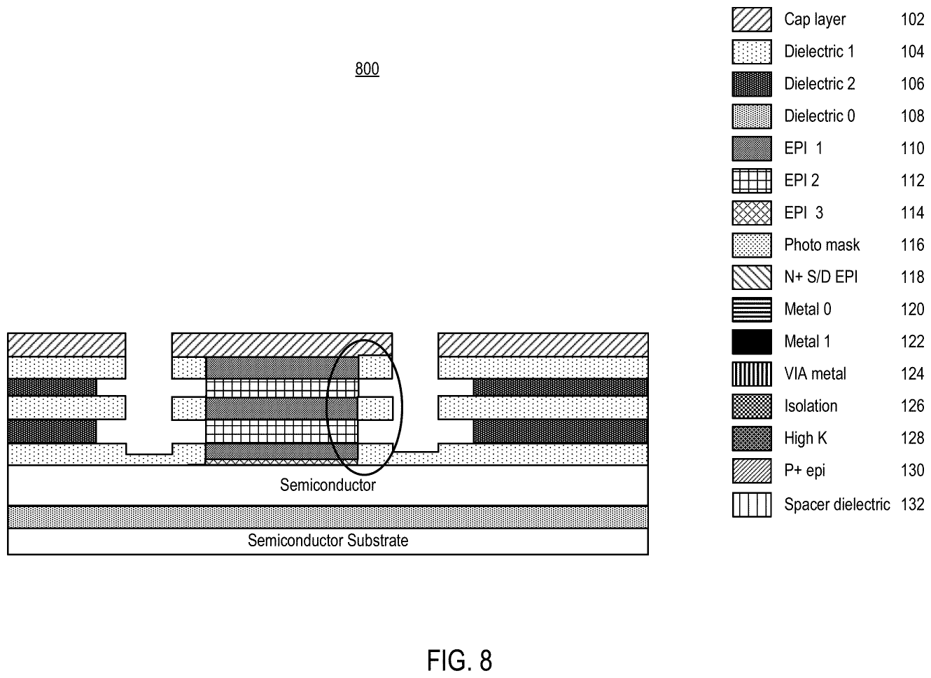

FIG. 8 illustrates a cross-sectional view 800 of the next stage in the process flow. After forming the channel openings at the second portion of the first stack, a portion of the dielectric material 106 can be horizontally etched. As shown, the dielectric material 106 (e.g., the upper and lower second dielectric layers) is selectively etched via the channel opening to form horizontal/lateral openings having a predetermined lateral distance/length. For example, the dielectric material 106 (e.g., upper and lower second dielectric layers) surrounding the sides of the semiconductor materials 112 (e.g., upper and lower second semiconductor layers) can be etched to expose the sidewalls or edges of the semiconductor materials 112.

In some arrangements, the lateral etching operation can include two or more sub-operations. For example, a first sub-operation can include etching a first portion of the dielectric materials 106 adjacent to the second stack, and a second sub-operation can include etching a second portion of the dielectric materials 106 across the channel opening from the first portion of the dielectric materials 106. The lateral distance of the lateral etching operation can be predetermined up to the desired distance, for example. The recess etching laterally reduces the dimension of the layers of the semiconductor device. The reduction in lateral dimension can create a lateral channel opening for depositing additional materials or structures. These additional materials can be structured to (e.g., electrically) connect to the semiconductor materials 112 (e.g., materials to form the source or drain of the semiconductor device).

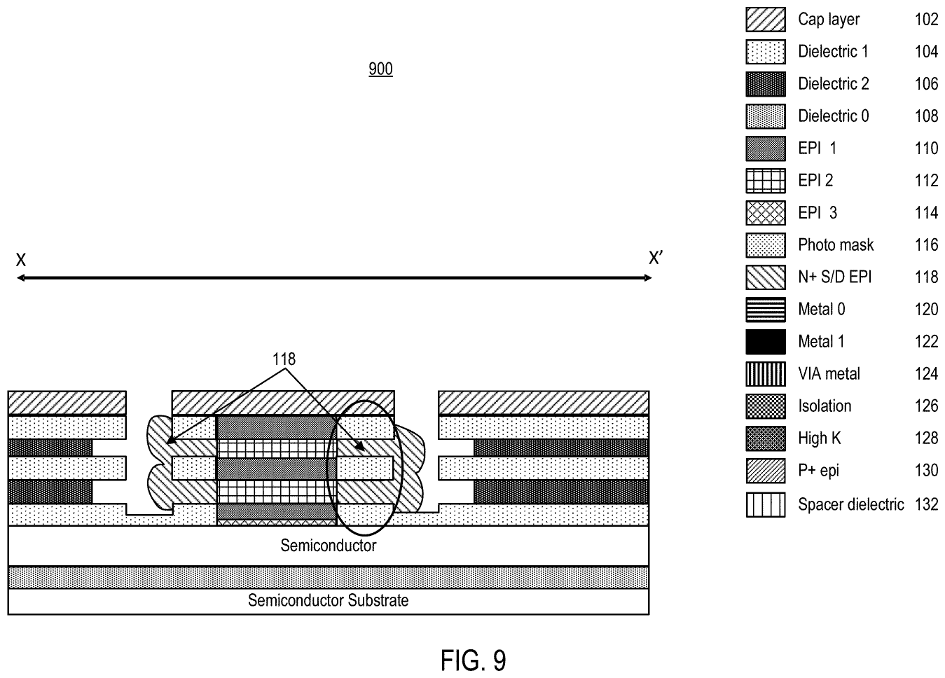

FIG. 9 illustrates a cross-sectional view 900 of the next stage in the process flow. After the lateral etching operation, epitaxial materials 118 (e.g., shown in the legend as “N+S/D EPI”, sometimes referred to as epitaxial structures or extensions) can be grown, deposited, or formed in the opening, such as the lateral opening exposing the sidewalls of the semiconductor material 112. Growing epitaxial material 118 can provide the S/D regions for the semiconductor device. The epitaxial material 118 can be formed through the removed second portion of the first stack to fill the lateral opening (e.g., grown from the Si channel or the dielectric material 104, not grown from dielectric material 106). In some cases, the epitaxial material 118 may extend or fill at least a portion of the vertical channel opening formed at the second portion of the first stack. The epitaxial material 118 can be in (e.g., electrical) contact with the semiconductor materials 112. For example, a pair of the epitaxial material 118 (e.g., a pair of first epitaxial structures) can be formed in (e.g., electrical) contact with the lower one of the semiconductor materials 112. A pair of the epitaxial material 118 (e.g., a pair of second epitaxial structures) can be formed in (e.g., electrical) contact with the upper one of the semiconductor materials 112. Hence, the epitaxial materials 118 can be in (e.g., electrical) contact with the exposed sidewalls of the semiconductor materials 112. The epitaxial material 118 can be deposited into one or more portions of the opening via at least one suitable deposition technique.

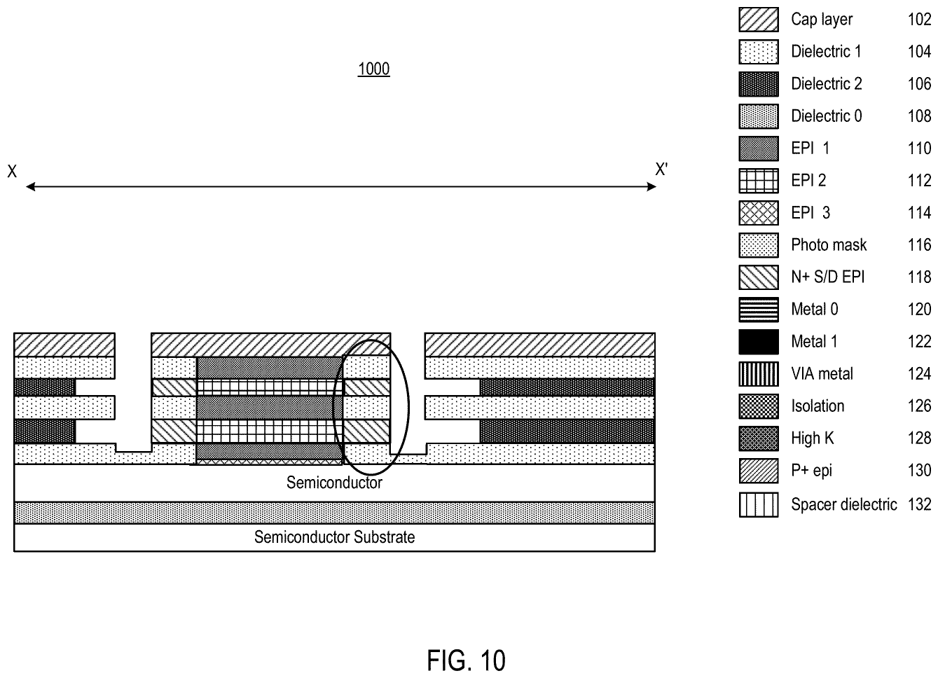

FIG. 10 illustrates a cross-sectional view 1000 of the next stage in the process flow. In some implementations, the epitaxial material 118 can be formed and etched from the channel opening at the second portion of the first stack. For example, the epitaxial material 118 exposed to the vertical channel opening can be etched using at least one suitable etching technique. By removing the epitaxial material 118 in the vertical channel opening, the exposed sidewalls of the epitaxial material 118 can be flushed with at least the exposed side walls of the dielectric material 104 (e.g., upper, middle, or lower first dielectric layers) adjacent to or in (e.g., electrical) connection with respective structures/materials/layers of the second stack. In some cases, the exposed sidewalls of the epitaxial material 118 can be aligned with the respective sidewall of the capping layer 102.

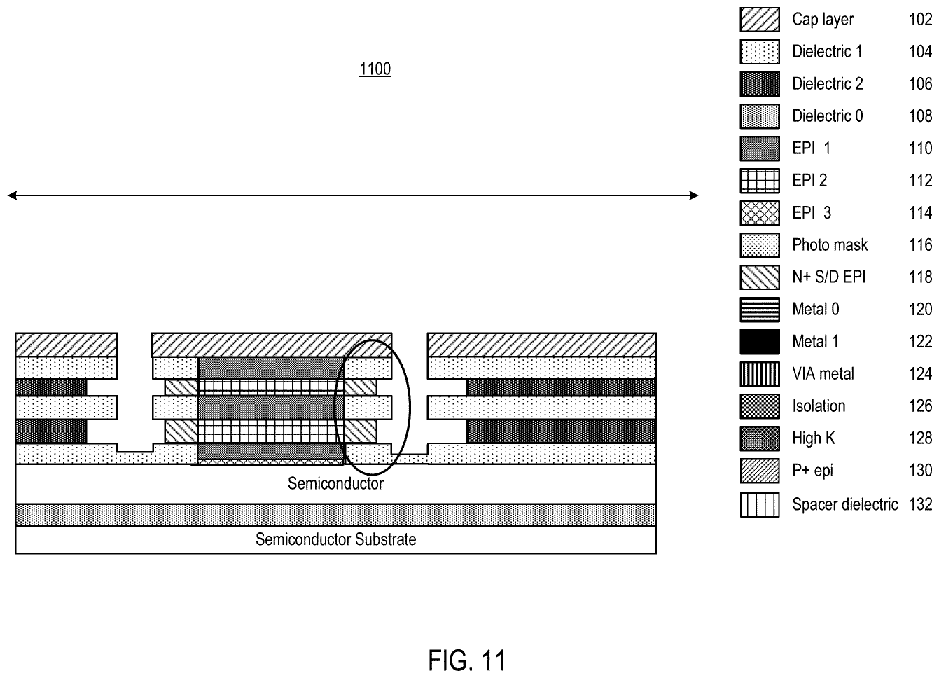

FIG. 11 illustrates a cross-sectional view 1100 of the next stage in the process flow. In some implementations, the epitaxial material 118 (e.g., epitaxial extension or structure) can be grown laterally in the lateral channel opening, such that the epitaxial material 118 extend or include a lateral distance of less than the distance of the lateral channel opening. As shown, the epitaxial material 118 may not be grown to the edge of the cavity of the dielectric material 104 (e.g., which may define or represent the sides of the vertical channel opening at the second portion of the first stack). For simplicity, the operations discussed herein can be performed subsequent to growing the epitaxial material 118 described in FIG. 11. In various other implementations, similar operations can be performed subsequent to growing the epitaxial material 118 described in at least one of FIG. 9 or 10, for example.

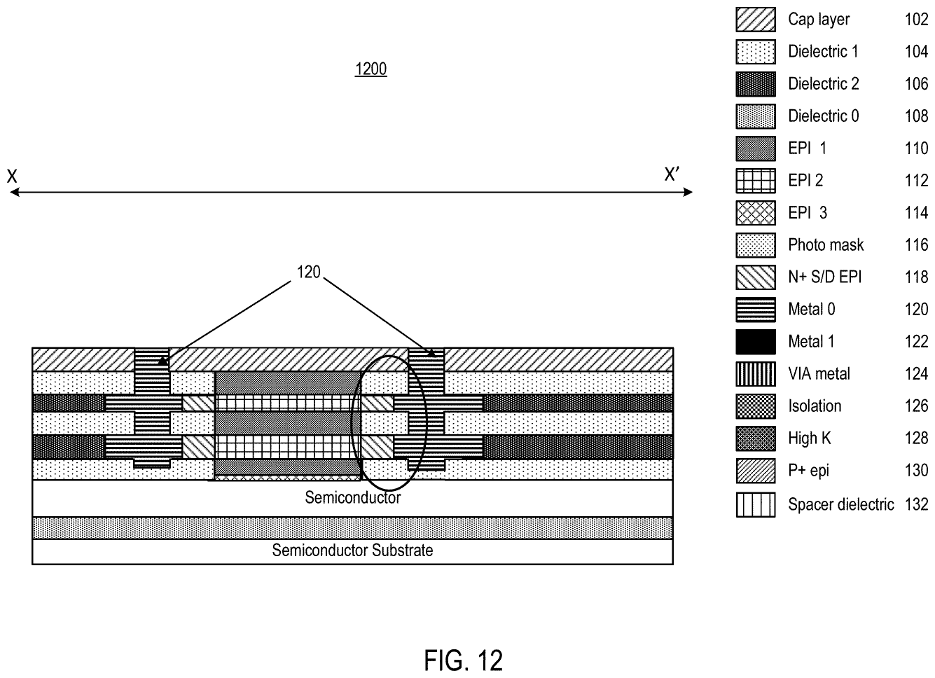

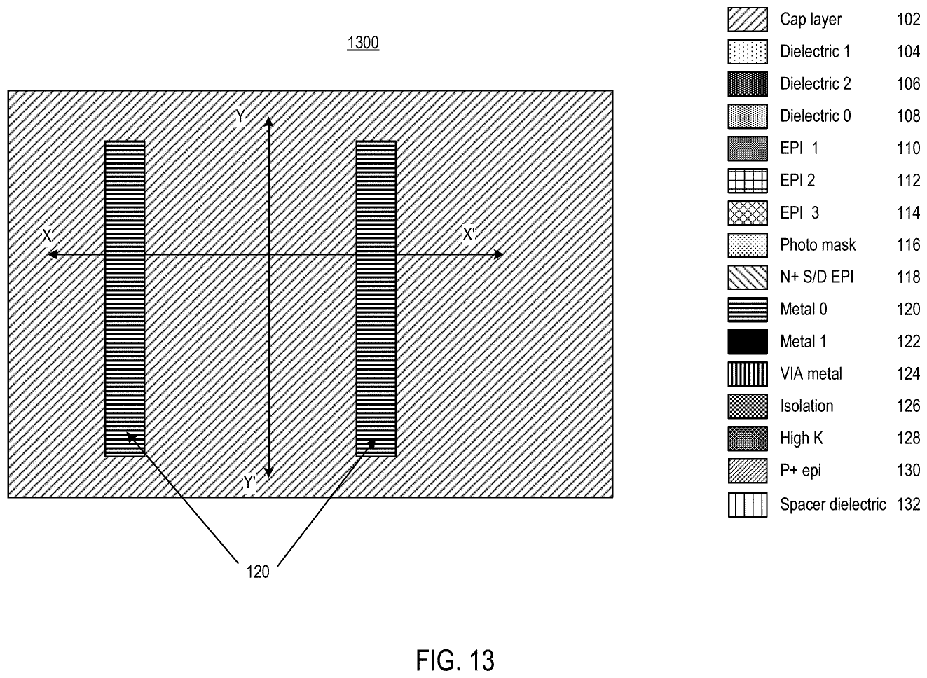

FIG. 12 illustrates a cross-sectional view 1200 of the next stage in the process flow. FIG. 13 illustrates a top view 1300 corresponding to the cross-sectional view 1200 of FIG. 12. Subsequent to growing the epitaxial material 118, metal materials 120 (e.g., shown in the legend as “Metal 0”, sometimes referred to as metal structures) can be deposited to fill the opening (e.g., remaining vertical and/or lateral openings) at the second portion of the second stack. The metal material 120 can be disposed in the channel using at least one suitable deposition technique. The metal material 120 can be composed of any suitable conductive material, such as Cu, Al, W, Ti, TiN, Ta, TaN, or multiple layers or combinations thereof. The metal material 120 can fill the lateral and vertical openings, such that the remaining opening or gap within the semiconductor device is filled with the metal material 120. The metal material 120 can extend vertically to align with the surface of the capping layer 102. In some cases, the metal material 120 can be etched to be flushed with the surface of the capping layer 102. Although FIG. 12 shows the deposition of the metal material 120 with the grown epitaxial material 118 described in FIG. 11, other methods of growing the epitaxial material 118 can be used prior to deposition of the metal material 120, such as described in conjunction with FIGS. 9-10, for example.

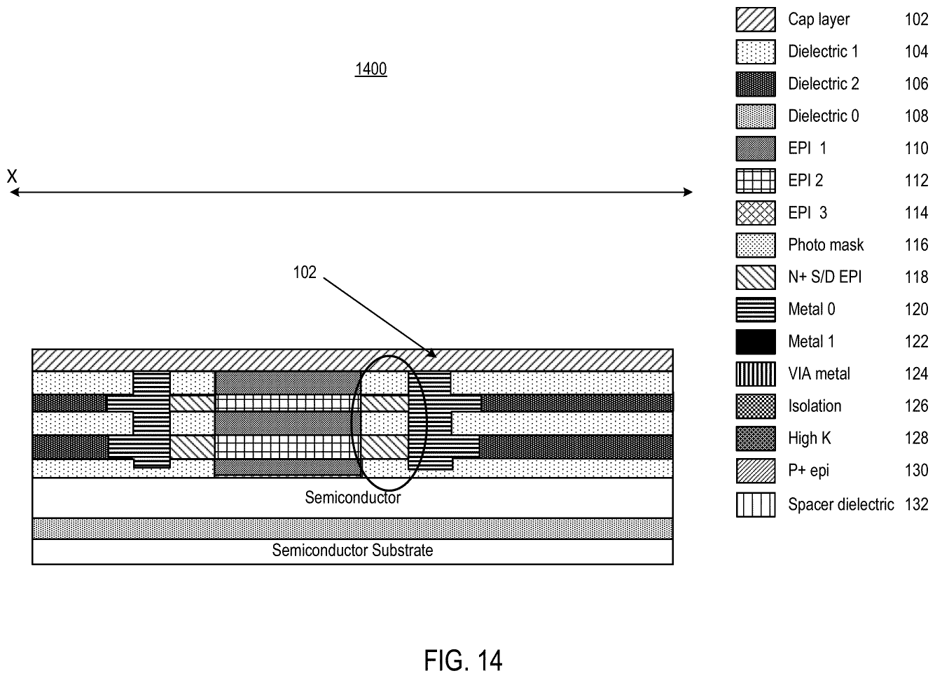

FIG. 14 illustrates a cross-sectional view 1400 of the next stage in the process flow. The epitaxial material 118 can be grown in accordance with or as described in at least one of FIGS. 9-11. After depositing the metal material 120, the height of the metal material 120 can be reduced via at least one suitable etching technique. For example, the height of the metal material 120 can be reduced down to the top surface of the upper first dielectric layer (e.g., the upper one of the dielectric materials 104 or dielectric layers). Subsequently, the capping layer 102 can be deposited into the removed portion of the metal material 120. In this case, the deposited capping layer 102 can seal the S/D side of the semiconductor device.

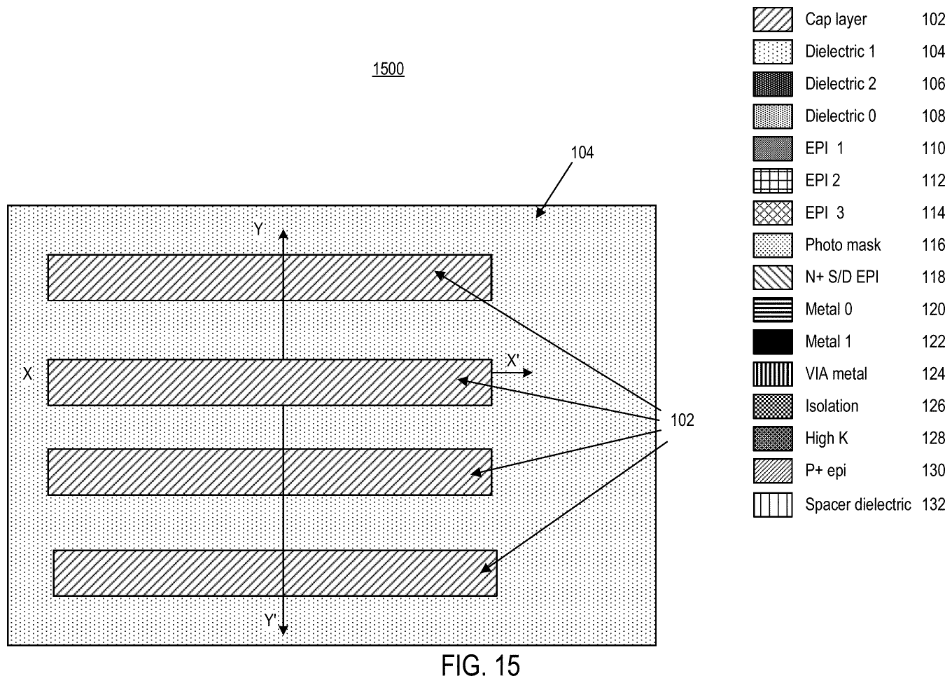

FIG. 15 illustrates a top view 1500 of the next stage in the process flow. After depositing the capping layer 102, the capping layer 102 can cover the top surfaces of the various structures discussed herein. In various implementations, the capping layer 102 can be etched using at least one suitable etching technique, such as a mask having a predetermined pattern. As shown, the capping layer 102 can be etched to define the y-dimension (e.g., the width) of individual 3D nanosheets (e.g., semiconductor devices). The y-dimension can be predetermined based on the configuration or the specification of the semiconductor device, for example. In some cases, the y-dimension of the individual nanosheets may be similar to one another. In some other cases, the y-dimension of at least one certain nanosheet may be different from at least one other nanosheet. Although four nanosheets are shown, additional nanosheets can be constructed or structured using similar operations described herein, for example.

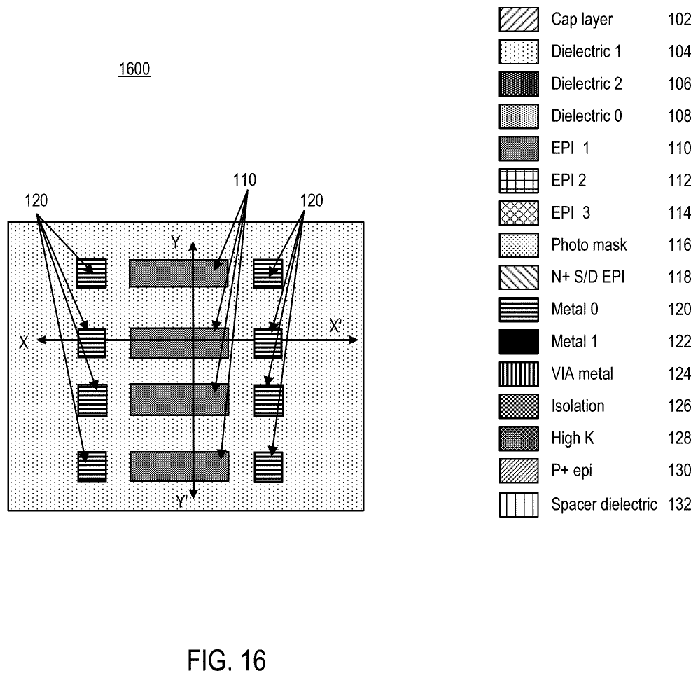

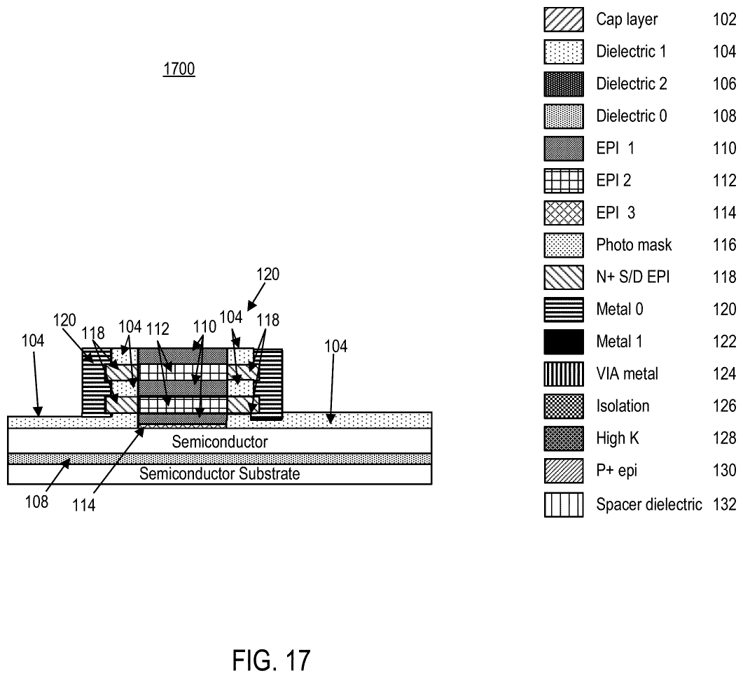

FIG. 16 illustrates a top view 1600 of the next stage in the process flow. FIG. 17 illustrates a cross-sectional view 1700 corresponding to the top view 1600 of FIG. 16. In various arrangements, the top view 1600 and the cross-sectional view 1700 show the structures without the capping layer 102 (e.g., although the capping layer 102 can remain above the semiconductor device). In some implementations, various portions of the first stack can be etched or removed, such as by using at least one suitable etching technique. For example, as shown in FIG. 17, portions of the first stack surrounding or located at the sides of the metal materials 120 can be removed. In this case, the removed portions of the first stack can extend from the upper first dielectric layer to at least the lower first dielectric layer (e.g., lower one of the dielectric materials 104). As shown, at least a portion of the lower first dielectric layer can remain subsequent to removing the various portions of the first stack at the sidewall of the metal material 120 facing opposite from the second stack.

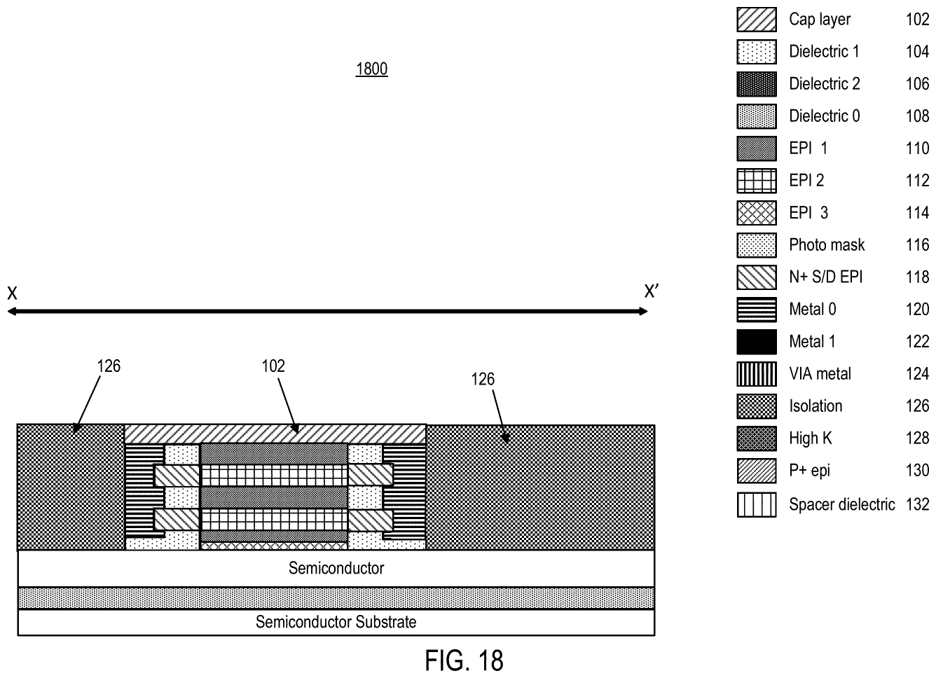

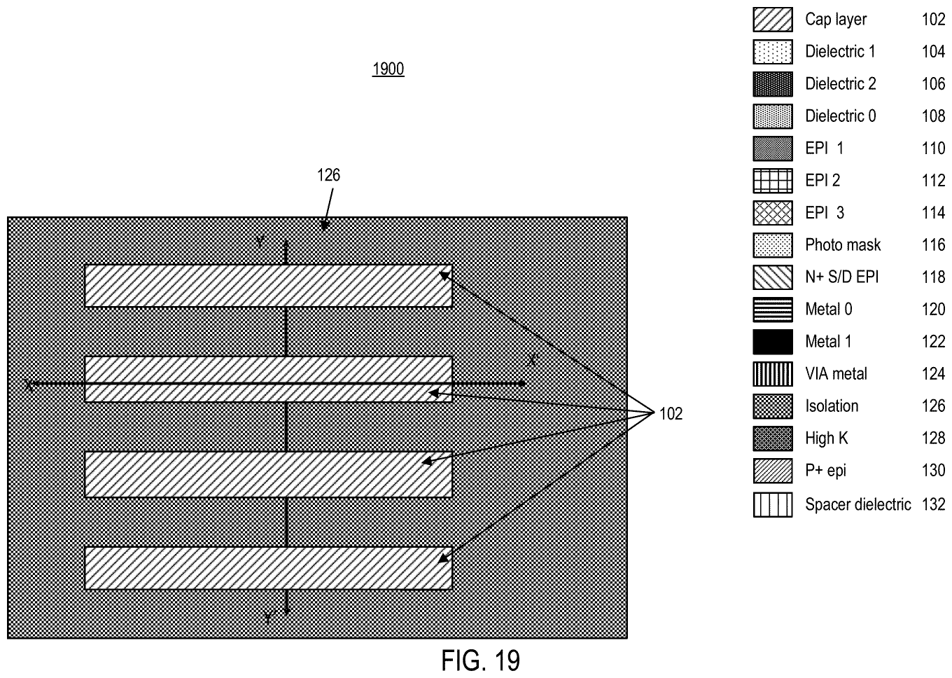

FIG. 18 illustrates a cross-sectional view 1800 of the next stage in the process flow. FIG. 19 illustrates a top view 1900 corresponding to the cross-sectional view 1800 of FIG. 18. In various implementations, the capping layer 102 can be maintained above the stacks (e.g., first and second stacks of structures, materials, or layers). After removing the portions of the first stack, an isolation material 126 can be deposited, such that the sidewalls of at least one of the metal materials 120 and/or the lower dielectric material 104 can be in contact with the isolation material 126. Deposition of the isolation material 126 can be performed using at least one suitable selective deposition technique. In some cases, such as in FIG. 19, the capping layer 102 may be deselected over the channel region (e.g., at least one of semiconductor materials 110, 112, etc.) The isolation material 126 can be composed of any suitable material for isolating or insulating one material from another. In this case, the stacks or the various materials/structures (e.g., under the capping layer 102) can be isolated from other materials by the isolation material 126. In some implementations, the isolation material 126 can be deposited (e.g., directly) above the surface of the semiconductor substrate (e.g., in contact with the semiconductor substrate). In some other implementations, the isolation material 126 can be deposited above at least a portion of the lower dielectric material 104 (e.g., the remaining portion of the lower first dielectric layer), for example.

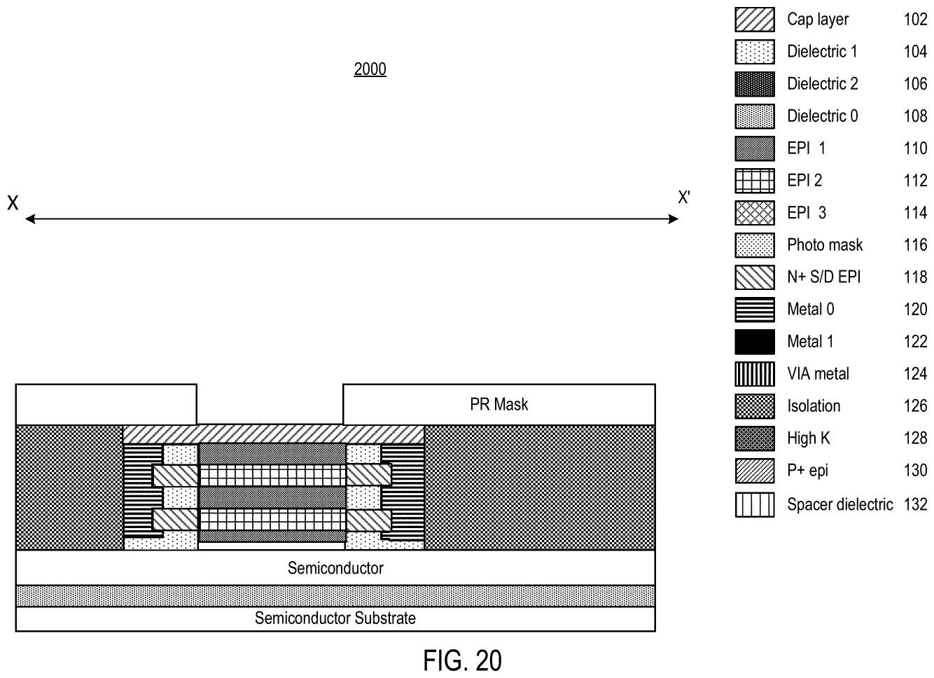

FIG. 20 illustrates a cross-sectional view 2000 of the next stage in the process flow. A mask can be deposited on or above the surface of the semiconductor device. The mask (e.g., mask material 116) can include a predetermined/predefined pattern. For instance, the pattern may include an opening aligning with at least a portion of the second stack. The semiconductor material 114 can be removed or etched using at least one suitable etching technique, for instance, including the use of the mask. At this stage, as shown in FIG. 20, a gap between the lower semiconductor material 110 and the semiconductor substrate (e.g., below the second stack) is created at the removed semiconductor material 114 portion of the second stack.

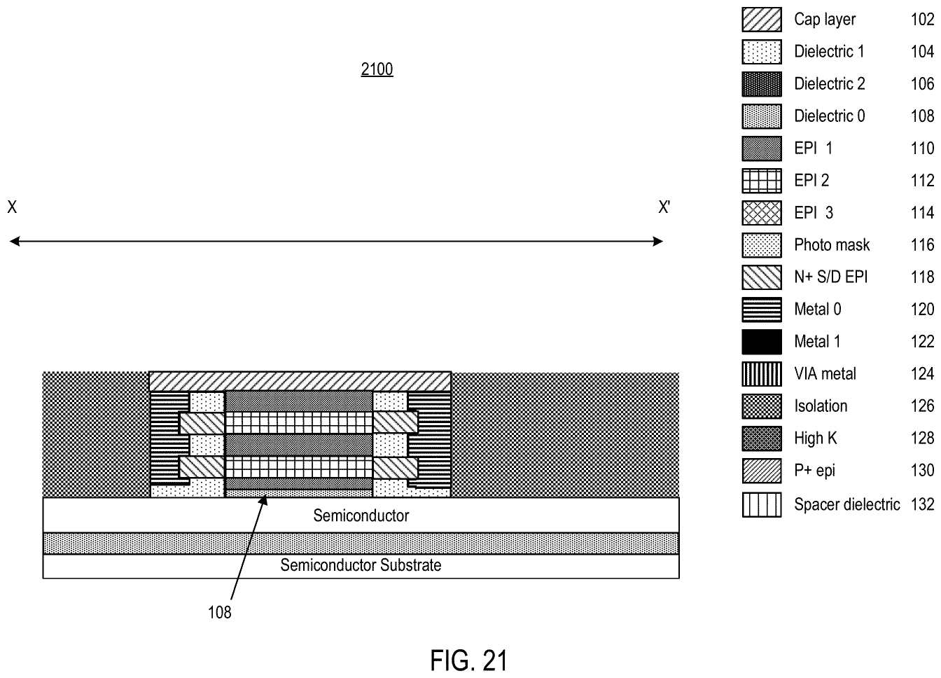

FIG. 21 illustrates a cross-sectional view 2100 of the next stage in the process flow. After removing the semiconductor material 114, the dielectric material 108 can be deposited to fill the gap (or opening) created by removing the semiconductor material 114. The dielectric material 108 can be deposited using at least one suitable deposition technique. Upon its deposition, the dielectric material 108 can be self-aligned with the capping layer 102. The dielectric material 108 isolates the second stack (e.g., including at least the semiconductor materials 110, 112, etc.) from the semiconductor substrate.

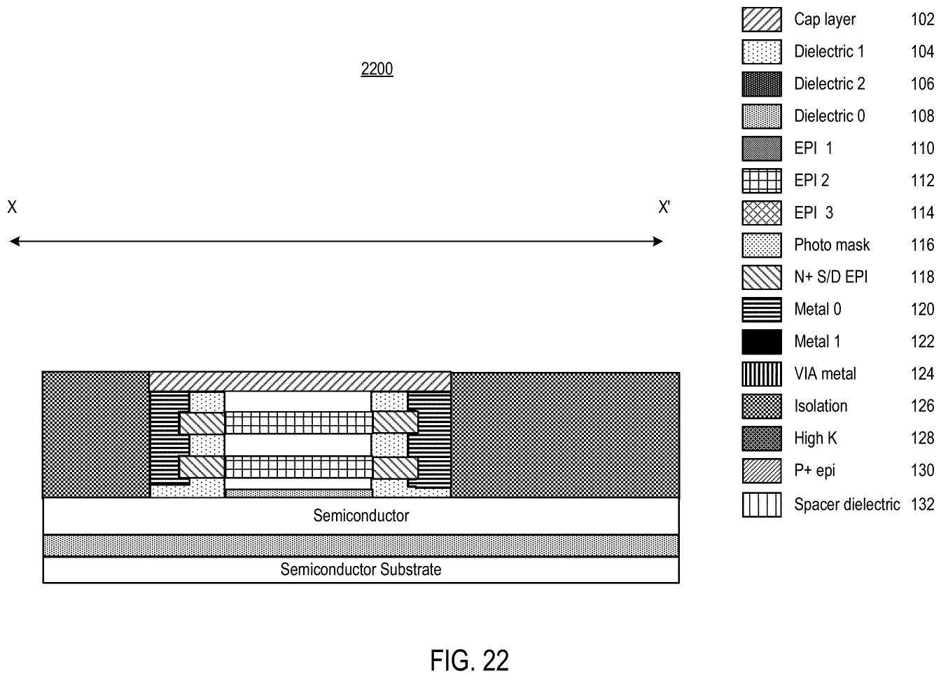

FIG. 22 illustrates a cross-sectional view 2200 of the next stage in the process flow. The semiconductor materials 110 (e.g., spacer layer) can be removed using at least a suitable etching technique. The semiconductor material 110 can assist with aligning the channel and S/D region with the gate structure, as described herein. In this case, removing the semiconductor materials 110 exposes the surfaces (e.g., top and/or bottom surfaces) of the semiconductor material 112.

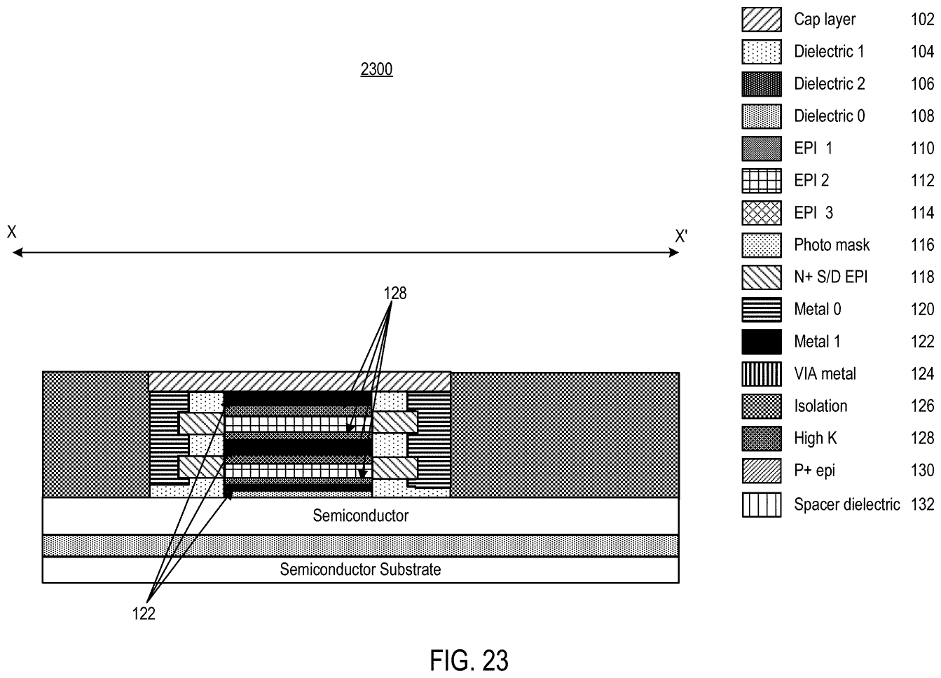

FIG. 23 illustrates a cross-sectional view 2300 of the next stage in the process flow. After removing the semiconductor materials 110, the removed portion of the second stack can be replaced or filled with metal material 122 (e.g., shown in the legend as “Metal 1,” sometimes referred to as a gate metal material) and high-k dielectric material 128 (e.g., shown in the legend as “High K”). The metal material 122 and/or the high-k dielectric material 128 can be deposited using at least one suitable deposition technique. The metal material 122 can be composed of any types of conductive material, which may be similar to or different from the metal material 120. In some arrangements, the metal material 122 may be used for an NMOS gate, or other types of gate (e.g., according to the type of transistors).

The high-k dielectric material 128 can be in (e.g., vertical) contact with at least one of the metal material 122 and the semiconductor material 112. The metal material 122 can be in connection or contact with at least one of the high-k dielectric material 128, the capping layer 102 (e.g., the top most metal material 122), or the dielectric material 108. The high-k dielectric material 128 can be composed of any suitable materials having a high dielectric constant, such as compared to certain dielectric materials.

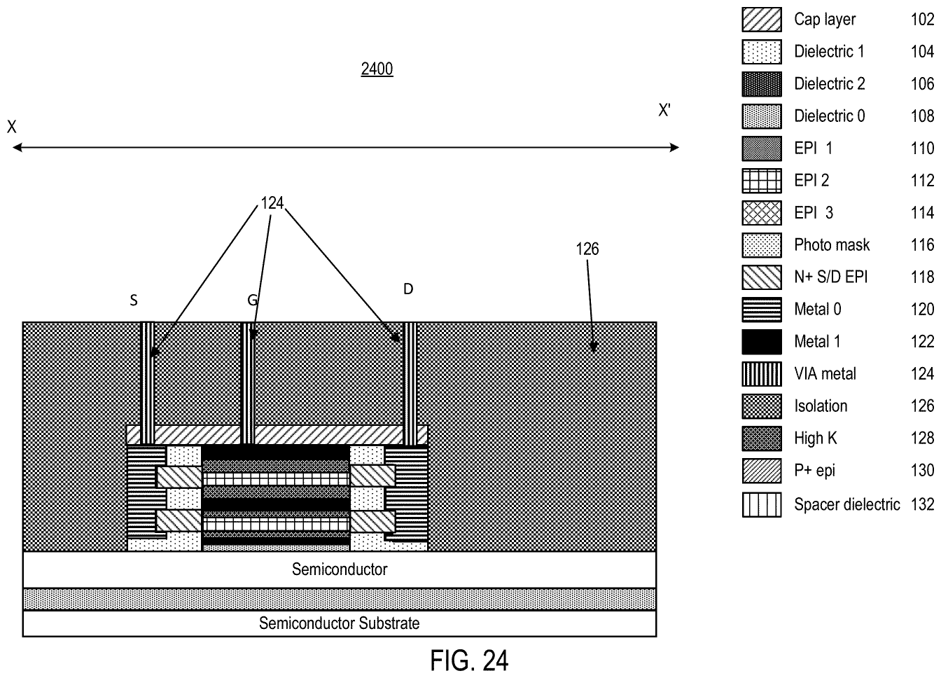

FIG. 24 illustrates a cross-sectional view 2400 of the next stage in the process flow. After depositing the metal material 122 and the high-k dielectric material 128, one or more via structures 124 (e.g., shown in the legend as “VIA metal,” sometimes referred to as a through channel or via material, etc.) can be formed. The via structure 124 can be composed of any suitable conductive material. As shown, the via structures 124 can be extended from the surface of the isolation material 126 to respective portions of the semiconductor device. For example, after the deposition of the metal material 122 and the high-k dielectric material 128, the isolation material 126 can be deposited above the semiconductor device using at least one suitable deposition technique. Various channels or openings can be etched using at least one suitable etching technique.

For instance, a channel may extend from the surface of the isolation material 126 to one of the metal materials 120 corresponding to one of the source or the drain of the semiconductor device. Similarly, another channel may extend from the surface of the isolation material 126 to another one of the metal materials 120 (e.g., on opposite side of the second stack) corresponding to another one of the source or the drain of the semiconductor device. Yet another channel can be etched extending from the surface of the isolation material 126 to at least a portion of the metal material 122 (e.g., corresponding to a gate structure of the semiconductor device).

In further example, the one or more channels can be filled with the via structures 124. The via structures 124 can each (e.g., electrically) connect to at least one of the respective metal materials 120 and the metal material 122. The via structures 142 can route the respective materials to above the isolation material 126, such as for (e.g., electrical) connection with other materials or devices. Hence, the via structures 124 can provide connections from various devices or structures to the respective source (e.g., one of the sides of the metal material 120), drain (e.g., the other one of the sides of the metal material 120), and/or gate of the semiconductor device (e.g., the top/upper metal material 122).

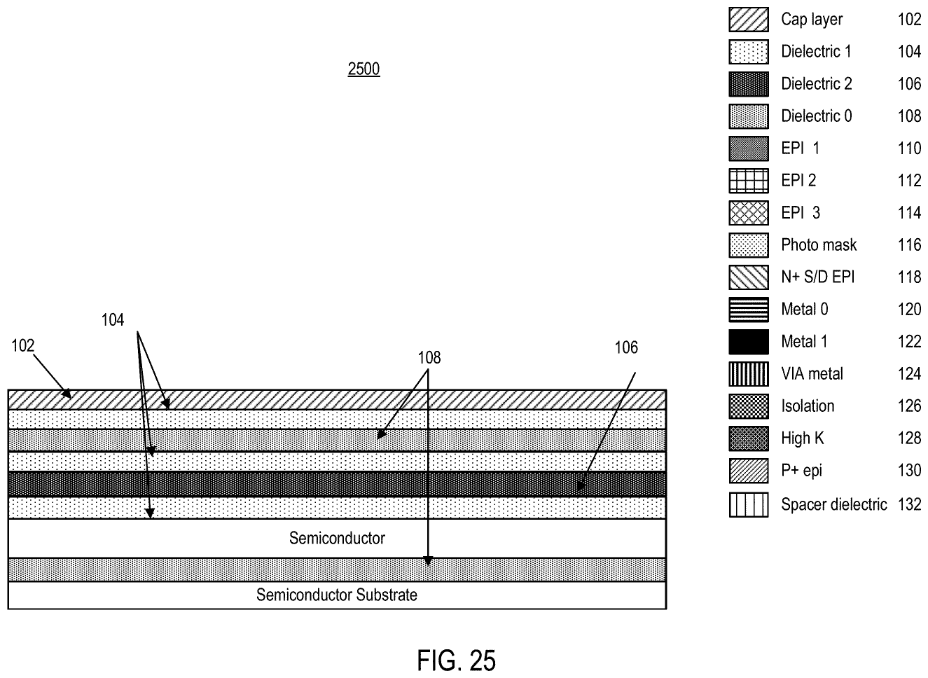

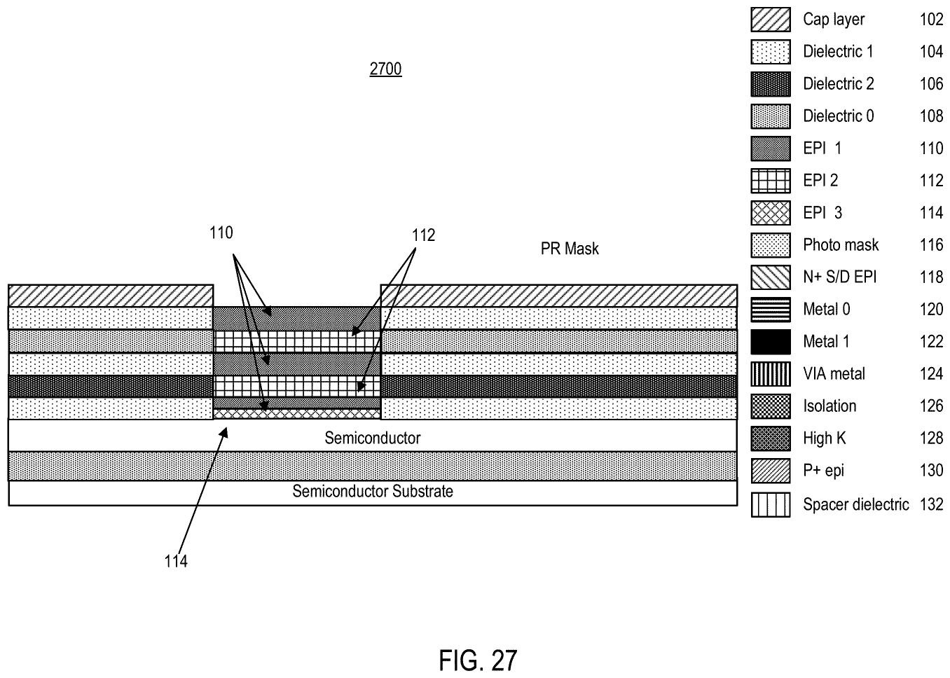

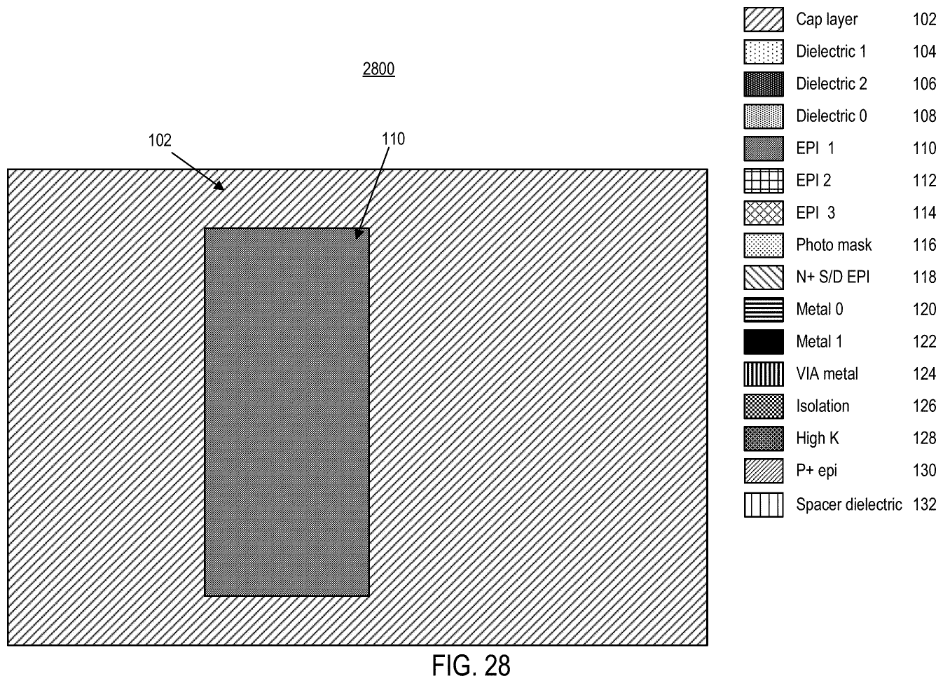

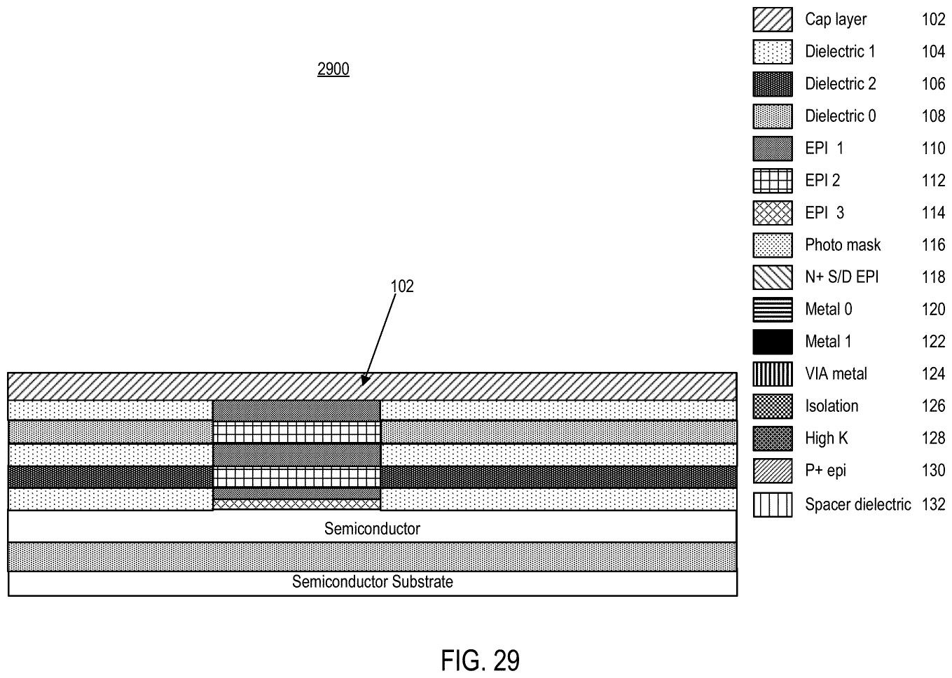

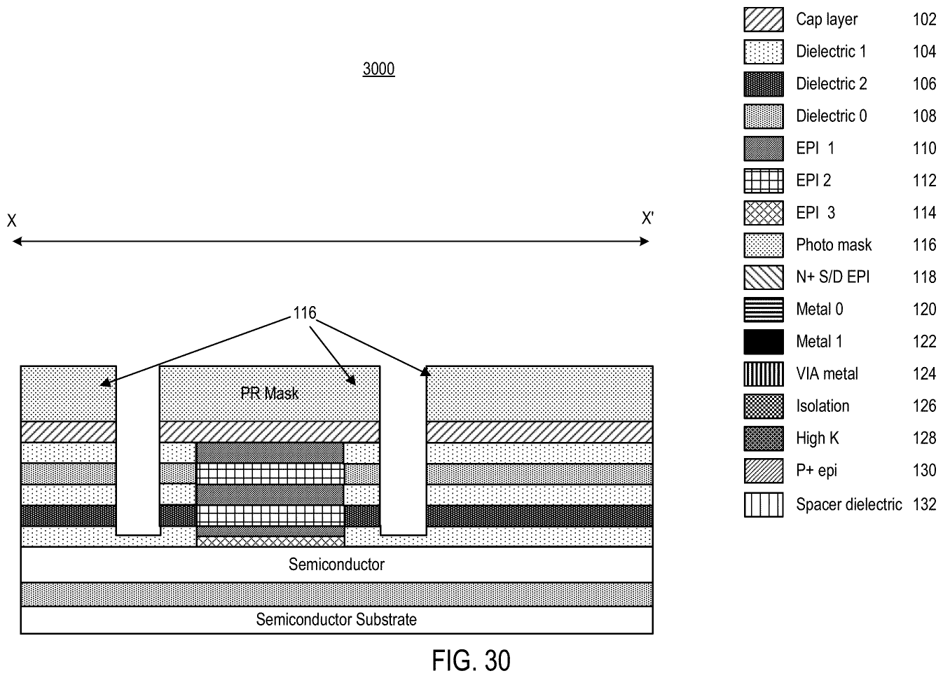

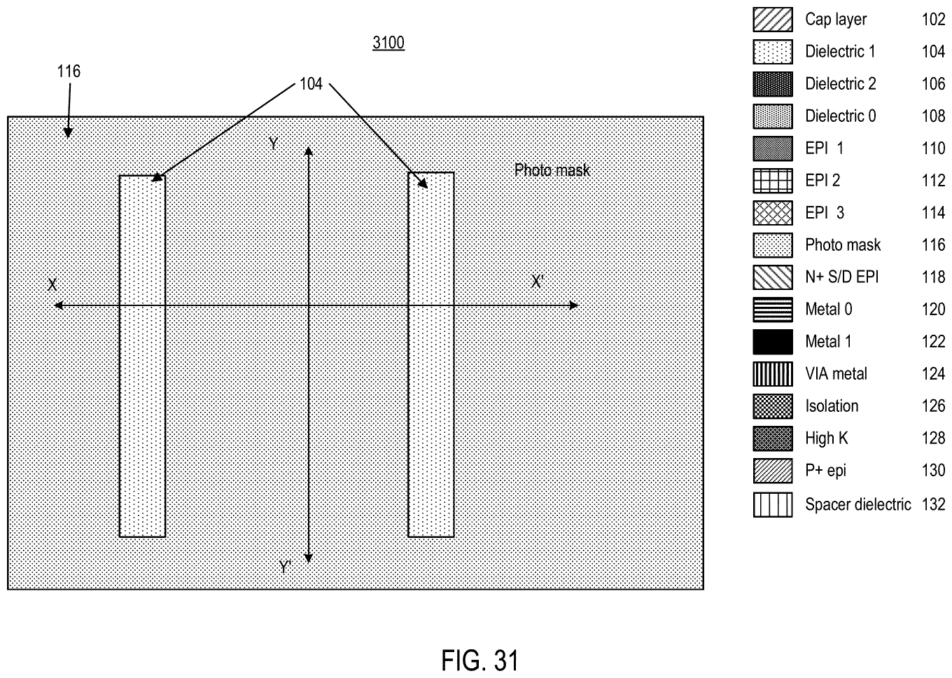

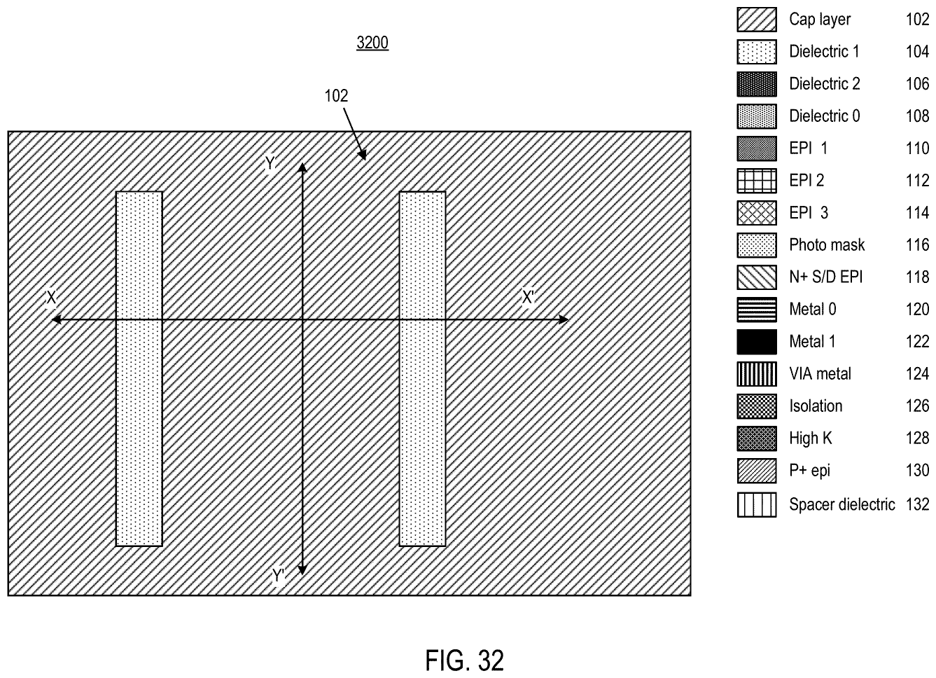

FIGS. 25-46 show various views 2500-4600 of a second process flow to manufacture semiconductor devices with S/D extensions. Each of FIGS. 25-46 generally refer to one or more process steps in a process flow, each of which are described in detail in connection with a respective Figure. For the purposes of simplicity and ease of visualization, some reference numbers may be omitted from some Figures. In FIGS. 25-46, an example process flow is described to manufacture a 3D stacking device with S/D extension using a channel trench nanosheet formation (CFET) N=2 inverter flow, where a gate electrode can be tied/coupled together for NMOS and PMOS.

The second process flow of FIGS. 25-46 can include operations, features, constructions, structures, or processes similar to one or more operations described in conjunction with at least one of FIGS. 1-24. For example, the operations of the second process flow can be performed using one or more similar techniques (e.g., etching, deposition, etc.) as at least FIGS. 1-7 of the first process flow.

FIG. 25 illustrates a cross-sectional view 2500 of a semiconductor device in which various layers, including various materials (e.g., dielectric materials), are formed over at least one semiconductor substrate. The operations (e.g., formation of the first stack) of FIG. 25 can be performed similar to the operations described in FIG. 1, for example. In this case, the first stack of the semiconductor device can include the capping layer 102 and dielectric materials 104, 106, 108. As shown, from the bottom to the top of the first stack above the semiconductor substrate, the first stack includes a lower one of the dielectric material 104, a dielectric material 106, a middle/center one of the dielectric material 104, a dielectric material 108, an upper one of the dielectric material 104, and the capping layer 102. In some cases, the capping layer 102 may not be a part of the first stack. Instead, the capping layer 102 can be another layer above the layers of the first stack. Hence, the first stack includes layers alternating between the dielectric materials 104 and both the dielectric materials 106, 108, in this case.

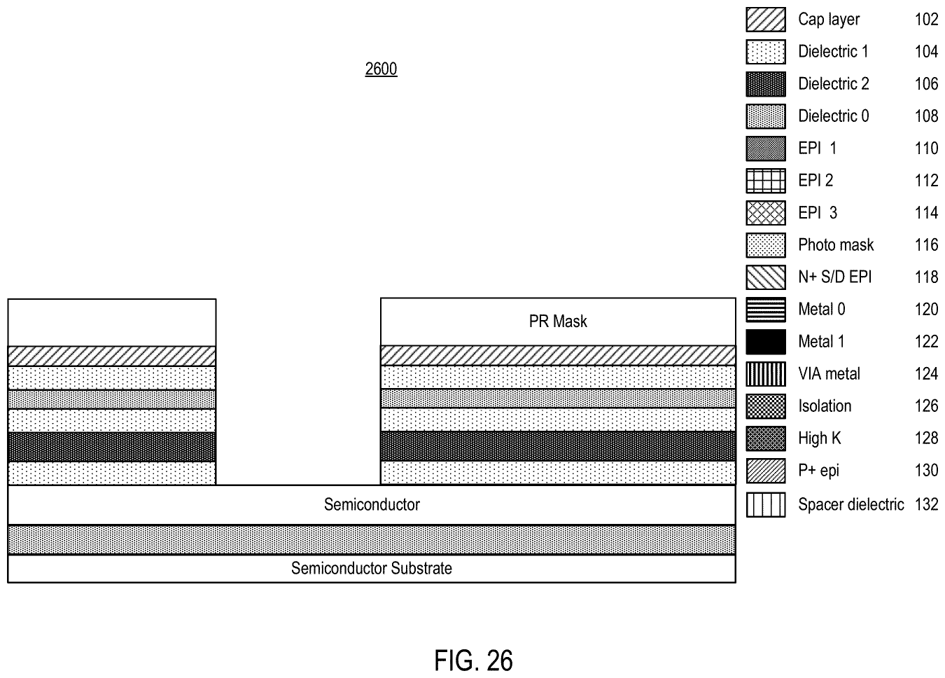

Subsequently, FIGS. 26-32 illustrate cross-sectional and top views 2600-3200 of the next stages in the process flow (e.g., second process flow). The operations corresponding to FIGS. 26-32 can be similar to the operations described in conjunction with FIGS. 2-7. For example, referring to the cross-sectional view 2600, after forming the first stack, a portion (e.g., first portion) of the first stack can be removed or etched. The first portion can be removed using at least one suitable etching technique, such as using the photoresist (PR) mask (e.g., mask material 116). The first portion of the first stack can be removed using similar operation(s) described in conjunction with FIG. 2, for example.

Referring to cross-sectional view 2700 and the top view 2800, a second stack can be formed at the first portion of the first stack (e.g., filling the opening of the first stack). The second stack can be formed or grown using at least one suitable material formation technique, including epitaxial growth. The second stack can include at least one of the semiconductor materials 110, 112, 114. The semiconductor material 114 can be formed above the surface of the semiconductor substrate to isolate the semiconductor materials 110, 112 from the semiconductor substrate. The semiconductor material 114 may or may not be a part of the second stack. The semiconductor materials 110, 112 can be alternatively stacked on top of one another. For instance, from the semiconductor material 114 to the top of the second stack, the second stack includes a lower one of the semiconductor materials 110, a lower one of the semiconductor materials 112, a center/middle one of the semiconductor materials 110, an upper one of the semiconductor materials 112, and an upper one of the semiconductor material 110. The semiconductor materials 110 can laterally align, in part, with the dielectric materials 104 of the first stack. The lower one of the semiconductor materials 112 (e.g., lower second semiconductor layer) can laterally align, in part, with the dielectric material 106. The upper one of the semiconductor materials 112 (e.g., upper second semiconductor layer) can laterally align, in part, with the dielectric material 108.

Referring to cross-sectional view 2900, the capping layer 102 can be deposited above the surface of the second stack (e.g., above the upper one of the semiconductor material 110). The capping layer 102 can be deposited using at least one suitable deposition technique. Any overburden can be removed by a chemical-mechanical planarization (CMP) process (e.g., similar to the operation described in conjunction with FIG. 5).

Referring to cross-sectional view 3000 and top view 3100, at least one section portions (e.g., in this case two portions) of the first stack can be removed using at least one suitable etching technique. As shown, the mask material 116 is deposited above the capping layer and includes a pattern for etching the second portions of the first stack. Referring to top view 3200, the mask material 116 can be removed after completing the etching process. The etching of the second portions of the first stack can be described in conjunction with FIGS. 6-7, for example.

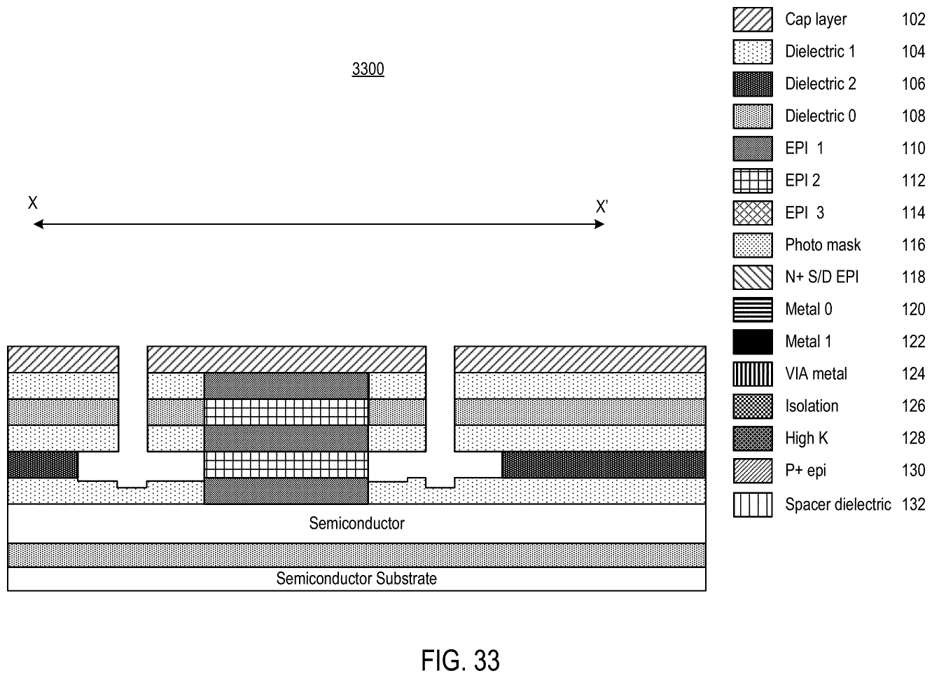

FIG. 33 illustrates a cross-sectional view 3300 of the next stage in the process flow. The operation corresponding to the cross-sectional view 3300 can be similar to the operation described in FIG. 8. For example, within the second portion (e.g., the vertical channel opening) of the first stack, a portion of the dielectric material 106 can be horizontally/laterally (e.g., selectively) etched (e.g., adjacent to an NMOS channel, in some cases). The dielectric material 106 can be etched using at least one suitable etching technique. After etching the dielectric material 106, the sidewalls/edges of the semiconductor material 112 (e.g., the lower second semiconductor layer) can be exposed.

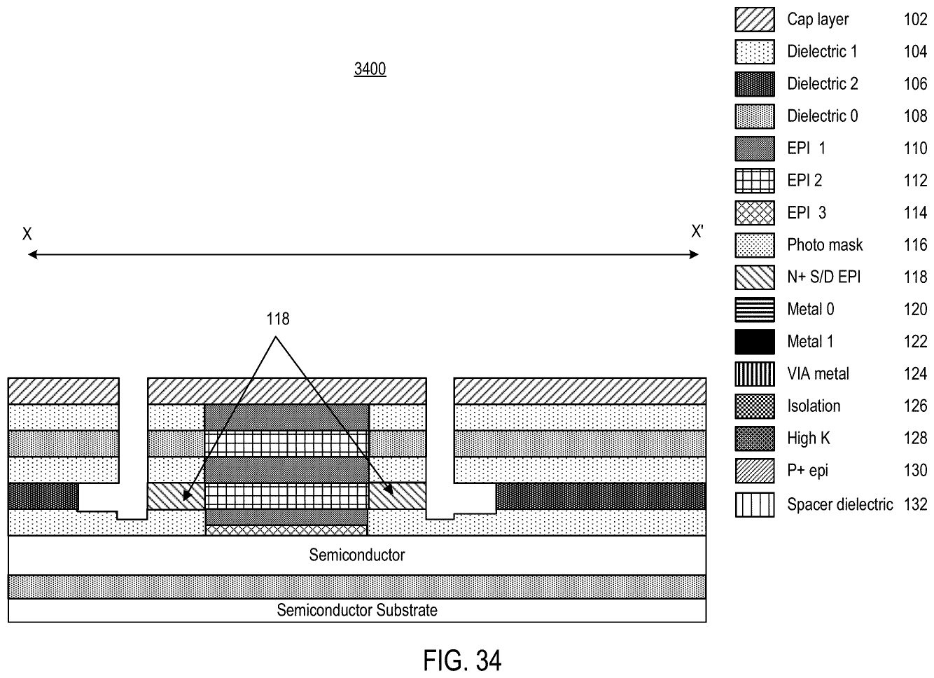

FIG. 34 illustrates a cross-sectional view 3400 of the next stage in the process flow. The operation corresponding the cross-section view 3400 can be similar to the operations described in conjunction with at least one of FIGS. 9-11. For example, after removing the dielectric materials 106, epitaxial materials 118 can be grown, deposited, or formed in the lateral opening. For purposes of providing an example, the epitaxial material 118, in this case, can be suitable for an NMOS device. For example, the epitaxial material 118 may have n-type dopants such as, for example, phosphorus, arsenic, etc. The epitaxial material 118 can be in contact with or coupled to the semiconductor material 112. In this case, at least one suitable etching technique can be used to remove excess epitaxial material 118 from the vertical opening at the second portion of the first stack. The edge or sidewall of the epitaxial material 118 can be flushed or vertically aligned with the edges of other structures, such as above or below the epitaxial material 118.

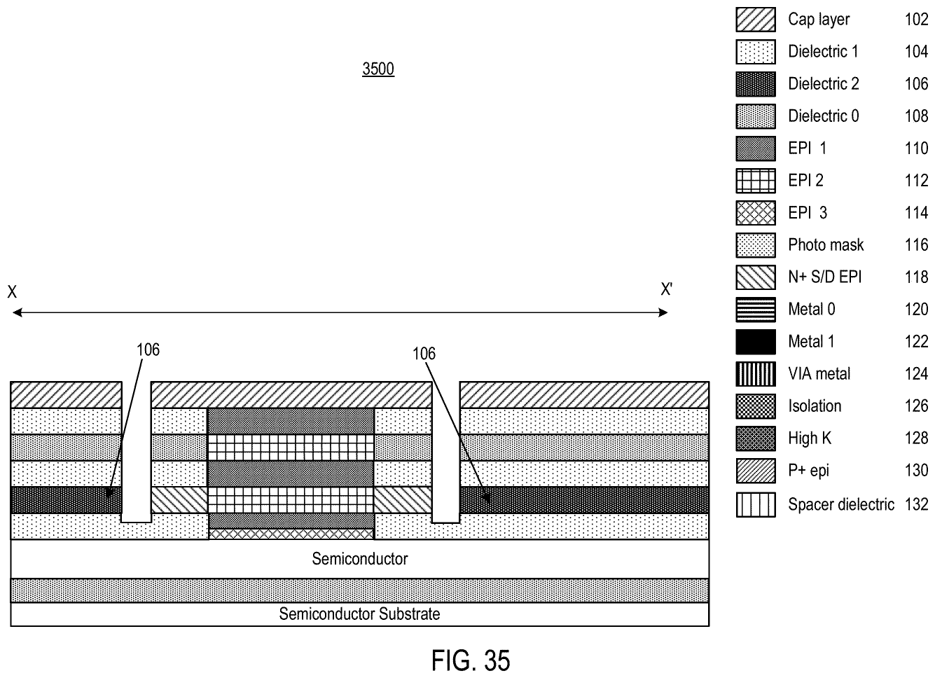

FIG. 35 illustrates a cross-sectional view 3500 of the next stage in the process flow. In various implementations, the dielectric material 106 can be deposited into the remaining lateral opening across from the epitaxial material 118 (e.g., the opposite side of the lateral opening). The dielectric material 106 can be deposited using at least one suitable deposition technique. Excess dielectric material 106 within the vertical opening at the second portion of the first stack can be etched to align with the capping layer 102, for example. The dielectric material 106 can be etched using at least one suitable etching technique. As shown, the sidewalls of the vertical channel opening can be flushed or aligned.

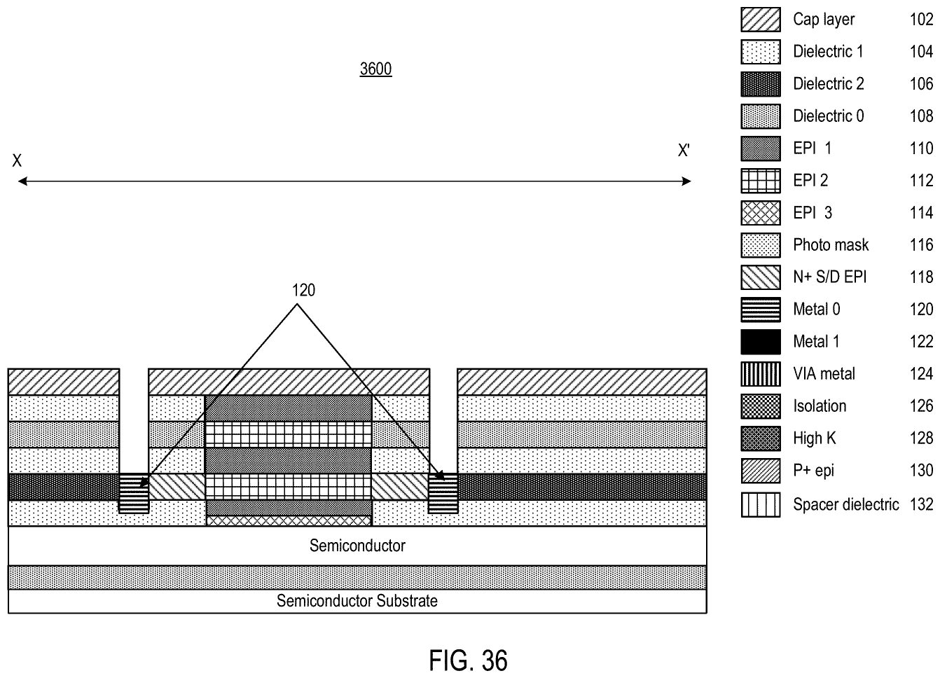

FIG. 36 illustrates a cross-sectional view 3600 of the next stage in the process flow. In various arrangements, a metal material 120 can be deposited into the vertical opening. The metal material 120 can be similar to or different from the metal material 120 described in conjunction with FIG. 12, for example. The metal material 120 can be formed or deposited vertically up to the top of the dielectric material 106 or the epitaxial material 118. In some cases, the metal material 120 can be etched to laterally align the exposed surface (e.g., top) of the metal material 120 with the top of the dielectric material 106 or the epitaxial material 118, for example. The metal material 120 can be in (e.g., electrical) contact with the epitaxial material 118.

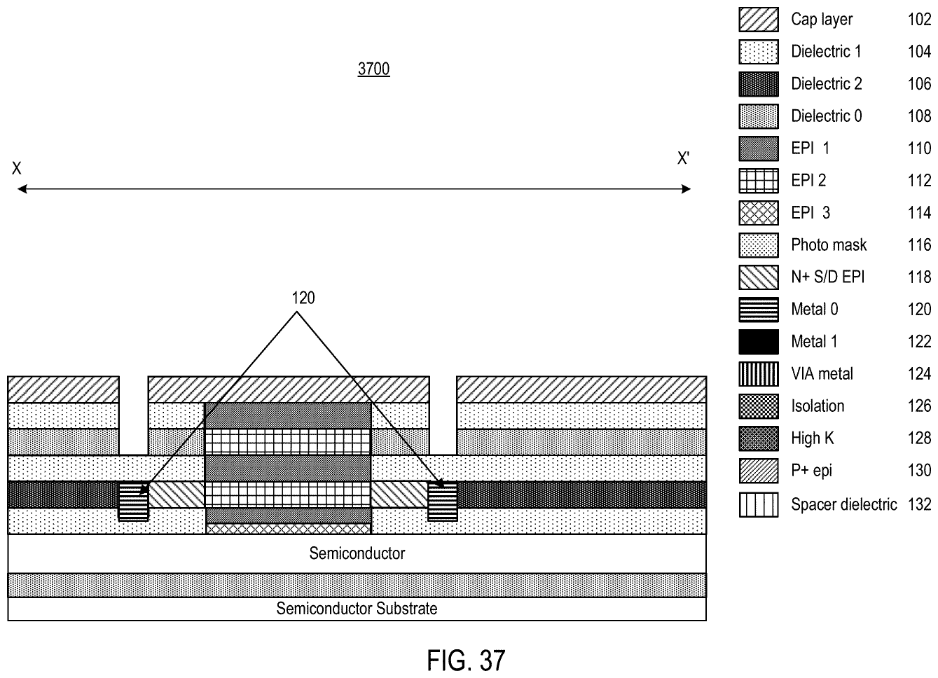

FIG. 37 illustrates a cross-sectional view 3700 of the next stage in the process flow. After forming the metal material 120, the dielectric material 104 can be deposited above the metal material 120. The dielectric material 104 can isolate the top of the metal material 120 from other materials/structures. The dielectric material 104 can be etched to vertically align with the other portions of the dielectric material 104 (e.g., the middle one of the dielectric materials 104).

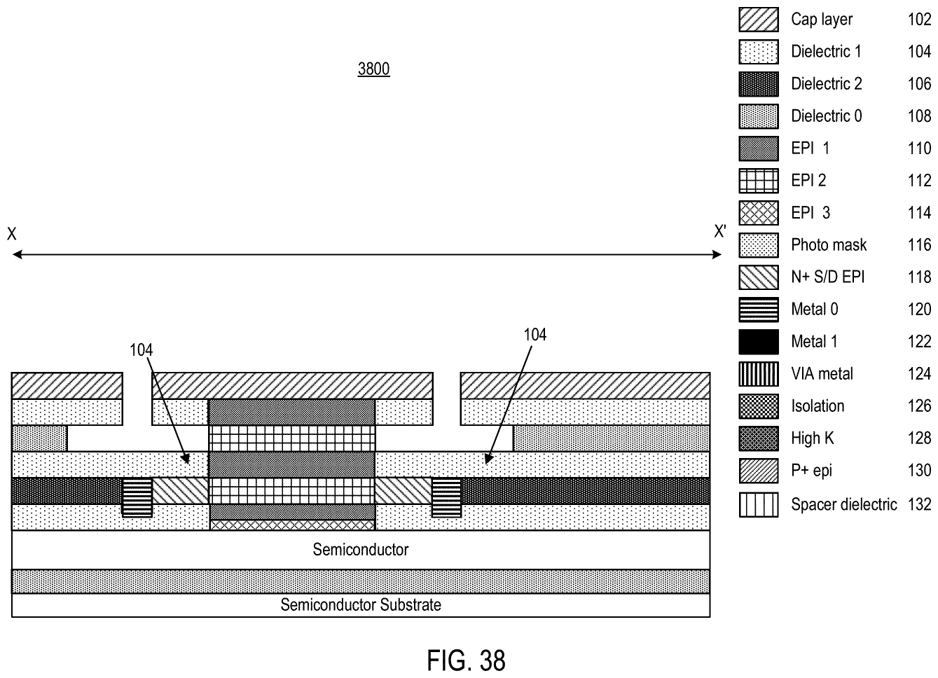

FIG. 38 illustrates a cross-sectional view 3800 of the next stage in the process flow. After depositing the dielectric material 104 to isolate the metal material 120, a similar operation can be performed as described in conjunction with at least one of FIG. 8 or 33. For example, a portion of the dielectric material 108 can be laterally etched or removed, such as using at least one suitable etching technique. Subsequent to laterally etching the portion of the dielectric material 108, the edges of the upper one of the semiconductor material 112 can be exposed (e.g., adjacent to a PMOS channel, in some cases).

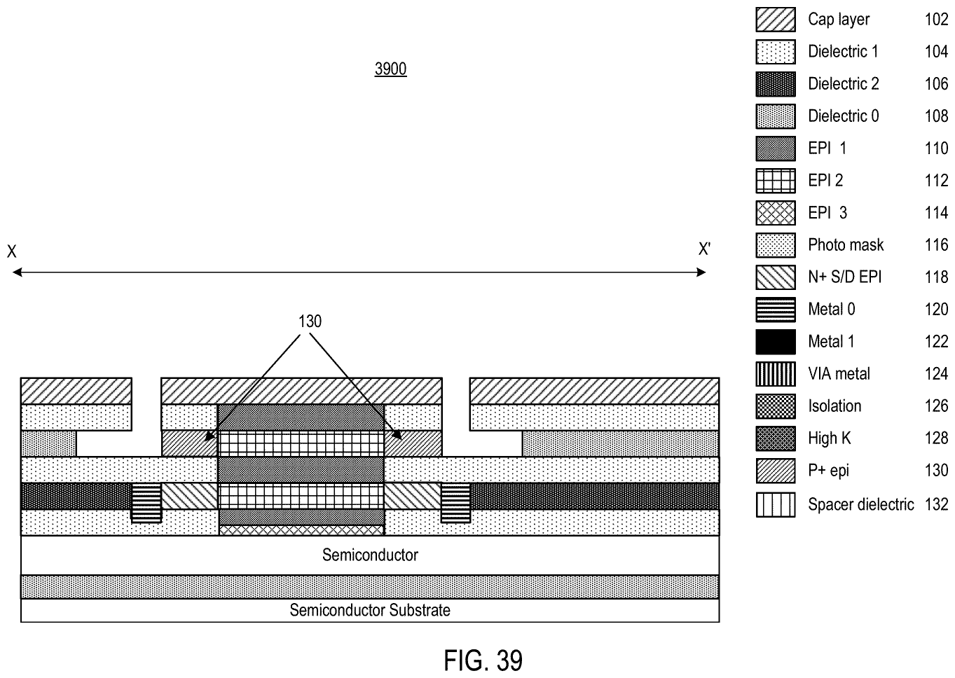

FIG. 39 illustrates a cross-sectional view 3900 of the next stage in the process flow. An epitaxial material 130 can be grown within the lateral opening within the second portion of the first stack. The epitaxial material 130 can use a portion of the dielectric material 104 as a seed layer. For purposes of providing an example, the epitaxial material 130, in this case, can be suitable for an PMOS device. For example, the epitaxial material 130 may have p-type dopants such as, for example, boron, gallium, etc. The epitaxial material 130 can be in contact with the upper semiconductor material 112. The epitaxial material 130 can be grown or formed similar to the epitaxial material 118, for example. In some cases, the epitaxial material 130 can extend laterally into the second portion (e.g., pass the sidewall of the vertical channel opening) or up to the sidewall/edge of the dielectric material 104 or the capping layer 102 above the epitaxial material 130, for example.

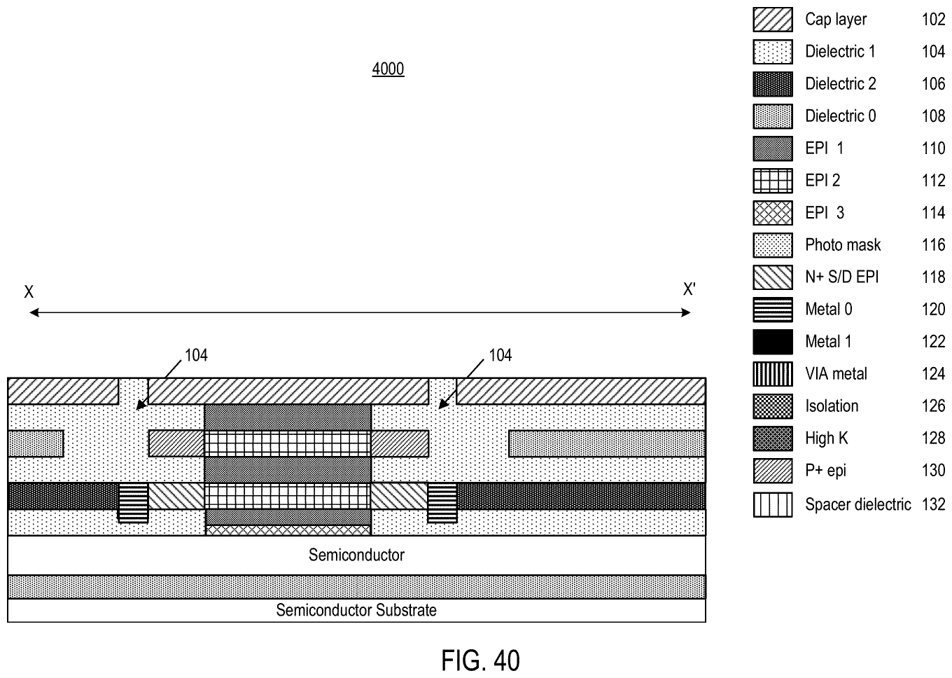

FIG. 40 illustrates a cross-sectional view 4000 of the next stage in the process flow. The remaining opening can be filled with the dielectric material 104, among other isolation layers, structures, or materials. The dielectric material 104 can be deposited into the lateral opening and the vertical opening at or around the second portion of the first stack. The dielectric material 104 can be deposited using at least one suitable deposition technique. Any excess portion of the dielectric material 104 (e.g., extending vertically beyond the surface of the capping layer 102) can be etched.

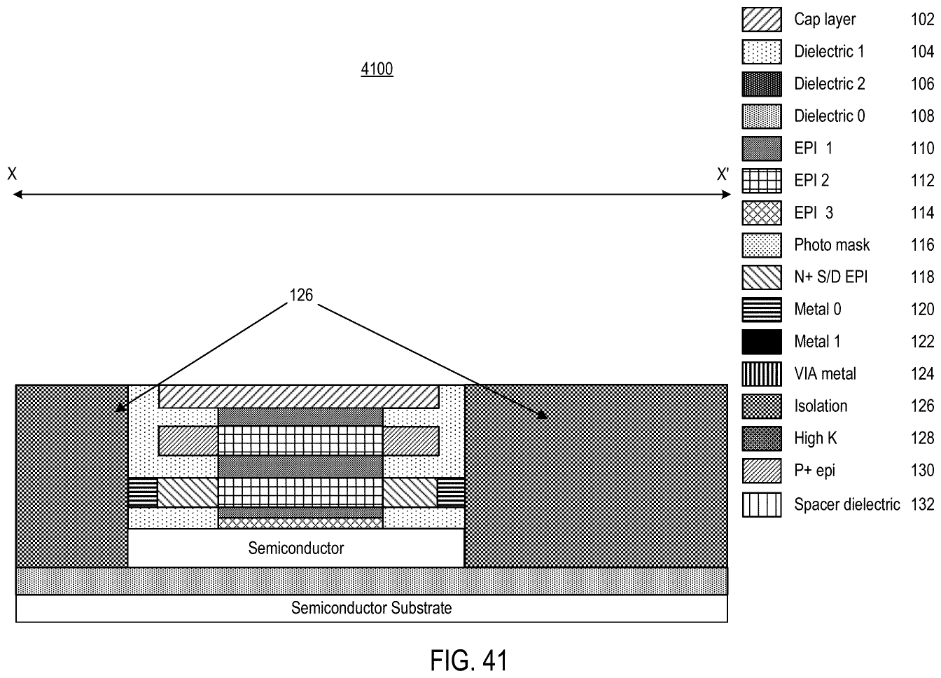

FIG. 41 illustrates a cross-sectional view 4100 of the next stage in the process flow. Portions (e.g., third portion) of the first stack can be removed using at least one suitable etching technique. This portion of the first stack can be described in conjunction with at least one of FIG. 16 or 17, for example. As shown, the portions adjacent to the second portion of the first stack at the opposite side of the second stack can be removed using at least one suitable etching technique. The removed portion can be replaced with an isolation material 126 (e.g., deposited at the third portion). The deposition of the isolation material 126 can be described as similar to the operation of FIG. 18, for example. In various implementations, as shown throughout the second process flow, multiple types of dielectric materials (e.g., dielectric materials 106 and 108) can be used to allow the removal of each dielectric material 106, 108 per time instance, such as to grow the respective epitaxial materials 118, 130. For instance, the dielectric material 106 can be removed to grow the epitaxial material 118, and the dielectric material 108 can be removed to grow the epitaxial material 130, or vice versa in some cases.

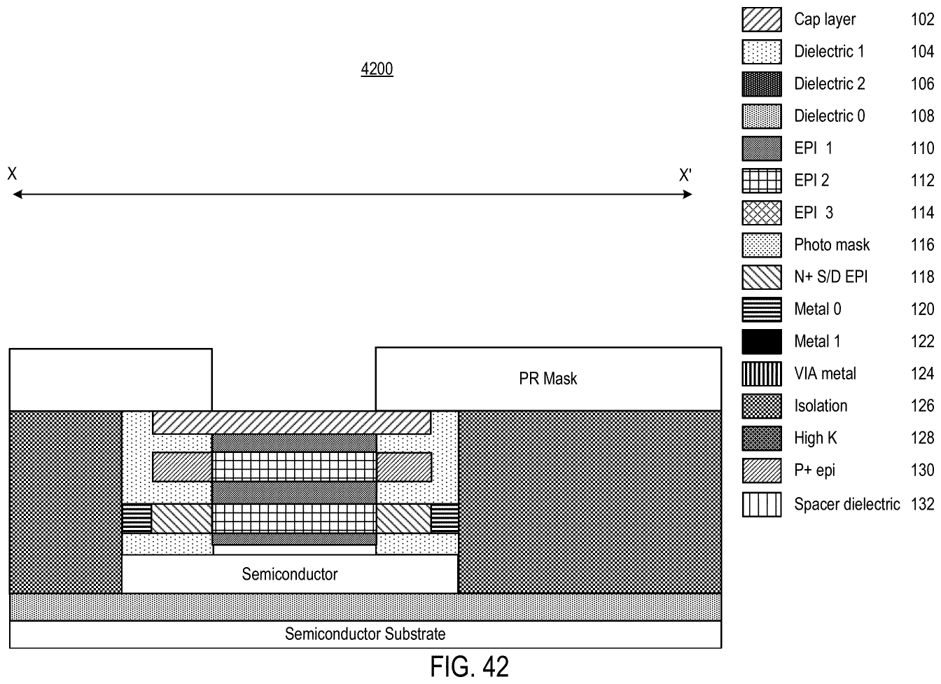

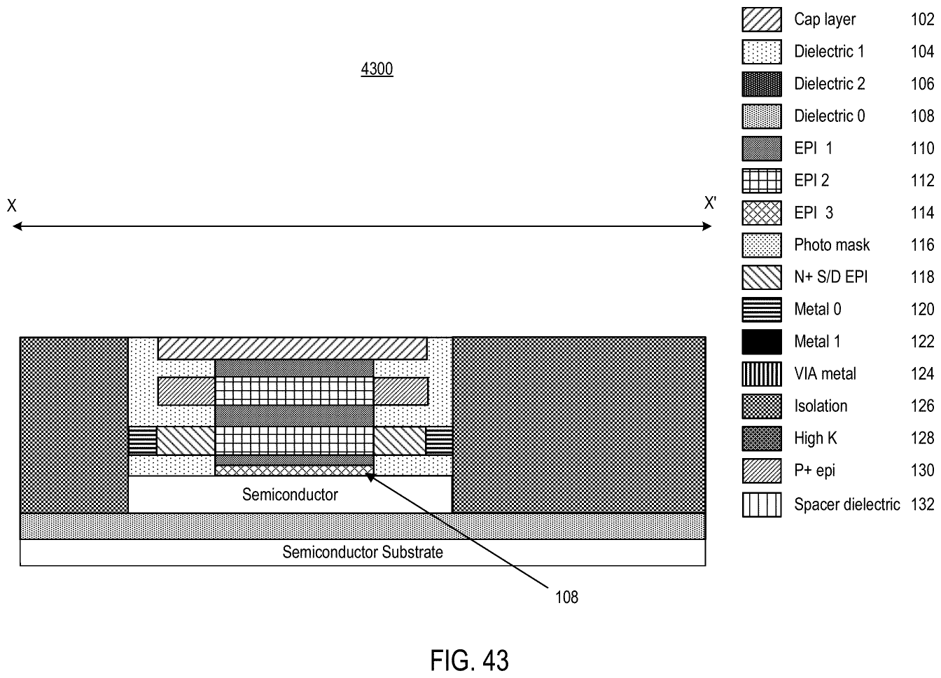

FIG. 42 illustrates a cross-sectional view 4200 of the next stage in the process flow. In this case, the semiconductor material 114 can be selectively etched or removed (e.g., using the mask material 116). The removal of the semiconductor material 114 can be described in conjunction with FIG. 20, for example. FIG. 43 illustrates a cross-sectional view 4300 of the next stage in the process flow. After the removal, the dielectric material 108 can be deposited at the removed semiconductor material 114 portion, thereby isolating the second stack layers from the semiconductor substrate. In some aspects, the dielectric material 108 can be etched to align with the pattern of the mask material 116, for example. The deposition of the dielectric material 108 can be described in conjunction with FIG. 20.

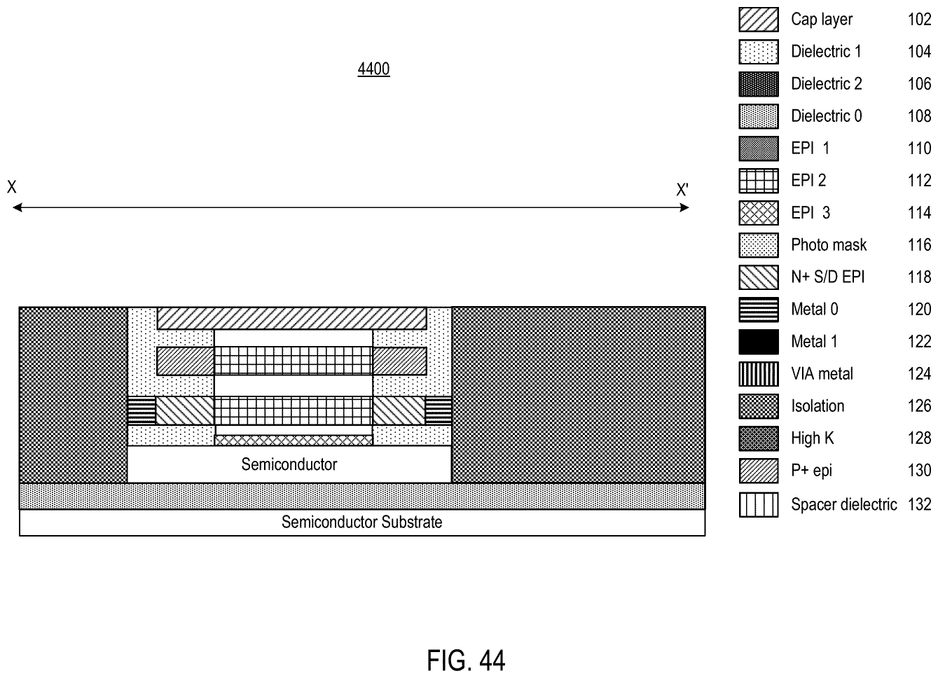

FIG. 44 illustrates a cross-sectional view 4400 of the next stage in the process flow. After depositing the dielectric material 108, the semiconductor materials 110 (e.g., upper, middle, and lower first semiconductor layers) can be removed using at least one suitable etching technique. Removing the semiconductor materials 110 can be similarly described in conjunction with FIG. 22, for example. By removing the semiconductor materials 110, the top surface and the bottom surface of the semiconductor materials 112 (e.g., upper and lower second semiconductor layers) are exposed.

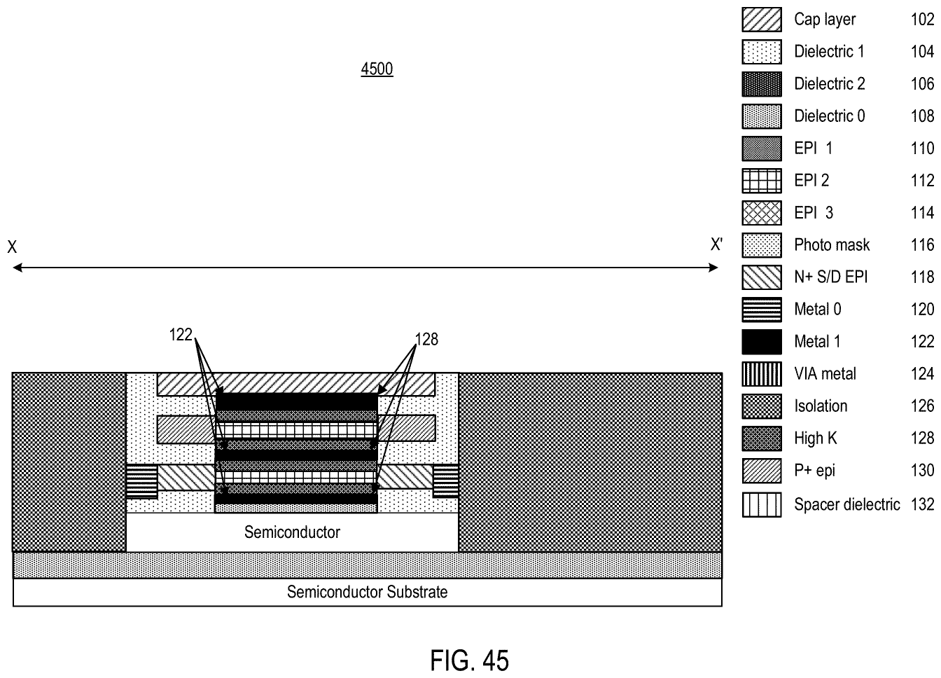

FIG. 45 illustrates a cross-sectional view 4500 of the next stage in the process flow. Similar to the operations described in conjunction with FIG. 23, the metal materials 122 and the high-k dielectric materials 128 are deposited to replace the removed portion of the semiconductor materials 110. The high-k dielectric materials 128 are interposed between the semiconductor materials 112 and the metal materials 122. In various embodiments, the metal materials 122 and the high-k dielectric materials 128 that are collectively function as a gate structure can gate the (e.g., lower) NMOS device and (e.g., upper) PMOS device concurrently. Alternatively stated, respective gates of the NMOS device and PMOS device are shorted together, which allows these two devices to function as an inverter.

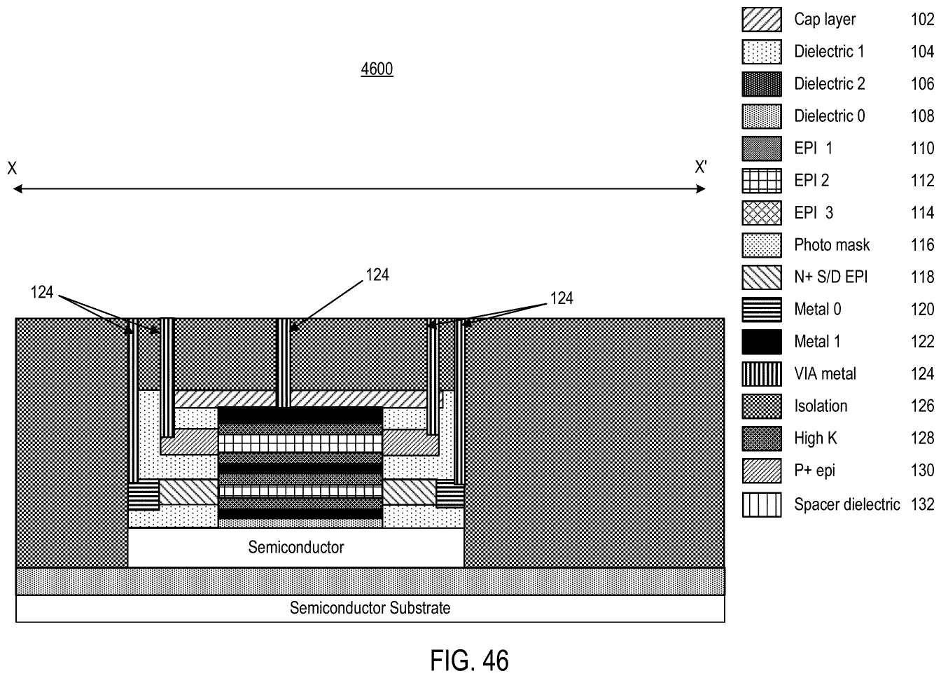

FIG. 46 illustrates a cross-sectional view 4600 of the next stage in the process flow. After depositing the metal material 122 and the high-k dielectric material 128, one or more via structures 124 can be formed. The formation of the via structures 124 can be similar to the operations described in conjunction with FIG. 24. For example, the isolation material 126 can be deposited above the stacks (e.g., above the semiconductor device(s)), such as up to a predetermined height. Vertical etching can be performed (e.g., using at least one suitable etching technique) to form vertical openings to at least one of the metal materials 120, 122, and the epitaxial materials 130. The via structures 124 can be deposited into the vertical openings using at least one suitable deposition technique. As shown, the via structures 124 can be extended from the surface of the isolation material 126 to respective portions of the semiconductor device. The via structures can be in (e.g., electrical) contact with the various structures (e.g., the metal materials 120, 122, and the epitaxial material 130) of the stacks.

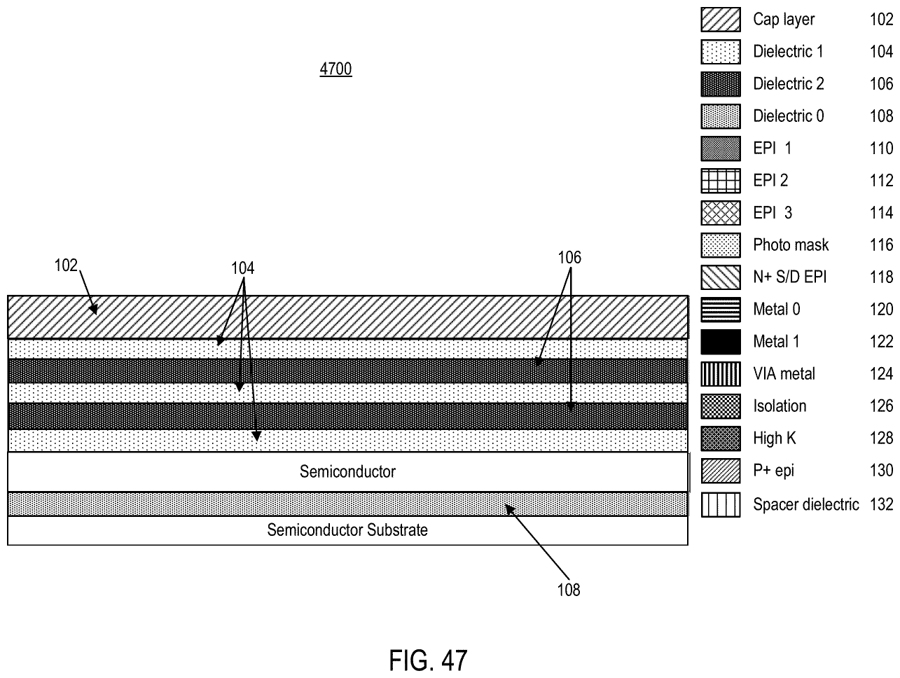

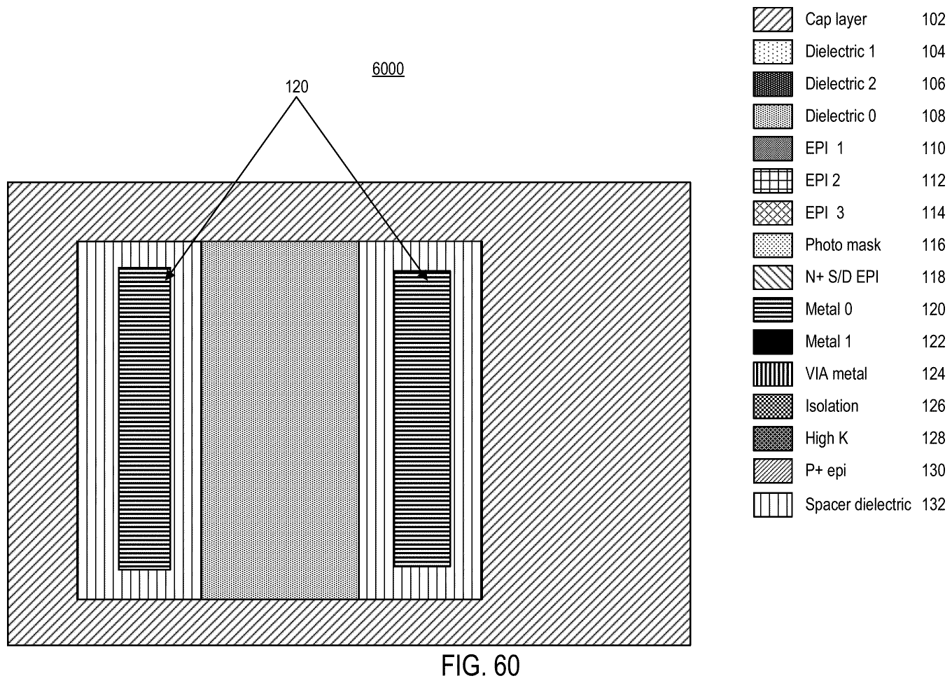

FIGS. 47-70 show various views 4700-7000 of a third process flow to manufacture semiconductor devices with S/D extensions. Each of FIGS. 47-70 generally refer to one or more process steps in a process flow, each of which is described in detail in connection with a respective Figure. For the purposes of simplicity and ease of visualization, some reference numbers may be omitted from some Figures. In FIGS. 47-70, an example process flow is described to manufacture a 3D stacking device with S/D extension using 3D nanosheet formation side by side N=2 stacking. A top spacer can be used to define dielectric overhang for additional symmetry, such as for S/D spacer regions.

The third process flow of FIGS. 47-70 can include operations, features, constructions, structures, or processes similar to one or more operations described in conjunction with at least one of FIGS. 1-46. For example, the operations of the third process flow can be performed using one or more similar techniques (e.g., etching, deposition, etc.) as at least one of the FIGS. 1-46.

FIG. 47 illustrates a cross-sectional view 4700 of a semiconductor device in which various layers, including various materials (e.g., dielectric materials), are formed over at least one semiconductor substrate. The operations (e.g., formation of the first stack) of FIG. 25 can be performed similar to the operations described in FIG. 1, for example, such as including alternate between the dielectric materials 104, 106, as shown. The capping layer 102 can be deposited or formed above the first stack.

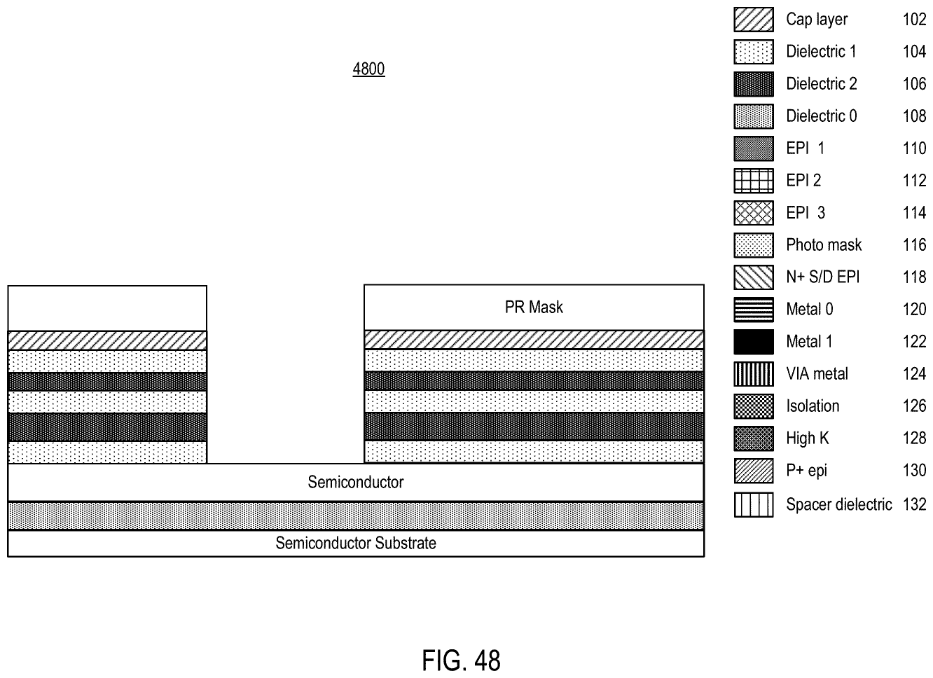

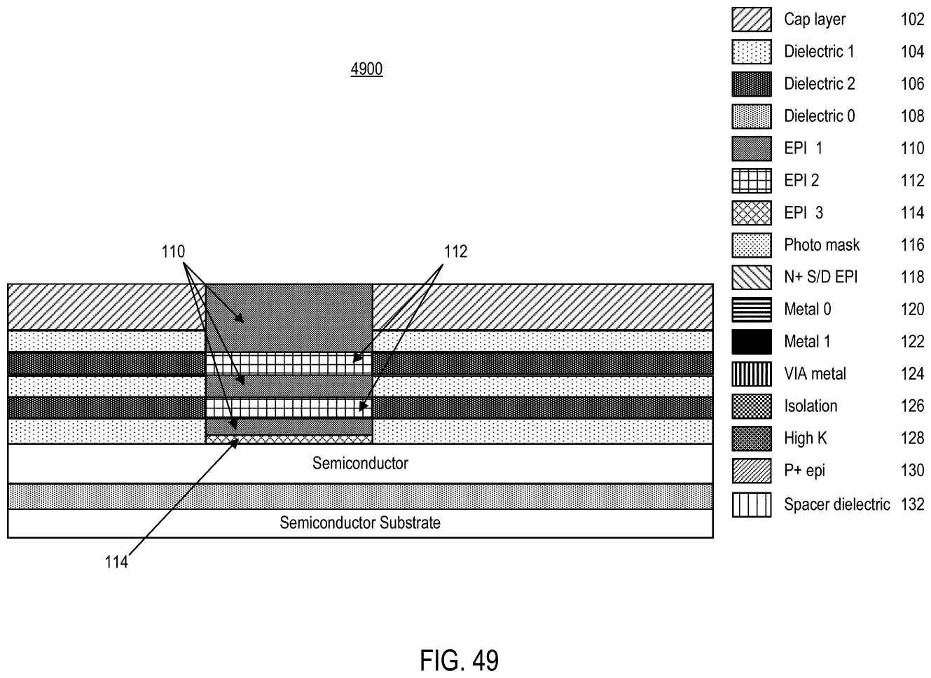

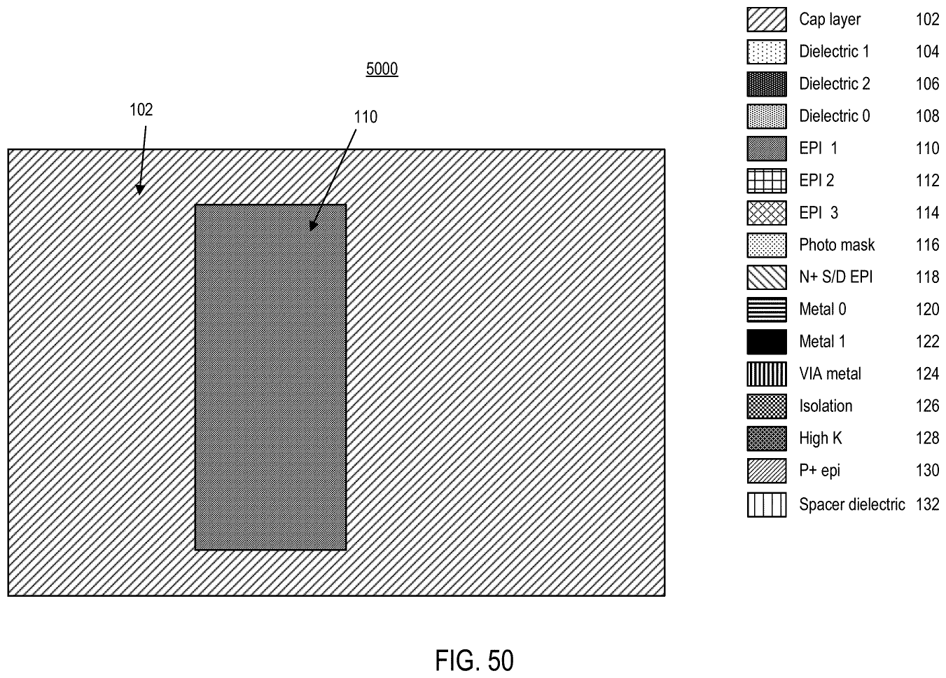

FIG. 48 illustrates a cross-sectional view 4800 of the next stage in the process flow. A portion (e.g., a first portion) of the first stack can be etched. The removal of the first portion can be similar to the operation described in FIG. 2, for example. FIG. 49 illustrates a cross-sectional view 4900 of the next stage in the process flow. FIG. 50 illustrates a top view 5000 corresponding to the cross-sectional view 4900. Materials of the second stack can be deposited into the first portion, including the semiconductor materials 110, 112, 114. The process for depositing the semiconductor materials 110, 112, 114 can be similar to the operations described in FIG. 3, for example. In this case, the upper semiconductor material 110 can extend vertically up to (e.g., align with) the surface of the capping layer 102.

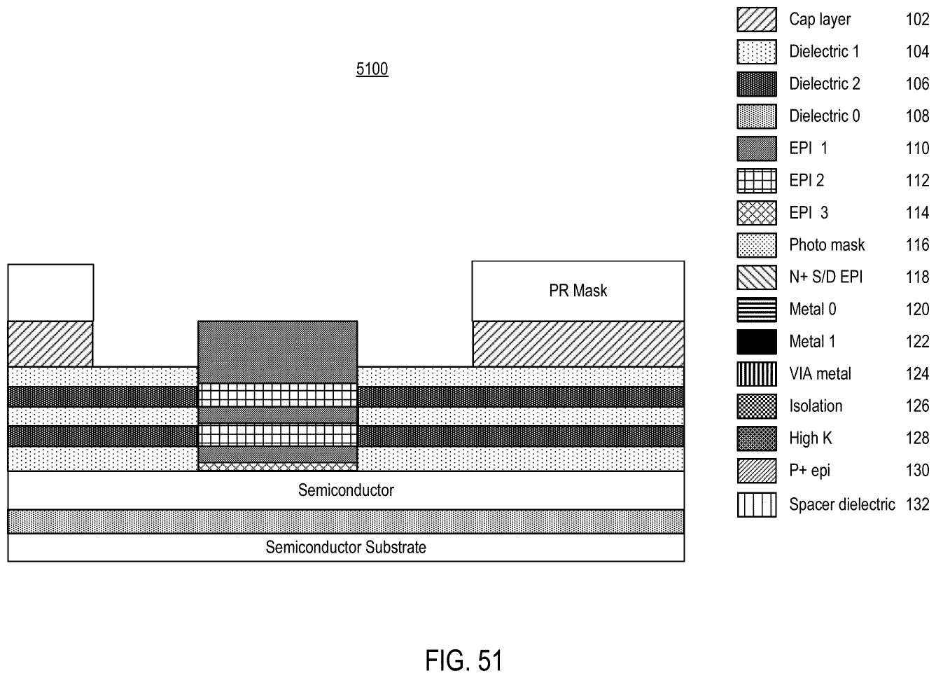

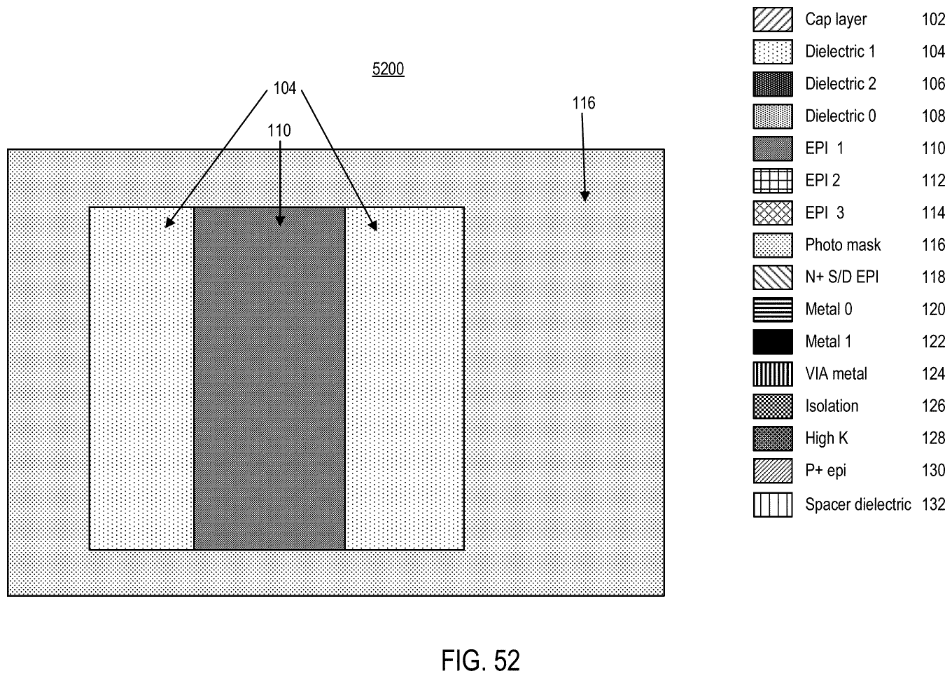

FIG. 51 illustrates a cross-sectional view 5100 of the next stage in the process flow. FIG. 52 illustrates a top view 5200 corresponding to the cross-sectional view 5100. A mask (e.g., mask material 116) can be deposited above the semiconductor device, including a predefined pattern. As shown, using the mask, at least a portion of the capping layer 102 can be removed or opened. The removed portion can be adjacent to the second stack, including a predefined lateral distance. The removed portion can expose the top surface of a portion of the dielectric material 104.

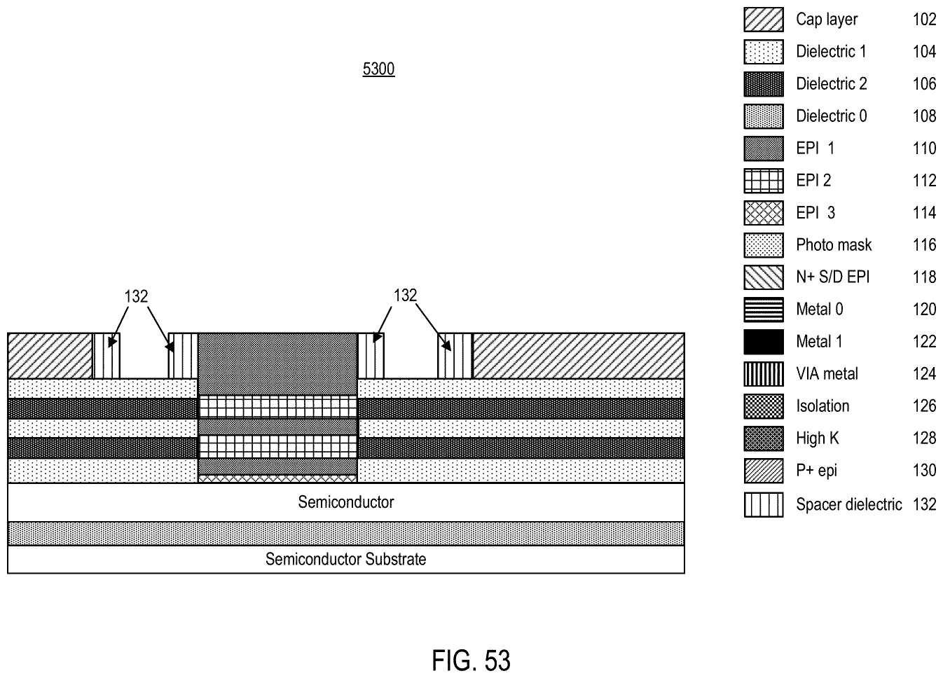

FIG. 53 illustrates a cross-sectional view 5300 of the next stage in the process flow. A dielectric material 132 (e.g., shown in the legend as “spacer dielectric”) can be deposited into at least a portion of the opening formed after removing the capping layer 102. The dielectric material 132 can be deposited using at least one suitable deposition technique. The dielectric material 132 can be etched to form an entrance or an opening at a second portion of the first stack. At this stage, the opening can expose a portion of the top surface of the upper dielectric material 104. The dielectric material 132 can be etched using at least one suitable etching technique. In this case, the dielectric material 132 can form or correspond to a spacer hard mask, such as for self-aligning to align with the second stack for dielectric overhang (e.g., channel spacer alignment to S/D regions).

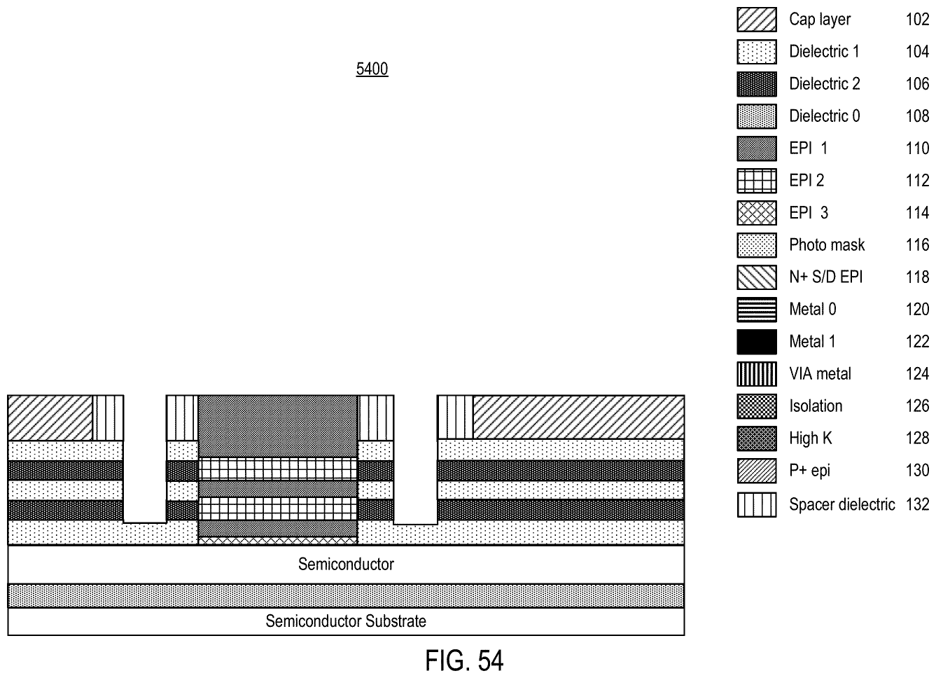

FIG. 54 illustrates a cross-sectional view 5400 of the next stage in the process flow. After forming the dielectric material 132 to define an opening to the second portion of the first stack, the second portion of the first stack can be etched, including the dielectric materials 104, 106. The etching of the second portion of the first stack can be performed similar to the operations described in FIG. 6, for example. The opening at the second portion can expose the top surface of the dielectric material 104.

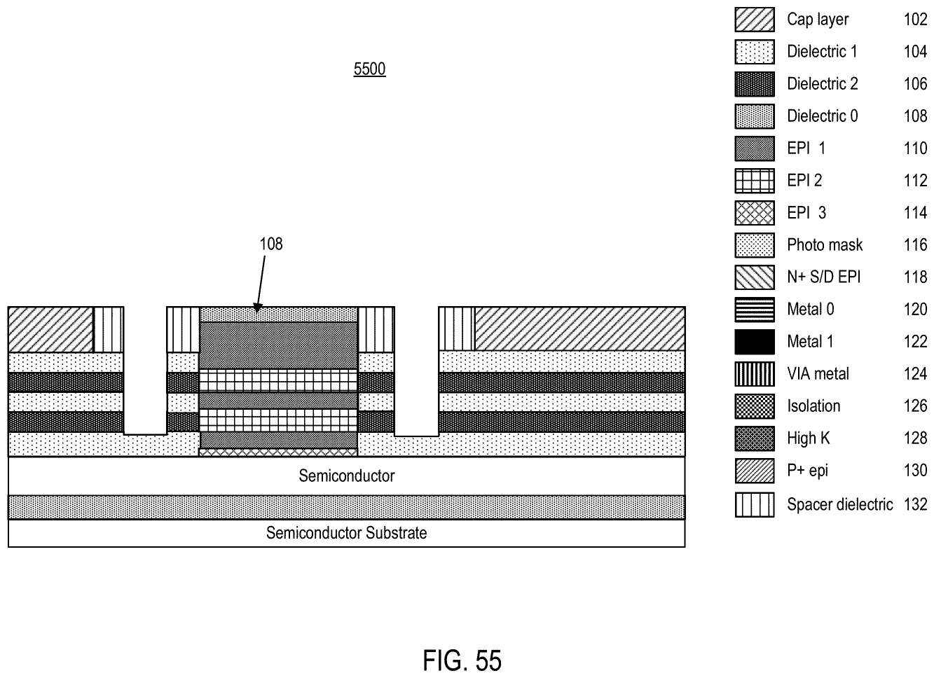

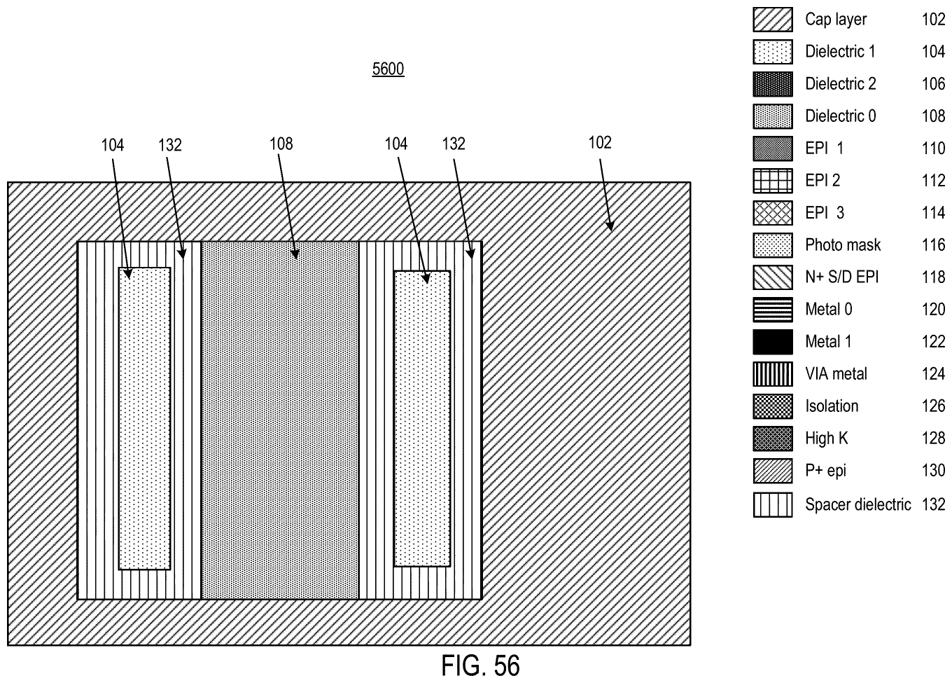

FIG. 55 illustrates a cross-sectional view 5500 of the next stage in the process flow. FIG. 56 illustrates a top view 5600 corresponding to the cross-sectional view 5500. The dielectric material 108 can be formed at least at a portion of the upper semiconductor material 110. The dielectric material 108 can be formed, for example, by oxidizing at least the top portion of the semiconductor material 110 (e.g., among other suitable material formation techniques).

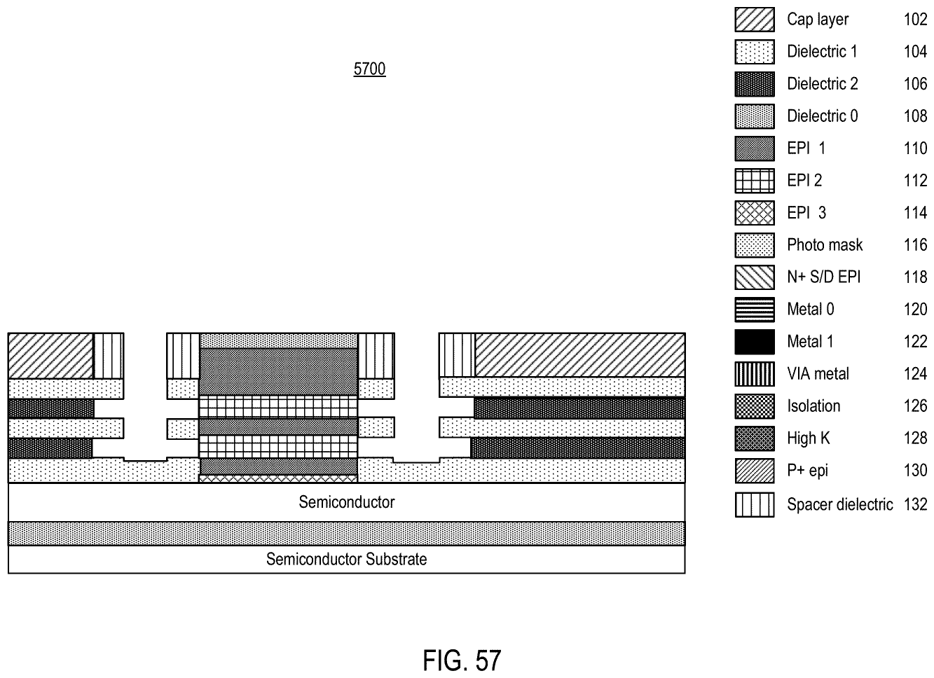

FIG. 57 illustrates a cross-sectional view 5700 of the next stage in the process flow. Portions of the dielectric materials 106 can be laterally etched using at least one suitable etching technique. For example, the dielectric materials 106 can be etched similar to the operations described in conjunction with FIG. 8. By etching the dielectric materials 106, the edges or sidewalls of the semiconductor materials 112 can be exposed.

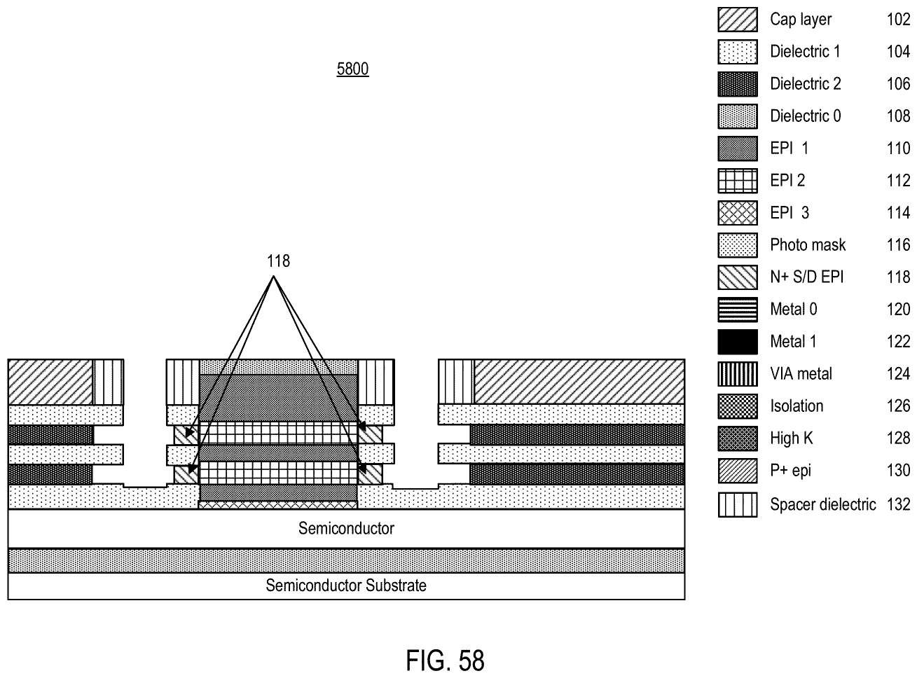

Referring to FIGS. 58-60, cross-sectional views 5800, 5900 and a top view 6000 of the next stages in the process flow are shown. As shown, the epitaxial material 118 and metal material 120 can be deposited into the opening. The deposition of the epitaxial material 118 and metal material 120 can be performed similarly to the operations described in at least one of FIGS. 9-12.

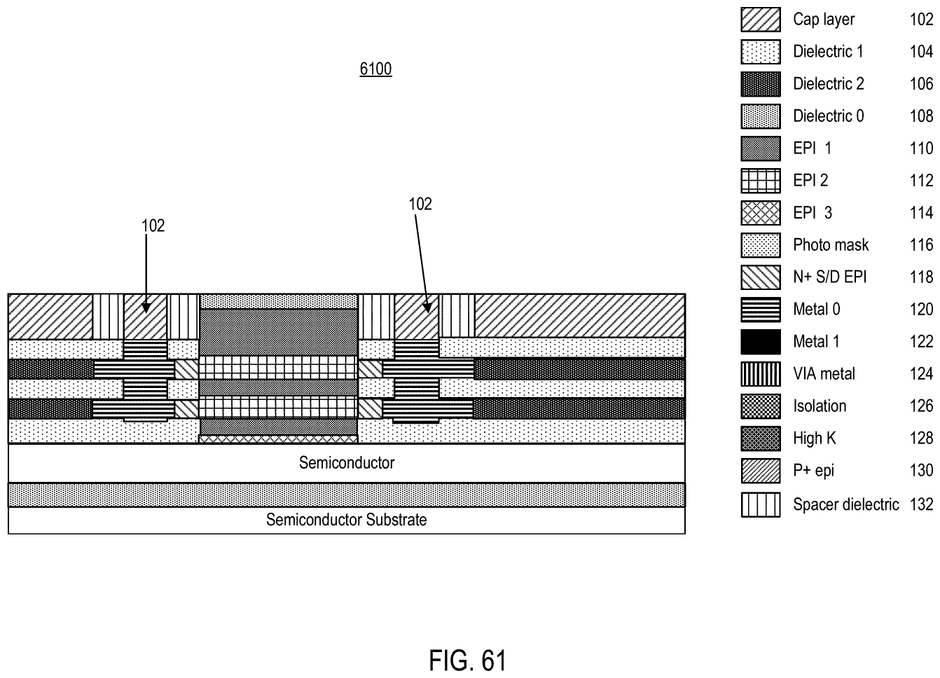

FIG. 61 illustrates a cross-sectional view 6100 of the next stage in the process flow. After depositing the metal material 120, a portion of the metal material 120 can be etched for height reduction. The etching of the metal material 120 can be performed using at least one suitable etching technique. For instance, the height of the metal material 120 can vertically extend up to (or align with) the top surface of the upper dielectric material 104. Subsequently, an opening above the second portion of the first stack can be formed above the metal material 120. The capping layer 102 can be deposited into the opening using at least one suitable deposition technique. Any overburden can be removed by CMP process, for example.

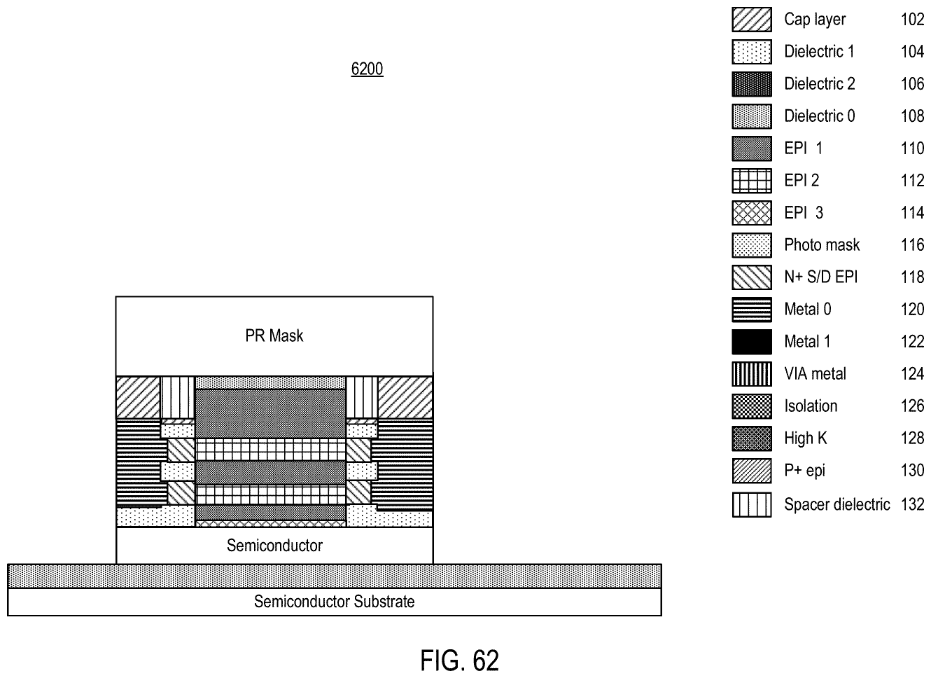

FIG. 62 illustrates a cross-sectional view 6200 of the next stage in the process flow. After depositing the capping layer 102, portions of the first stack can be removed using at least one suitable etching technique (e.g., using a patterned mask). The removal of these portions can be performed similarly to the operations described in at least one of FIGS. 16-17, for example.

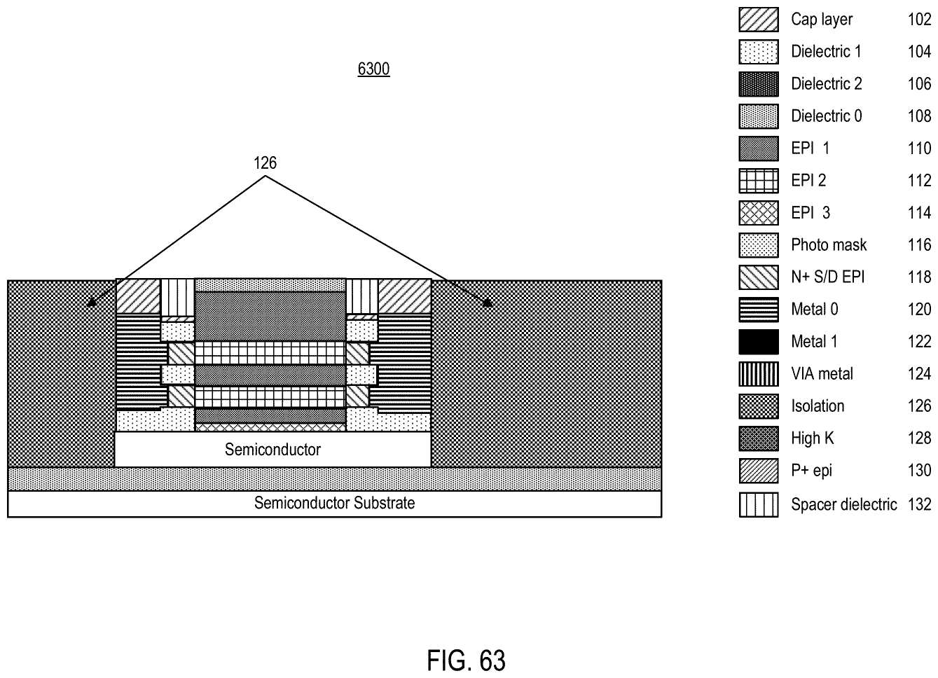

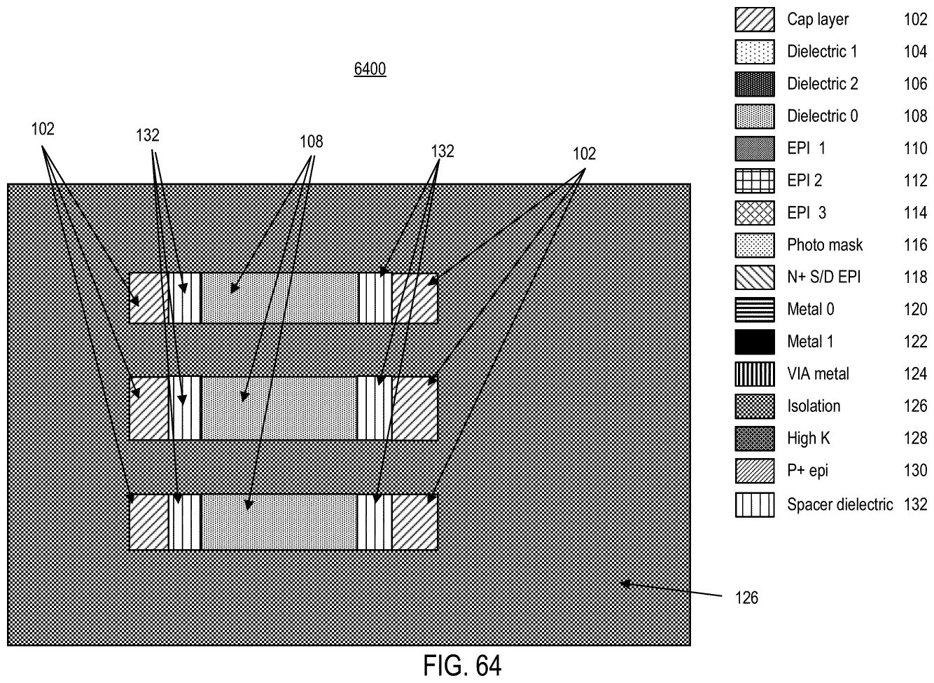

FIG. 63 illustrates a cross-sectional view 6300 of the next stage in the process flow. FIG. 64 illustrates a top view 6400 corresponding to the cross-sectional view 6300. The isolation material 126 can be deposited at the removed portions of the first stack. The isolation material 126 can extend vertically up to the surface of the capping layer 102, among other materials. The isolation material 126 can be deposited similarly to the operations as in FIG. 18, for example.

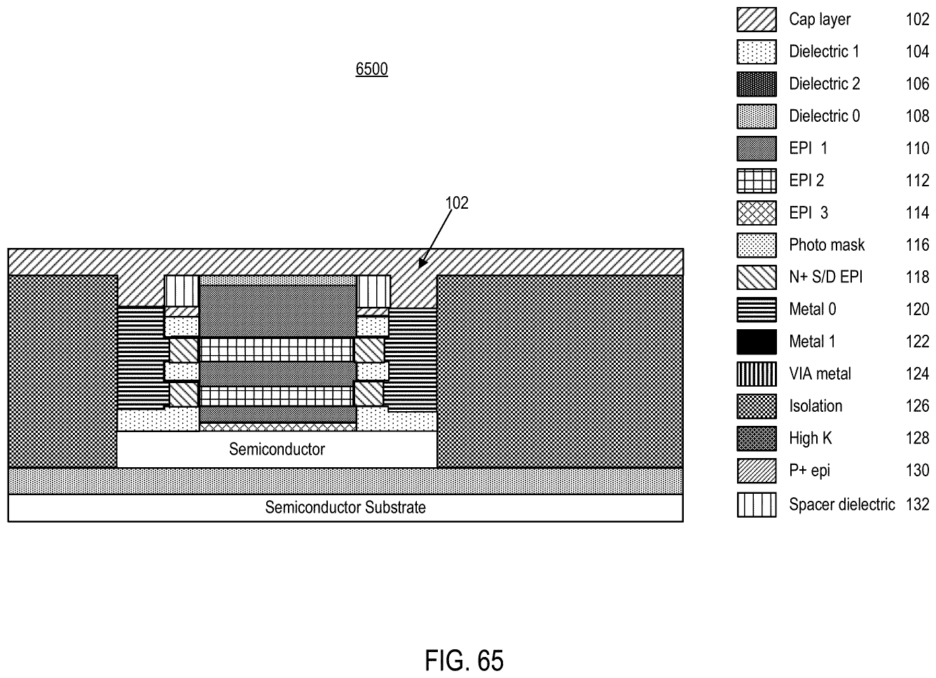

FIG. 65 illustrates a cross-sectional view 6500 of the next stage in the process flow. The capping layer 102 (e.g., hard mask) can be deposited above the semiconductor device (e.g., the materials/structures, such as the isolation material 126, capping layer 102, and dielectric materials 108, 132. The capping layer 102 can be deposited using at least one suitable deposition technique up to a predefined height.

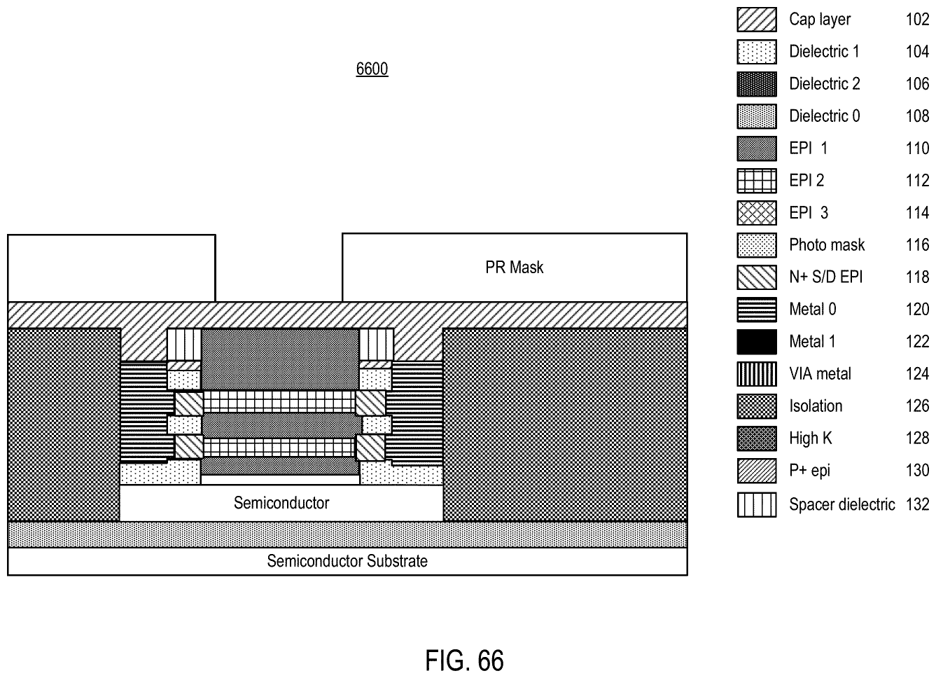

FIG. 66 illustrates a cross-sectional view 6600 of the next stage in the process flow. At this stage, the semiconductor material 114 below the second stack (or a part of the second stack) can be removed using at least one suitable etching technique. The semiconductor material 114 can be removed based on similar operations as described in conjunction with FIG. 20, for example. In various arrangements, the dielectric material 108 above the second stack may be removed using at least one suitable etching or removal technique.

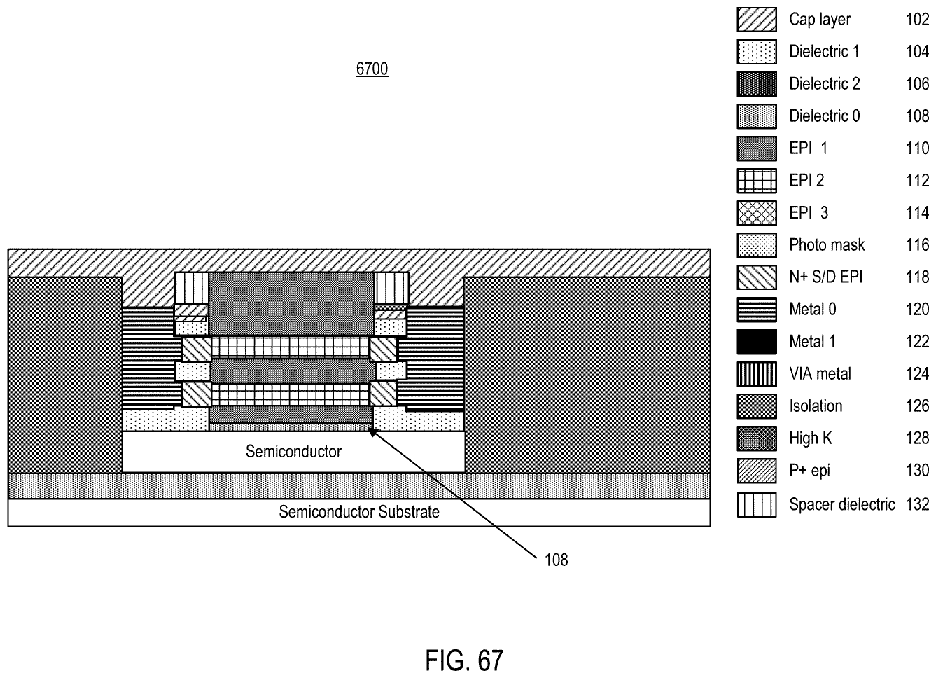

FIG. 67 illustrates a cross-sectional view 6700 of the next stage in the process flow. A dielectric material 108 can be deposited to replace the removed semiconductor material 114. The deposition of the dielectric material 108 can be performed similarly to the operations described in FIG. 21, for example. The dielectric material 108 isolates the second stack from the semiconductor substrate.

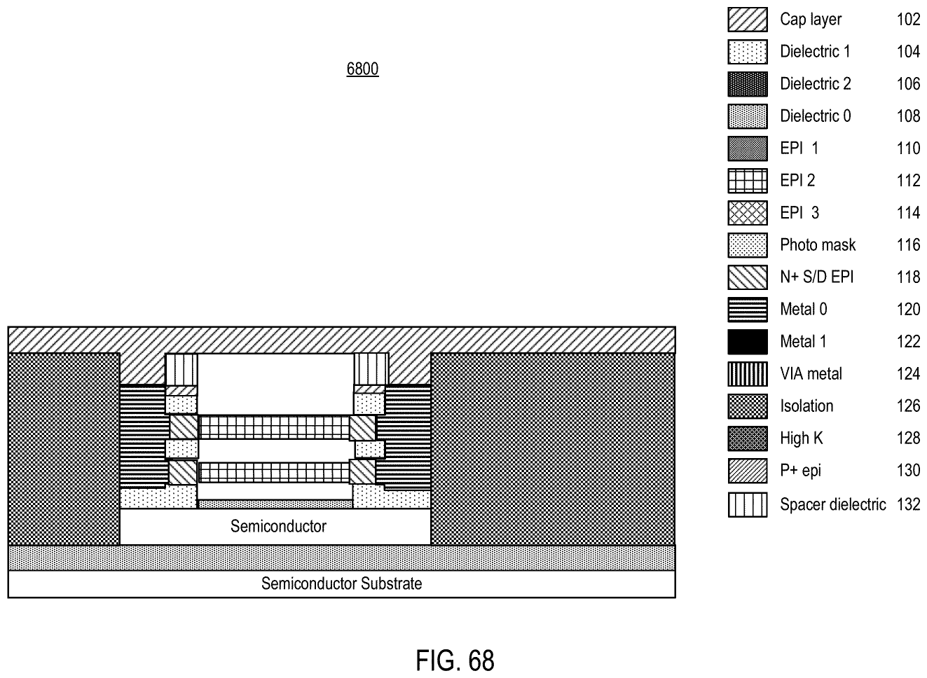

FIG. 68 illustrates a cross-sectional view 6800 of the next stage in the process flow. In various implementations, the semiconductor materials 110 (e.g., upper, middle, and lower first semiconductor layers) can be removed. The removal of the semiconductor materials 110 can be performed similarly to the operations described in FIG. 22, for example.

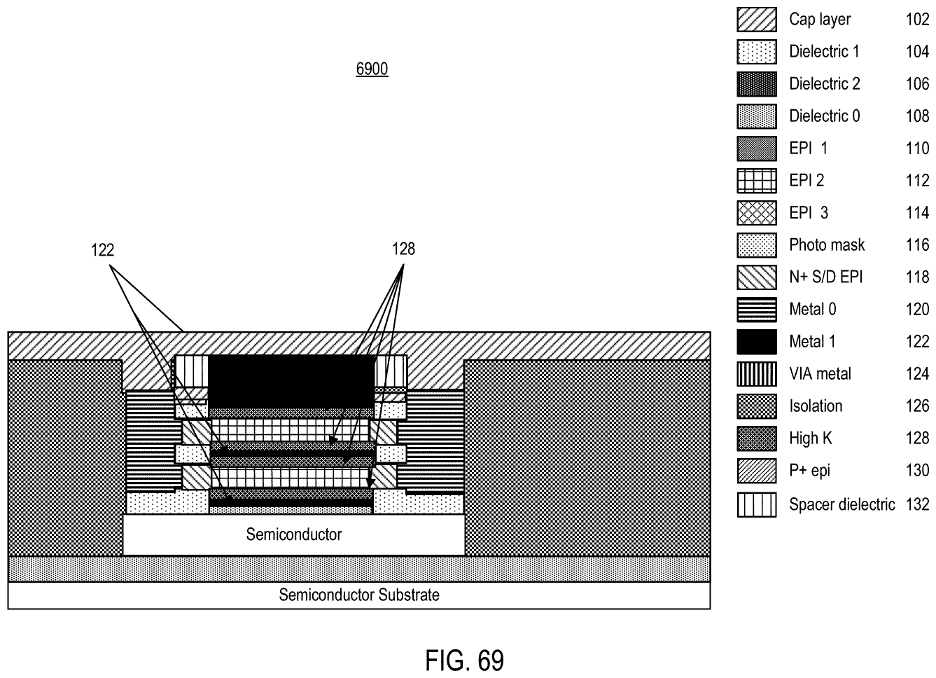

FIG. 69 illustrates a cross-sectional view 6900 of the next stage in the process flow. Replacing the semiconductor materials 110, the metal materials 122 and high-k dielectric materials 128 can be deposited, such as performed similarly to the operations described in FIG. 23, for example. As shown, in this case, the upper metal material 122 can extend vertically up to the top surface of the dielectric material 132 and/or the isolation material 126.

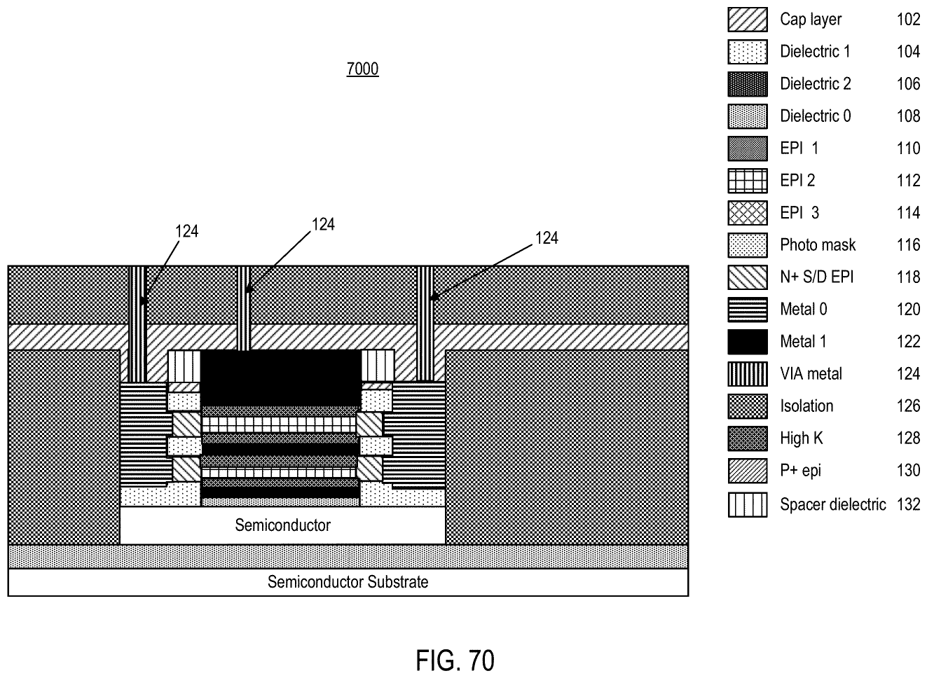

FIG. 70 illustrates a cross-sectional view 7000 of the next stage in the process flow. After depositing the metal materials 122 and the high-k dielectric materials 128, an isolation material 126 can be deposited using at least one suitable deposition technique up to a predefined height. Vertical channel openings can be formed through the isolation material 126 and the capping layer 102, extending to at least one of the metal materials 120, 122. The vertical channel openings expose the surface of the respective metal materials 120, 122. The via structures 124 can be formed at the vertical channel openings to be in (e.g., electrical) contact with the respective metal materials 120, 122 (e.g., source, gate, drain regions). In this case, the metal materials 120 can correspond to one of the source or drain regions, and the metal material 122 can correspond to the gate region, for example. The formation of the via structure 124 can be described in conjunction with at least FIG. 24, for example.

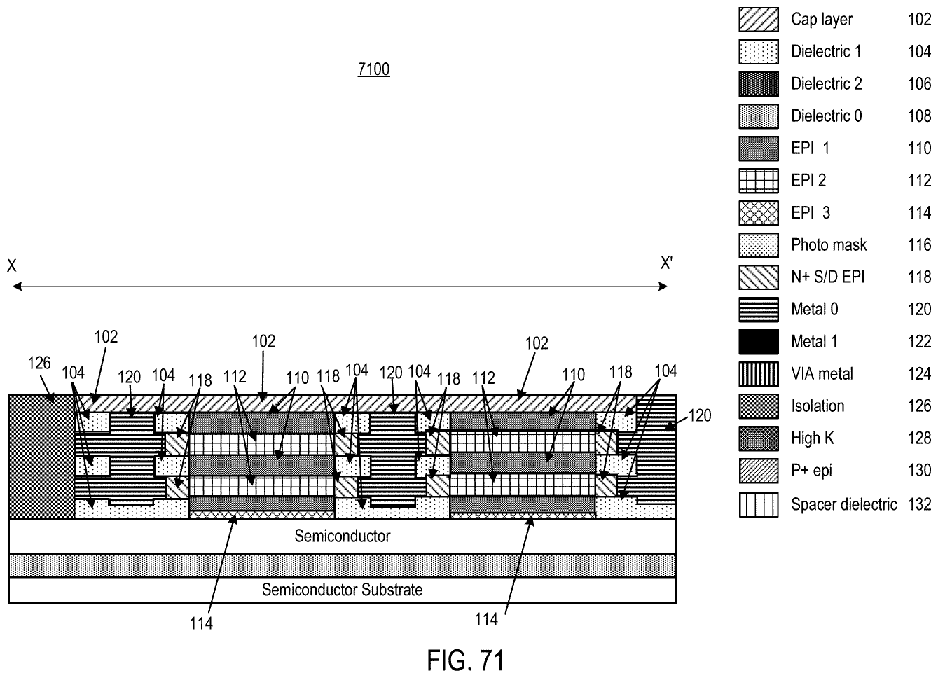

FIGS. 71-76 show various views 7100-7600 of a fourth process flow to manufacture semiconductor devices. Each of FIGS. 71-76 generally refer to one or more process steps in a process flow, each of which is described in detail in connection with a respective Figure. For the purposes of simplicity and ease of visualization, some reference numbers may be omitted from some Figures. In FIGS. 71-76, an example process flow is described to subdividing the S/D regions using, for instance, a self-aligned spacer between adjacent nanosheet device stacks.

The fourth process flow of FIGS. 71-76 can include operations, features, constructions, structures, or processes similar to one or more operations described in conjunction with at least one of FIGS. 1-70. For example, the operations described herein can be performed using one or more similar techniques (e.g., etching, deposition, etc.) as at least one of the FIGS. 1-70. Further, referring to FIG. 71, depicted is a cross-sectional view 7100 of a stage in manufacturing the semiconductor device. The stage corresponding to FIG. 71 can start at the stage described in FIG. 14, such as the deposition of the metal material 120. In this case, the isolation material 126 can be formed to the left of the stacks, extending vertically from the semiconductor substrate to the surface of the capping layer 102, for example. In various aspects, multiple stacks can be formed at portions of the first stack, such as including a second stack (e.g., including the semiconductor materials 110, 112, 114 relatively closer to the isolation material 126) and a third stack, the third stack can include similar materials or structures (e.g., including another set of semiconductor materials 110, 112, 114) as the second stack. The third stack can be positioned relatively further from the isolation material 126. Operations discussed herein performed on the second stack can be performed the same as the third stack. In various implementations, the second stack can be associated with a first semiconductor device and the third stack can be associated with a second semiconductor device, in this case.

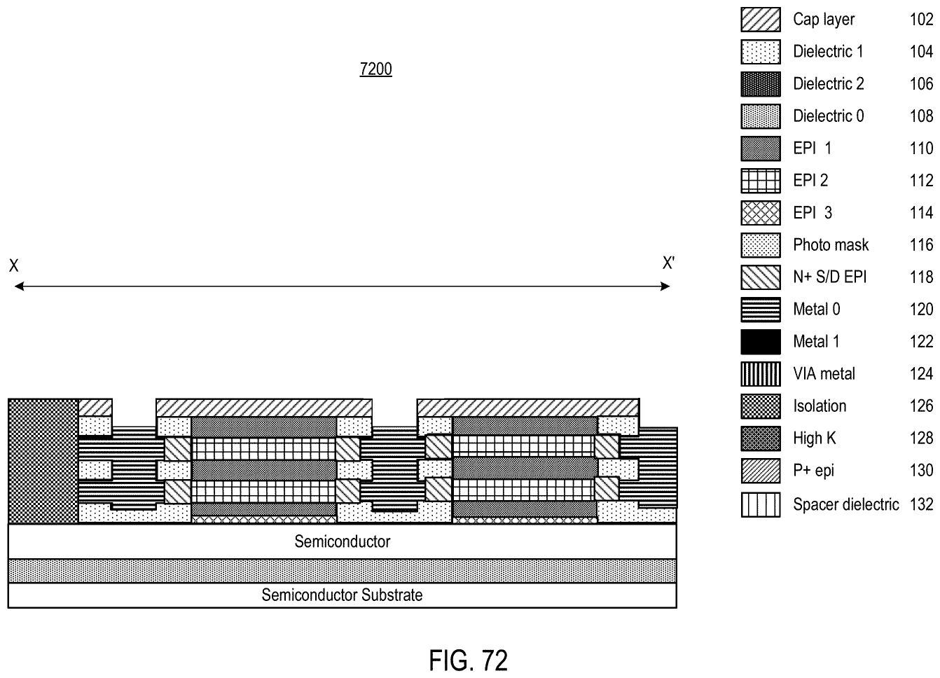

FIG. 72 illustrates a cross-sectional view 7200 of the next stage in the process flow. A portion of the metal materials 120 can be etched for height reduction (e.g., reducing the height of the metal material 120 by a predetermined level). The metal material 120 can be etched using at least one suitable etching technique. The etching of the metal material 120 can form an opening above the metal material 120.

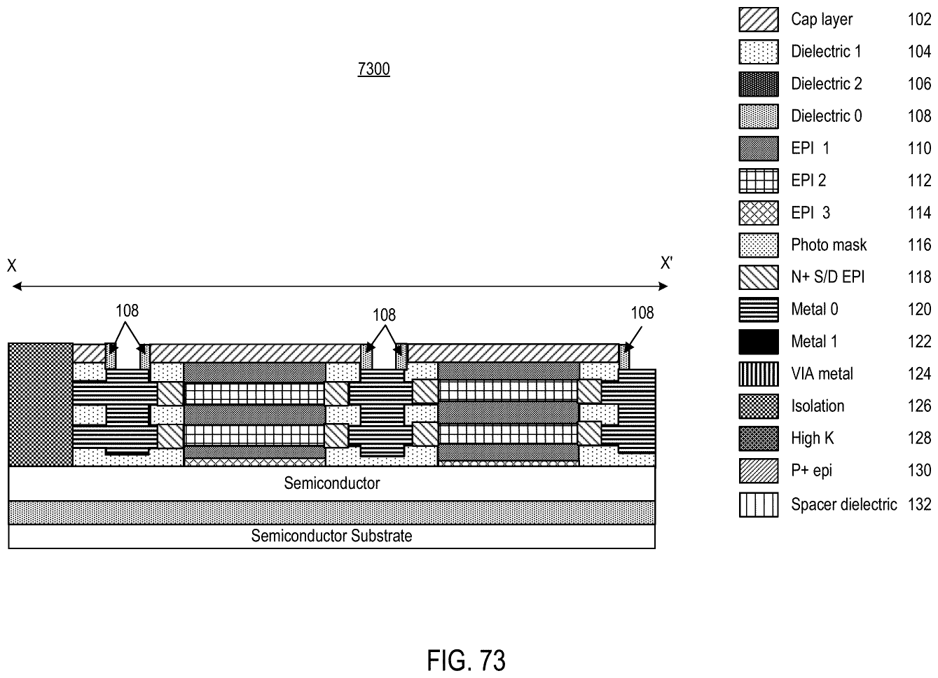

FIG. 73 illustrates a cross-sectional view 7300 of the next stage in the process flow. After forming the opening, the dielectric material 108 can be deposited into the opening above the metal material 120. The deposited dielectric material 108 can be etched to form a relatively narrower (e.g., having a predefined lateral distance) opening above the metal material 120.

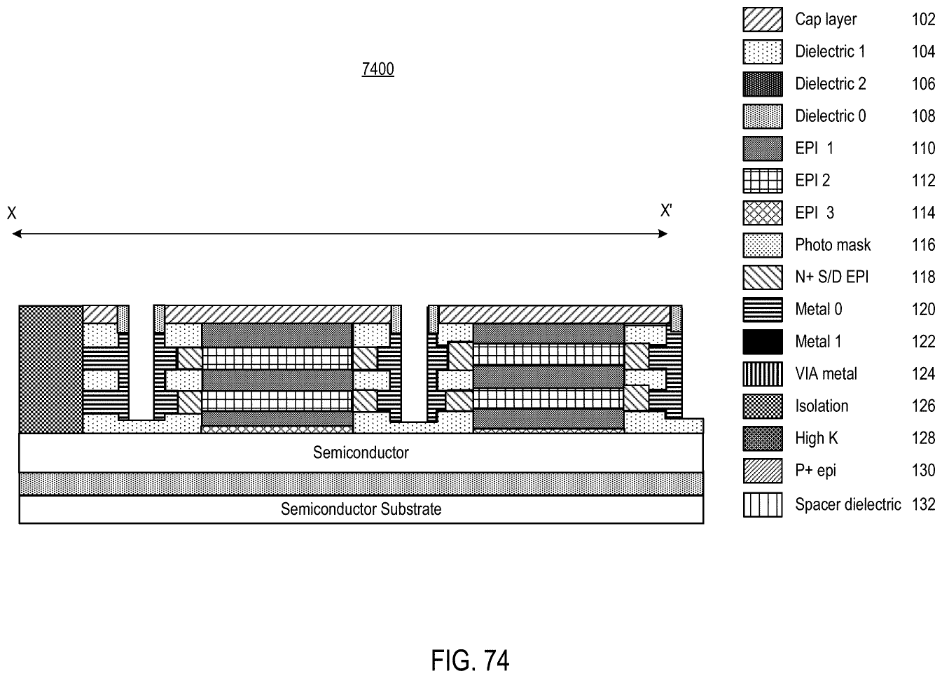

FIG. 74 illustrates a cross-sectional view 7400 of the next stage in the process flow. Using the dielectric material 108 as a spacer, channel opening(s) can be formed within the second portion(s) of the first stack. A self-aligned etching can be performed, such as using the dielectric material 108 for etching the metal material 120. As shown, the lateral distance (e.g., width) of the channel opening can be defined by the opening formed between the dielectric materials 108 as described in conjunction with FIG. 73. This channel opening can extend laterally from the top of the semiconductor device to the dielectric material 104 (e.g., exposing the surface of the dielectric material 104).

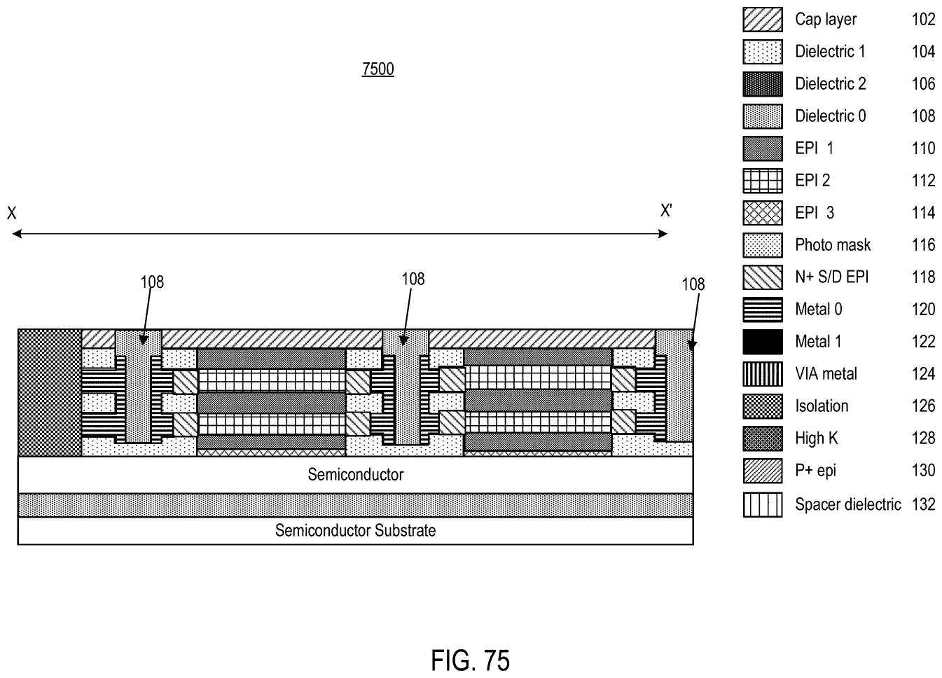

FIG. 75 illustrates a cross-sectional view 7500 of the next stage in the process flow. The dielectric material 108 can be deposited into the opening. The dielectric material 108 can be interposed between the adjacent metal materials 120 (e.g., adjacent S/D metal lines/structures). Any overhaul can be etched by the CMP process, for example.

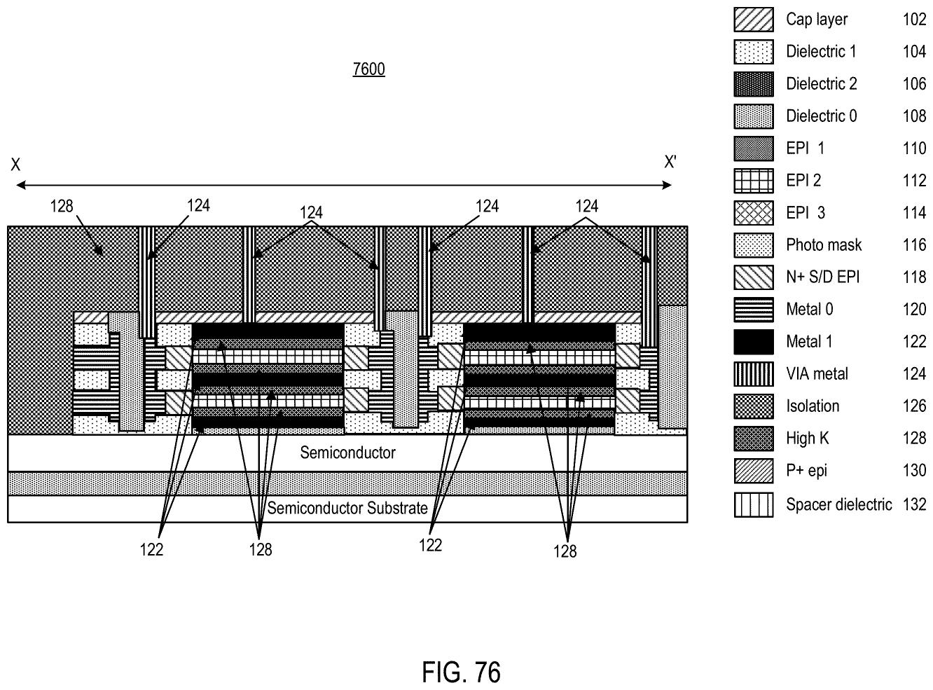

FIG. 76 illustrates a cross-sectional view 7600 of the subsequent stage in the process flow. After depositing the dielectric material 108, various operations can be performed to form or provide cross-section of the semiconductor device. For example, the semiconductor material 114 can be removed and replaced with the dielectric material 108 to isolate the second stack (and the third stack) from the semiconductor substrate. The semiconductor materials 110 can be removed and replaced with the metal material 122 and high-k dielectric materials 128. The isolation material 126 can be deposited above the semiconductor devices (e.g., first and second semiconductor devices). Etching and deposition of the via structures 124 can be performed to form the via structures 124, as shown in FIG. 76. The removal and formation of the materials in FIG. 76 can be performed similarly to the operations or techniques described in connection with FIGS. 20-24, 42-46, and 66-70, for example.

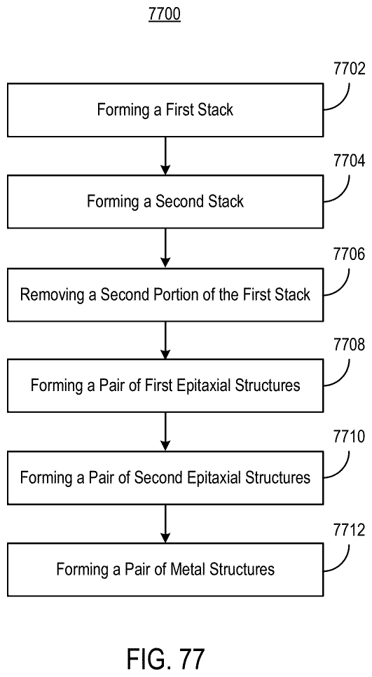

FIG. 77 illustrates a flow diagram of a method 7700 for microfabrication using the process flows described in connection with FIGS. 1-76, according to an embodiment. The method 7700 may include steps 7702-7712. However, other embodiments may include additional or alternative steps, or may omit one or more steps altogether.

Referring to step 7702, the method 7700 includes forming a first stack over a substrate. The first stack includes multiple first dielectric layers (e.g., dielectric materials 104) and multiple second dielectric layers (e.g., dielectric materials 106) alternately stacked on top of one another. The process for forming the first stack can be described in connection with at least one of FIG. 1, 25, or 47, for example.

Referring to step 7704, the method 7700 includes forming a second stack. For example, a first portion of the first stack can be replaced with a second stack. The second stack includes multiple first semiconductor layers (e.g., semiconductor materials 110) and multiple second semiconductor layers (e.g., semiconductor materials 112) alternately stacked on top of one another. The process for forming the second stack can be described in connection with at least one of FIG. 2-3, 26-27, or 48-49, for example.

In various arrangements, the replacing the first portion of the first stack with the second stack can include (e.g., from bottom to top of the second stack) epitaxially growing a third semiconductor layer (e.g., semiconductor material 114) from the substrate, epitaxially growing a lower one of the first semiconductor layers, epitaxially growing the lower second semiconductor layer, epitaxially growing a middle one of the first semiconductor layers, epitaxially growing the upper second semiconductor layer, and epitaxially growing an upper one of the first semiconductor layers. In various implementations, the first stack and the second stack may be a part of the same stack, where the sidewalls of each of the first semiconductor layers are respectively covered by corresponding first dielectric layers, and the sidewalls of each of the second semiconductor layers are respectively covered by corresponding second dielectric layers (e.g., shown in conjunction with at least one of FIG. 3, 27, or 49, among others).

Referring to step 7706, the method 7700 includes removing a second portion of the first stack to expose sidewalls of each of the second semiconductor layers, respectively. To remove the second portion of the first stack, the process can be described in connection with at least one of FIGS. 6, 30, 54.

Referring to step 7708, the method 7700 includes forming a pair of first epitaxial structures (e.g., lower epitaxial material 118) through the removed second portion (e.g., lateral opening or “spine-shaped” cavity) of the first stack. The pair of first epitaxial structures can be in contact with a lower one of the second semiconductor layers, respectively. Referring to step 7710, the method 7700 includes forming a pair of second epitaxial structures (e.g., upper epitaxial material 118 or epitaxial material 130) through the removed second portion of the first stack. The pair of second epitaxial structures can be in contact with an upper one of the second semiconductor layers, respectively. The pair of first epitaxial structures and the pair of second epitaxial structures can be vertically spaced from one another (e.g., by the middle one of the first dielectric layers). The formation of the pairs of the first and second epitaxial structures can be described in connection with at least one of FIG. 9-11, 34, 39, or 58, among others.

In some implementations, the pair of first epitaxial structures and the pair of second epitaxial structures can be concurrently formed. In this case, the pair of first epitaxial structures and the pair of second epitaxial structures can have the same conductive type. Forming the pairs of first and second epitaxial structures concurrently can be described in connection with FIG. 9-11 or 58, for example.

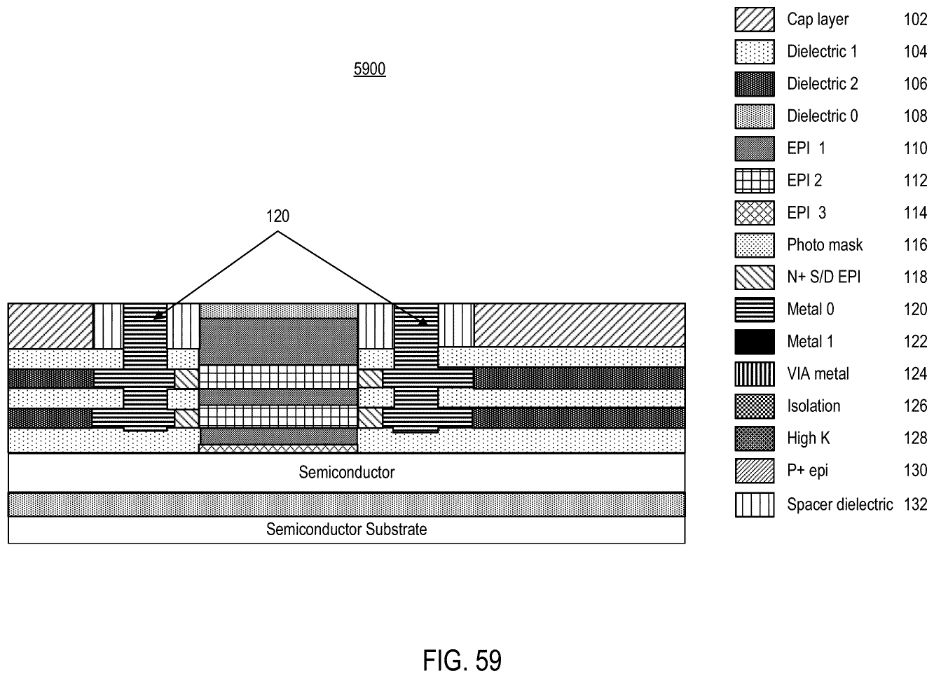

Referring to step 7712, the method 7700 includes forming a pair of metal structures (e.g., metal material 120) through the removed second portion of the first stack. The pair of metal structures can be in electrical contact with the pair of first epitaxial structures, respectively, and with the pair of second epitaxial structures, respectively. The formation of the pair of metal structures can be described in connection with the process of at least one of FIG. 12 or 59, for example.

In some implementations, the pair of first epitaxial structures and the pair of second epitaxial structures are separately formed. In this case, the pair of first epitaxial structures and the pair of second epitaxial structures can have respectively different conductive types. Further, a pair of metal structures can be formed through the removed second portion of the first stack. The pair of metal structures can be in electrical contact with the pair of first epitaxial structures, respectively. The separate formation of the pairs of first and second epitaxial structures and pair of metal structures can be described in connection with the process of at least one of FIGS. 34-39, for example.

In various arrangements, the third semiconductor layer is replaced with a third dielectric layer to electrically isolate the second stack from the substrate. Replacing the third semiconductor layer can be described in connection with the process of at least one of FIG. 20, 21, 42, 43, 66, or 67, among others, for example. In some aspects, the first semiconductor layers can be replaced with a gate structure (e.g., at least one of metal material 122 and/or high-k dielectric material 128) that is around each of the second semiconductor layers. To replace the first semiconductor layers with the gate structure, a process can be performed in connection with at least one of FIG. 22, 23, 44, 45, 68, or 69, for example.

In various arrangements, the gate structure, the upper and lower second semiconductor layers, the pair of first epitaxial structures, and the pair of second epitaxial structures collectively operate as a single transistor. In various other arrangements, the gate structure, the lower second semiconductor layer, and the pair of first epitaxial structures collectively operate as a first transistor of an inverter, and the gate structure, the upper second semiconductor layer, and the pair of second epitaxial structures collectively operate as a second transistor of the inverter.

In some implementations, prior to removing the second portion of the first stack, a pair of dielectric spacers (e.g., dielectric material 132) can be formed on opposite sides of a topmost one of the second semiconductor layers. To form the pair of dielectric spacers, the process can be described in connection with at least FIG. 53, for example. In various implementations, a third portion of the first stack can be removed using the dielectric spacers as a mask (e.g., the process of which is described in conjunction with FIG. 53). In this case, respective portions of the second dielectric layers can be etched through the removed third portion while leaving the first dielectric layers substantially intact to form the second portion of the first stack. Etching these portions of the second dielectric layers can be described in conjunction with the process of at least FIG. 24, for example.

In certain implementations, the upper and lower second semiconductor layers may be referred to as a first semiconductor layer and a second semiconductor layer vertically spaced from one another (e.g., vertically spaced by other semiconductor layers). For instance, the second semiconductor layer can be in contact with the pair of first epitaxial structures, and the first semiconductor layer can be in contact with the pair of second epitaxial structures. The formation of other structures can be performed using the techniques described in connection with at least one of FIGS. 1-76, as described herein.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method for fabricating semiconductor devices, comprising:
forming a first stack over a substrate, the first stack including a plurality of first dielectric layers and a plurality of second dielectric layers alternately stacked on top of one another;
replacing a first portion of the first stack with a second stack, the second stack including a plurality of first semiconductor layers and a plurality of second semiconductor layers alternately stacked on top of one another;
removing a second portion of the first stack to expose sidewalls of each of the plurality of second semiconductor layers, respectively;
forming, through the removed second portion of the first stack, a pair of first epitaxial structures in contact with a lower one of the second semiconductor layers, respectively; and
forming, through the removed second portion of the first stack, a pair of second epitaxial structures in contact with an upper one of the second semiconductor layers, respectively.

2. The method of claim 1, wherein the pair of first epitaxial structures and the pair of second epitaxial structures are concurrently formed, and wherein the pair of first epitaxial structures and the pair of second epitaxial structures have a same conductive type.

3. The method of claim 2, further comprising forming, through the removed second portion of the first stack, a pair of metal structures in electrical contact with the pair of first epitaxial structures, respectively, and with the pair of second epitaxial structures, respectively.

4. The method of claim 1, wherein the pair of first epitaxial structures and the pair of second epitaxial structures are separately formed, and wherein the pair of first epitaxial structures and the pair of second epitaxial structures have respectively different conductive types.

5. The method of claim 4, further comprising forming, through the removed second portion of the first stack, a pair of metal structures in electrical contact with the pair of first epitaxial structures, respectively.

6. The method of claim 1, further comprising replacing the first semiconductor layers with a gate structure that is around each of the second semiconductor layers.

7. The method of claim 1, wherein the step of replacing a first portion of the first stack with a second stack further comprises:
epitaxially growing a third semiconductor layer from the substrate;
epitaxially growing a lower one of the first semiconductor layers;
epitaxially growing the lower second semiconductor layer;
epitaxially growing a middle one of the first semiconductor layers;
epitaxially growing the upper second semiconductor layer; and
epitaxially growing an upper one of the first semiconductor layers.

8. The method of claim 7, further comprising replacing the third semiconductor layer with a third dielectric layer to electrically isolate the second stack from the substrate.

9. The method of claim 1, prior to removing the second portion of the first stack, further comprising forming a pair of dielectric spacers on opposite sides of a topmost one of the second semiconductor layers.

10. The method of claim 9, further comprising:
removing a third portion of the first stack using the dielectric spacers as a mask; and
etching, through the removed third portion, respective portions of the second dielectric layers while leaving the first dielectric layers substantially intact to form the second portion of the first stack.

11. A method for fabricating semiconductor devices, comprising:
forming a stack including a plurality of first semiconductor layers and a plurality of second semiconductor layers alternately stacked on top of one another, wherein sidewalls of each of the first semiconductor layers are respectively covered by corresponding first dielectric layers, and sidewalls of each of the second semiconductor layers are respectively covered by corresponding second dielectric layers;
exposing the sidewalls of each of the second semiconductor layers;
forming a pair of first epitaxial structures in contact with the sidewalls of a lower one of the second semiconductor layers, respectively; and
forming a pair of second epitaxial structures in contact with the sidewalls of an upper one of the second semiconductor layers, respectively.

12. The method of claim 11, further comprising replacing the first semiconductor layers with a gate structure that is around each of the second semiconductor layers.

13. The method of claim 12, wherein the pair of first epitaxial structures and the pair of second epitaxial structures are concurrently formed, and wherein the pair of first epitaxial structures and the pair of second epitaxial structures have a same conductive type.

14. The method of claim 13, wherein the gate structure, the upper and lower second semiconductor layers, the pair of first epitaxial structures, and the pair of second epitaxial structures collectively operate as a single transistor.

15. The method of claim 12, wherein the pair of first epitaxial structures and the pair of second epitaxial structures are separately formed, and wherein the pair of first epitaxial structures and the pair of second epitaxial structures have respectively different conductive types.

16. The method of claim 15, wherein the gate structure, the lower second semiconductor layer, and the pair of first epitaxial structures collectively operate as a first transistor of an inverter, and the gate structure, the upper second semiconductor layer, and the pair of second epitaxial structures collectively operate as a second transistor of the inverter.

17. The method of claim 11, wherein the step of forming a stack comprises:
epitaxially growing a third semiconductor layer from a semiconductor substrate;
epitaxially growing a lower one of the first semiconductor layers;
epitaxially growing the lower second semiconductor layer;
epitaxially growing a middle one of the first semiconductor layers;
epitaxially growing the upper second semiconductor layer; and
epitaxially growing an upper one of the first semiconductor layers;
wherein the third semiconductor layer is replaced with a third dielectric layer to electrically isolate the stack from the semiconductor substrate.

18. A semiconductor device, comprising:
a first semiconductor layer and a second semiconductor layer vertically spaced from one another;
a pair of first epitaxial structures and a pair of second epitaxial structures vertically spaced from one another, wherein the pair of first epitaxial structures are in contact with the first semiconductor layer and the pair of second epitaxial structures are in contact with the second semiconductor layer; and
a gate structure disposed around each of the first and second semiconductor layers.

19. The semiconductor device of claim 18, wherein the pair of first epitaxial structures and the pair of second epitaxial structures have a same conductive type such that the gate structure, the first and second semiconductor layers, the pair of first epitaxial structures, and the pair of second epitaxial structures collectively operate as a single transistor.

20. The semiconductor device of claim 18, wherein the pair of first epitaxial structures and the pair of second epitaxial structures have respectively different conductive types such that the gate structure, the first semiconductor layer, and the pair of first epitaxial structures collectively operate as a first transistor of an inverter, and the gate structure, the second semiconductor layer, and the pair of second epitaxial structures collectively operate as a second transistor of the inverter.
